(19) United States
(12) Patent Application Publication
(10) Pub. No.: US 2024/0405157 A1
(43) Pub. Date: Dec. 5, 2024

(54) DISPLAY MODULE, LED OPTICAL DEVICE AND MANUFACTURING METHOD THEREFOR

(71) Applicant: Shenzhen Jufei Optoelectronics Co., Ltd., Shenzhen, Guangdong (CN)

(72) Inventors: Wenbo MA, Shenzhen (CN); Ruibing CHEN, Shenzhen (CN); Bin ZHENG, Shenzhen (CN); Meizheng XING, Shenzhen (CN); Zhuangzhi LI, Shenzhen (CN); Xingmin LU, Shenzhen (CN)

(73) Assignee: Shenzhen Jufei Optoelectronics Co., Ltd., Shenzhen, Guangdong (CN)

(21) Appl. No.: 18/697,188

(22) PCT Filed: Sep. 30, 2022
(86) PCT No.: PCT/CN2022/123579

§ 371 Date: Mar. 29, 2024

(30) Foreign Application Priority Data
Sep. 30, 2021 (CN) 202111166118.8
Sep. 30, 2021 (CN) 202122395097.9
Sep. 30, 2021 (CN) 202122398449.6
Sep. 30, 2021 (CN) 202122409206.8
Oct. 28, 2021 (CN) 202111265275.4
Nov. 5, 2021 (CN) 202111308127.6
Nov. 5, 2021 (CN) 202122699980.7
Nov. 25, 2021 (CN) 202111414585.8
Nov. 30, 2021 (CN) 202111441754.7
Feb. 16, 2022 (CN) 202210141646.6
May 31, 2022 (CN) 202210612146.6
May 31, 2022 (CN) 202210612159.3
Jul. 29, 2022 (CN) 202210909811.8

(51) Int. Cl. H01L 33/10; H01L 25/075; H01L 33/56; H01L 33/62

(52) U.S. Cl. CPC H01L 33/10; H01L 25/0753; H01L 33/56; H01L 33/62

(57) ABSTRACT

A display module, an LED optical device and a manufacturing method therefor. The display module and the LED optical device each includes a substrate (1), a plurality of light-emitting units (2) arranged on the top surface of the substrate (1), and a packaging layer (3) arranged on the substrate (1) and covering each light-emitting unit (2), where each light-emitting unit (2) includes at least one LED chip, and the packaging layer (3) is configured to transmit light emitted by the LED chip.

### BACKGROUND OF THE INVENTION

### Technical Field

The present invention relates to the field of light emitting diode (LED) chip display, and in particular, to a display module, an LED optical device and a manufacturing method therefor.

### Related Art

LEDs are widely applied to the display field and other fields. In the field of display, air-tightness of an LED and the thickness of a display module or an LED optical device manufactured using an LED are both strictly required. To satisfy air-tightness, in the field of display, an LED lamp bead with good air-tightness is generally used, which includes a bracket, an LED chip arranged in the bracket, and a sealant layer sealing the LED chip in the bracket. Although the LED lamp bead can satisfy the air-tightness requirement, the LED lamp bead is large in size and high in cost because of using the LED bracket, and then a display module or an LED optical device manufactured using the LED lamp bead is thick as a whole and high in cost.

### SUMMARY

### Technical Problem

In view of the foregoing disadvantage of the existing technology, an objective of the present invention is to provide a display module, an LED optical device and a manufacturing method therefor, aiming to resolve the problem in the related technology that the display module or the LED optical device is thick as a whole and high in cost.

### Solution to the Problem

### Technical Solution

To resolve the foregoing problem, the present invention provides a display module and an LED optical device, including a substrate, a plurality of light-emitting units arranged on a top surface of the substrate, and a packaging layer arranged on the substrate and covering each of the light-emitting units, where each of the light-emitting units includes at least one LED chip, the packaging layer is configured to transmit light emitted by the LED chip, and the packaging layer has a thickness greater than a thickness of the light-emitting unit.

Based on the same inventive idea, the present invention further provides a manufacturing method for a display module and an LED optical device, including:
providing a substrate;
arranging a plurality of light-emitting units on a top surface of the substrate, where each of the light-emitting units includes at least one LED chip; and
arranging a packaging layer covering each of the light-emitting units on the substrate, where the packaging layer is configured to transmit light emitted by the LED chip, and the packaging layer has a thickness greater than a thickness of the light-emitting unit.

### BENEFICIAL EFFECTS OF THE PRESENT INVENTION

### Beneficial Effects

In the display module, the LED optical device and the manufacturing method therefor provided in the present invention, the display module and the LED optical device each includes a substrate and light-emitting units arranged on a top surface of the substrate, where each light-emitting unit includes at least one LED chip; and further includes a packaging layer arranged on the substrate and covering each light-emitting unit. For the display module, LED lamp beads are no longer used as a light source, but instead LED chips are directly used as a light source. Therefore, use of brackets included in the LED lamp beads can be omitted, which can reduce costs and can also reduce a whole thickness of the display module and the LED optical device, to better facilitate lightening and thinning thereof. In addition, the arranged packaging layer covers each light-emitting unit, which can also satisfy the air-tightness requirement of the display module and the LED optical device and can also protect each light-emitting unit.

### Beneficial Effects

In the display module and the manufacturing method therefor provided in the present invention, the display module includes a substrate and light-emitting units arranged on a top surface of the substrate, where each light-emitting unit includes at least one LED chip; and further includes a packaging layer arranged on the substrate and covering each light-emitting unit. For the display module, LED lamp beads are no longer used as a light source, but instead LED chips are directly used as a light source. Therefore, use of brackets included in the LED lamp beads can be omitted, which can reduce costs and can also reduce a whole thickness of the display module, to better facilitate lightening and thinning thereof. In addition, the arranged packaging layer covers each light-emitting unit, which can also satisfy the air-tightness requirement of the display module and can also protect each light-emitting unit.

### BRIEF DESCRIPTION OF THE DRAWINGS

FIG. 1 is a schematic structural diagram of a display module according to the present invention;

FIG. 2-1 is a schematic structural diagram 1 of a display module according to Embodiment 1 of the present invention;

FIG. 2-2 is a top view of the display module shown in FIG. 2-1;

FIG. 2-3 is a bottom view of the display module shown in FIG. 2-2;

FIG. 2-4 is a schematic structural diagram 2 of a display module according to Embodiment 1 of the present invention;

FIG. 2-5 is a top view of the display module shown in FIG. 2-4;

FIG. 2-6 is a schematic structural diagram 1 of a substrate according to Embodiment 1 of the present invention;

FIG. 2-7 is a schematic structural diagram 2 of a substrate according to Embodiment 1 of the present invention;

FIG. 2-8 is a schematic structural diagram 3 of a substrate according to Embodiment 1 of the present invention;

FIG. 2-9 is a schematic structural diagram 4 of a substrate according to Embodiment 1 of the present invention;

FIG. 2-10 is a schematic structural diagram 5 of a substrate according to Embodiment 1 of the present invention;

FIG. 2-11 is a schematic structural diagram 6 of a substrate according to Embodiment 1 of the present invention;

FIG. 2-12 is a schematic structural diagram 7 of a substrate according to Embodiment 1 of the present invention;

FIG. 2-13 is a schematic structural diagram 8 of a substrate according to Embodiment 1 of the present invention;

FIG. 2-14 is a schematic structural diagram 9 of a substrate according to Embodiment 1 of the present invention;

FIG. 2-15 is a schematic structural diagram 10 of a substrate according to Embodiment 1 of the present invention;

FIG. 2-16 is a schematic structural diagram 3 of a display module according to Embodiment 1 of the present invention;

FIG. 2-17 is a schematic structural diagram 4 of a display module according to Embodiment 1 of the present invention;

FIG. 2-18 is a schematic structural diagram 5 of a display module according to Embodiment 1 of the present invention;

FIG. 2-19 is a schematic structural diagram 6 of a display module according to Embodiment 1 of the present invention;

FIG. 2-20 is a schematic structural diagram 7 of a display module according to Embodiment 1 of the present invention;

FIG. 2-21 is a schematic structural diagram of a display screen according to Embodiment 1 of the present invention;

FIG. 3-1 is a top view of a display module according to Embodiment 1 of the present invention;

FIG. 3-2 is a bottom view of a display module according to Embodiment 1 of the present invention;

FIG. 3-3 is a cross-sectional view of the display module shown in FIG. 3-1;

FIG. 3-4 is a schematic structural diagram 2 of a display module according to Embodiment 1 of the present invention;

FIG. 3-5 is a schematic structural diagram 3 of a display module according to Embodiment 1 of the present invention;

FIG. 3-6 is a schematic structural diagram 4 of a display module according to Embodiment 1 of the present invention;

FIG. 3-7 is a schematic structural diagram 5 of a display module according to Embodiment 1 of the present invention;

FIG. 3-8 is a schematic structural diagram 6 of a display module according to Embodiment 1 of the present invention;

FIG. 3-9 is a schematic structural diagram 7 of a display module according to Embodiment 1 of the present invention;

FIG. 3-10 is a schematic structural diagram 8 of a display module according to Embodiment 1 of the present invention;

FIG. 4-1 is a schematic structural diagram 1 of a display module according to Embodiment 3 of the present invention;

FIG. 4-2 is a locally enlarged schematic diagram of a display module at a splicing place according to Embodiment 3 of the present invention;

FIG. 4-3 is a schematic structural diagram 2 of a display module according to Embodiment 3 of the present invention;

FIG. 4-4 is a schematic structural diagram 3 of a display module according to Embodiment 3 of the present invention;

FIG. 4-5 is a schematic structural diagram 4 of a display module according to Embodiment 3 of the present invention;

FIG. 4-6 is a schematic diagram of a basic wiring area according to Embodiment 3 of the present invention;

FIG. 4-7 is a schematic structural diagram 5 of a display module according to Embodiment 3 of the present invention;

FIG. 4-8 is a schematic structural diagram 6 of a display module according to Embodiment 3 of the present invention;

FIG. 4-9 is a schematic structural diagram 7 of a display module according to Embodiment 3 of the present invention;

FIG. 4-10 is a schematic structural diagram 8 of a display module according to Embodiment 3 of the present invention;

FIG. 4-11 is a schematic structural diagram 9 of a display module according to Embodiment 3 of the present invention;

FIG. 4-12 is a schematic structural diagram 10 of a display module according to Embodiment 3 of the present invention;

FIG. 4-13 is a schematic structural diagram 11 of a display module according to Embodiment 3 of the present invention;

FIG. 4-14 is a schematic structural diagram 12 of a display module according to Embodiment 3 of the present invention;

FIG. 4-15 is a schematic structural diagram 13 of a display module according to Embodiment 3 of the present invention;

FIG. 4-16 is a schematic structural diagram 14 of a display module according to Embodiment 3 of the present invention;

FIG. 4-17 is a schematic diagram 1 of a splicing effect of a display module according to Embodiment 3 of the present invention;

FIG. 4-18 is a schematic diagram 2 of a splicing effect of a display module according to Embodiment 3 of the present invention;

FIG. 5-1 is a schematic structural diagram of a top surface of a substrate according to Embodiment 4 of the present invention;

FIG. 5-2 is a schematic structural diagram of a back surface of a substrate according to Embodiment 4 of the present invention;

FIG. 5-3 is a schematic structural diagram 1 of a top surface of the substrate provided with a groove according to Embodiment 4 of the present invention;

FIG. 5-4 is a schematic structural diagram of an A4-A4 cross-section in FIG. 5-3;

FIG. 5-5 is a schematic structural diagram of a top surface of a substrate on which light-emitting units are mounted according to Embodiment 4 of the present invention;

FIG. 5-6 is a schematic structural diagram of an A4-A4 cross-section in FIG. 5-5;

FIG. 5-7 is a schematic structural diagram of an A4-A4 cross-section after a first packaging layer is mold-pressed on a top surface of the substrate according to Embodiment 4 of the present invention;

FIG. 5-8 is a schematic structural diagram of an A4-A4 cross-section after a part of a process edge of a substrate is cut away according to Embodiment 4 of the present invention;

FIG. 5-9 is another schematic structural diagram of an A4-A4 cross-section in FIG. 5-3 according to Embodiment 4 of the present invention;

FIG. 5-10 is another schematic structural diagram of an A4-A4 cross-section in FIG. 5-3 according to Embodiment 4 of the present invention;

FIG. 5-11 is another schematic structural diagram of an A4-A4 cross-section in FIG. 5-3 according to Embodiment 4 of the present invention;

FIG. 5-12a is another schematic structural diagram of an A4-A4 cross-section in FIG. 5-3 according to Embodiment 4 of the present invention;

FIG. 5-12b is a schematic structural diagram obtained after a part of a process edge is cut away based on FIG. 5-12a according to Embodiment 4 of the present invention;

FIG. 5-13 is a schematic structural diagram of an A4-A4 cross-section after an electronic driving element is mounted on a back surface of the substrate according to Embodiment 4 of the present invention;

FIG. 5-14 is a schematic structural diagram of a cross-section after two display modules are spliced according to Embodiment 4 of the present invention;

FIG. 5-15 is a schematic structural diagram of a cross-section after a second packaging layer is mold-pressed on a substrate according to Embodiment 4 of the present invention;

FIG. 5-16 is a schematic structural diagram obtained after a part of a process edge is cut away based on FIG. 5-15 according to Embodiment 4 of the present invention;

FIG. 5-17 is a schematic structural diagram of a cross-section after a second packaging layer is mold-pressed based on FIG. 5-16 according to Embodiment 4 of the present invention;

FIG. 5-18 is a schematic structural diagram of a cross-section after two display modules shown in FIG. 5-17 are spliced according to Embodiment 4 of the present invention;

FIG. 5-19 is a schematic structural diagram of a top surface of a screen into which display modules are spliced according to Embodiment 4 of the present invention;

FIG. 5-20 is a schematic structural diagram 1 of a back surface of the substrate provided with a back groove according to Embodiment 4 of the present invention;

FIG. 5-21 is a schematic structural diagram 2 of a back surface of the substrate provided with a back groove according to Embodiment 4 of the present invention;

FIG. 5-22 is a schematic structural diagram 3 of a back surface of the substrate provided with a back groove according to Embodiment 4 of the present invention;

FIG. 5-23 is a schematic structural diagram 4 of a back surface of the substrate provided with a back groove according to Embodiment 4 of the present invention;

FIG. 5-24 is another schematic structural diagram of splicing display modules according to Embodiment 4 of the present invention;

FIG. 6-1 is a schematic structural diagram 1 of a display module according to Embodiment 5 of the present invention;

FIG. 6-2 is a schematic structural diagram 2 of a display module according to Embodiment 5 of the present invention;

FIG. 6-3 is a schematic structural diagram 3 of a display module according to Embodiment 5 of the present invention;

FIG. 6-4 is a schematic structural diagram 4 of a display module according to Embodiment 5 of the present invention;

FIG. 6-5a is a schematic structural diagram 5 of a display module according to Embodiment 5 of the present invention;

FIG. 6-5b is a schematic structural diagram 6 of a display module according to Embodiment 5 of the present invention;

FIG. 6-6a is a schematic structural diagram 7 of a display module according to Embodiment 5 of the present invention;

FIG. 6-6b is a schematic structural diagram 8 of a display module according to Embodiment 5 of the present invention;

FIG. 6-7 is a schematic structural diagram 9 of a display module according to Embodiment 5 of the present invention;

FIG. 6-8a is a schematic structural diagram 10 of a display module according to Embodiment 5 of the present invention;

FIG. 6-8b is a schematic structural diagram 11 of a display module according to Embodiment 5 of the present invention;

FIG. 6-9 is a schematic diagram of a display screen according to Embodiment 5 of the present invention;

FIG. 7-1 is a schematic structural diagram 1 of a display module according to Embodiment 6 of the present invention;

FIG. 7-2 is a diagram of an orthographic projection of a display module according to Embodiment 6 of the present invention;

FIG. 7-3 is a schematic structural diagram 2 of a display module according to Embodiment 6 of the present invention;

FIG. 7-4 is a schematic structural diagram of a packaging layer according to Embodiment 6 of the present invention;

FIG. 7-5 is a schematic structural diagram of a substrate according to Embodiment 6 of the present invention;

FIG. 7-6 is a schematic structural diagram of a substrate jig according to Embodiment 6 of the present invention;

FIG. 7-7 is a schematic structural diagram of a substrate fixed on a substrate jig according to Embodiment 6 of the present invention;

FIG. 7-8 is a schematic structural diagram of a packaging layer laminated on a substrate according to Embodiment 6 of the present invention;

FIG. 7-9 is a schematic structural diagram of a packaging layer press-fit toward a substrate according to Embodiment 6 of the present invention;

FIG. 7-10 is a schematic structural diagram of a packaging layer press-fit onto a substrate according to Embodiment 6 of the present invention;

FIG. 7-11 is a schematic structural diagram of a back surface of the substrate on which an electronic element is arranged according to Embodiment 6 of the present invention;

FIG. 7-12 is another schematic structural diagram of a substrate according to Embodiment 6 of the present invention;

FIG. 7-13 is another schematic structural diagram of a substrate jig according to Embodiment 6 of the present invention;

FIG. 7-14 is another schematic structural diagram of a substrate fixed on a substrate jig according to Embodiment 6 of the present invention;

FIG. 7-15 is another schematic structural diagram of a packaging layer laminated on a substrate according to Embodiment 6 of the present invention;

FIG. 7-16 is another schematic structural diagram of a packaging layer press-fit toward a substrate according to Embodiment 6 of the present invention;

FIG. 7-17 is another schematic structural diagram of a packaging layer press-fit onto a substrate according to Embodiment 6 of the present invention;

FIG. 8-1 is a schematic diagram of a solder paste according to Embodiment 7 of the present invention;

FIG. 8-2 is a schematic structural diagram 1 of a substrate according to Embodiment 7 of the present invention;

FIG. 8-3 is a schematic structural diagram 2 of a substrate according to Embodiment 7 of the present invention;

FIG. 8-4 is a schematic structural diagram 1 of a display module according to Embodiment 7 of the present invention;

FIG. 8-5 is a schematic structural diagram of soldering corresponding to a single LED chip in FIG. 8-4;

FIG. 8-6 is a diagram of a physical reference of a display module according to Embodiment 7 of the present invention;

FIG. 8-7 is a schematic structural diagram 2 of a display module according to Embodiment 7 of the present invention;

FIG. 8-8 is a schematic diagram of a manufacturing method for a display module according to Embodiment 7 of the present invention;

FIG. 9-1 is a schematic structural diagram 1 of a black deposition layer according to Embodiment 8 of the present invention;

FIG. 9-2 is a schematic structural diagram 2 of a black deposition layer according to Embodiment 8 of the present invention;

FIG. 9-3 is a schematic structural diagram 3 of a black deposition layer according to Embodiment 8 of the present invention;

FIG. 9-4 is a schematic diagram 1 of a display module manufacturing process according to Embodiment 8 of the present invention;

FIG. 9-5 is a schematic diagram 2 of a display module manufacturing process according to Embodiment 8 of the present invention;

FIG. 9-6 is a schematic diagram 3 of a display module manufacturing process according to Embodiment 8 of the present invention;

FIG. 9-7 is a schematic diagram 1 of magnetron sputtering according to Embodiment 8 of the present invention;

FIG. 9-8 is a schematic diagram 2 of magnetron sputtering according to Embodiment 8 of the present invention;

FIG. 9-9 is a schematic structural diagram 1 of a display module according to Embodiment 8 of the present invention;

FIG. 9-10 is a schematic structural diagram 2 of a display module according to Embodiment 8 of the present invention;

FIG. 9-11 is a schematic structural diagram 3 of a display module according to Embodiment 8 of the present invention;

FIG. 9-12 is a schematic structural diagram of an LED display screen according to Embodiment 8 of the present invention;

FIG. 10-1 is a schematic structural diagram of a substrate provided with light-emitting units according to Embodiment 9 of the present invention;

FIG. 10-2 is a schematic structural diagram of a principle of a translucent layer according to Embodiment 9 of the present invention;

FIG. 10-3 is a schematic structural diagram of a reflection layer according to Embodiment 9 of the present invention;

FIG. 10-4 is a schematic structural diagram of a third black adhesive layer according to Embodiment 9 of the present invention;

FIG. 10-5 is a schematic diagram 1 of a light path of a translucent layer according to Embodiment 9 of the present invention;

FIG. 10-6 is a schematic diagram 2 of a light path of a translucent layer according to Embodiment 9 of the present invention;

FIG. 10-7 is a schematic structural diagram 1 of a display module according to Embodiment 9 of the present invention;

FIG. 10-8 is a schematic diagram 1 of a light path of the display module in FIG. 10-7;

FIG. 10-9 is a schematic diagram 2 of a light path of the display module in FIG. 10-7;

FIG. 10-10 is a schematic diagram of a plane mirror image according to Embodiment 9 of the present invention;

FIG. 10-11 is a schematic diagram of specular reflection according to Embodiment 9 of the present invention;

FIG. 10-12 is a schematic diagram of diffuse reflection according to Embodiment 9 of the present invention;

FIG. 10-13 is a schematic structural diagram 2 of a display module according to Embodiment 9 of the present invention;

FIG. 10-14 is a schematic structural diagram 3 of a display module according to Embodiment 9 of the present invention;

FIG. 10-15 is a schematic structural diagram 4 of a display module according to Embodiment 9 of the present invention;

FIG. 10-16 is a schematic structural diagram 5 of a display module according to Embodiment 9 of the present invention;

FIG. 10-17 is a schematic structural diagram 6 of a display module according to Embodiment 9 of the present invention;

FIG. 10-18 is a schematic structural diagram 7 of a display module according to Embodiment 9 of the present invention;

FIG. 10-19 is a schematic structural diagram 8 of a display module according to Embodiment 9 of the present invention;

FIG. 10-20 is a schematic structural diagram 9 of a display module according to Embodiment 9 of the present invention;

FIG. 10-21 is a schematic diagram 1 of a display module manufacturing process according to Embodiment 9 of the present invention;

FIG. 10-22 is a schematic diagram 2 of a display module manufacturing process according to Embodiment 9 of the present invention;

FIG. 10-23 is a schematic diagram 3 of a display module manufacturing process according to Embodiment 9 of the present invention;

FIG. 10-24 is a schematic diagram 4 of a display module manufacturing process according to Embodiment 9 of the present invention;

FIG. 10-25 is a schematic diagram 5 of a display module manufacturing process according to Embodiment 9 of the present invention;

FIG. 10-26 is a schematic diagram 6 of a display module manufacturing process according to Embodiment 9 of the present invention;

FIG. 10-27 is a schematic structural diagram of a display screen according to Embodiment 9 of the present invention;

FIG. 11-1 is a schematic diagram 1 of a display module manufacturing process according to Embodiment 10 of the present invention;

FIG. 11-2 is a schematic diagram 1 of a cross-section after a first packaging layer is removed from a display module according to Embodiment 10 of the present invention;

FIG. 11-3 is a schematic diagram 2 of a display module manufacturing process according to Embodiment 10 of the present invention;

FIG. 11-4 is a schematic diagram 2 of a cross-section after a first packaging layer is removed from a display module according to Embodiment 10 of the present invention;

FIG. 11-5 is a schematic cross-sectional view 1 of a display module according to Embodiment 10 of the present invention;

FIG. 11-6 is a schematic cross-sectional view 2 of a display module according to Embodiment 10 of the present invention;

FIG. 11-7 is a schematic cross-sectional view 3 of a display module according to Embodiment 10 of the present invention;

FIG. 11-8 is a schematic cross-sectional view 4 of a display module according to Embodiment 10 of the present invention;

FIG. 11-9 is a schematic cross-sectional view 5 of a display module according to Embodiment 10 of the present invention;

FIG. 11-10 is a schematic cross-sectional view 6 of a display module according to Embodiment 10 of the present invention;

FIG. 11-11 is a schematic cross-sectional view 7 of a display module according to Embodiment 10 of the present invention;

FIG. 11-12 is a schematic cross-sectional view 8 of a display module according to Embodiment 10 of the present invention;

FIG. 11-13 is a schematic cross-sectional view 9 of a display module according to Embodiment 10 of the present invention;

FIG. 12-1 is a schematic structural diagram of a display module according to Embodiment 11 of the present invention;

FIG. 12-2 is a schematic diagram of light homogenization treatment performed by a light diffusion unit according to Embodiment 11 of the present invention;

FIG. 12-3 is a schematic diagram 1 of a projection of a light diffusion unit on a substrate according to Embodiment 11 of the present invention;

FIG. 12-4 is a schematic diagram 2 of a projection of a light diffusion unit on a substrate according to Embodiment 11 of the present invention;

FIG. 12-5 is a schematic diagram 3 of a projection of a light diffusion unit on a substrate according to Embodiment 11 of the present invention;

FIG. 12-6 is a schematic diagram 4 of a projection of a light diffusion unit on a substrate according to Embodiment 11 of the present invention;

FIG. 13-1 is a schematic structural diagram of a display module according to Embodiment 12 of the present invention;

FIG. 13-2 is a schematic diagram of a light-emitting unit including four rectangular LED chips according to Embodiment 12 of the present invention;

FIG. 13-3 is a schematic diagram of an arrangement of LED chips in a spliced substrate according to Embodiment 12 of the present invention;

FIG. 13-4 is a schematic diagram of another arrangement of LED chips in a spliced substrate according to Embodiment 12 of the present invention;

FIG. 13-5 is a schematic diagram of a light-emitting unit including three elliptical LED chips according to Embodiment 12 of the present invention;

FIG. 13-6 is a schematic diagram of electrically connecting sub-central electrodes of LED chips according to Embodiment 12 of the present invention;

FIG. 13-7 is a schematic diagram of electrode orientations of LED chips in another light-emitting unit according to Embodiment 12 of the present invention;

FIG. 13-8 is a schematic diagram of electrode orientations of LED chips in still another light-emitting unit according to Embodiment 12 of the present invention;

FIG. 13-9 is another schematic structural diagram of a display module according to Embodiment 12 of the present invention;

FIG. 13-10 is a schematic diagram of an adjustable distance and an adjustable angle of an LED chip relative to a rotational symmetry center according to Embodiment 12 of the present invention;

FIG. 13-11 is a schematic diagram of a first light-emitting unit including three LED chips according to Embodiment 12 of the present invention;

FIG. 13-12 is a schematic diagram of a second light-emitting unit including three LED chips according to Embodiment 12 of the present invention;

FIG. 13-13 is a schematic diagram of a third light-emitting unit including three LED chips according to Embodiment 12 of the present invention;

FIG. 13-14 is a schematic diagram of a fourth light-emitting unit including three LED chips according to Embodiment 12 of the present invention;

FIG. 13-15 is a schematic diagram of a fifth light-emitting unit including three LED chips according to Embodiment 12 of the present invention;

FIG. 13-16 is a schematic diagram of a first light-emitting unit including four LED chips according to Embodiment 12 of the present invention;

FIG. 13-17 is a schematic diagram of a second light-emitting unit including four LED chips according to Embodiment 12 of the present invention;

FIG. 13-18 is a schematic diagram of a third light-emitting unit including four LED chips according to Embodiment 12 of the present invention;

FIG. 13-19 is a schematic diagram of a fourth light-emitting unit including four LED chips according to Embodiment 12 of the present invention;

FIG. 14-1 is a schematic structural diagram 1 of a display module according to Embodiment 13 of the present invention;

FIG. 14-2 is a schematic structural diagram 2 of a display module according to Embodiment 13 of the present invention;

FIG. 14-3 is a schematic structural diagram 3 of a display module according to Embodiment 13 of the present invention;

FIG. 14-4 is a schematic structural diagram 4 of a display module according to Embodiment 13 of the present invention;

FIG. 14-5 is a schematic structural diagram 5 of a display module according to Embodiment 13 of the present invention;

FIG. 14-6 is a schematic structural diagram 6 of a display module according to Embodiment 13 of the present invention;

FIG. 14-7 is a schematic structural diagram 7 of a display module according to Embodiment 13 of the present invention;

FIG. 14-8 is a schematic structural diagram of a blind hole of a substrate according to Embodiment 13 of the present invention;

FIG. 14-9 is a schematic structural diagram 1 of a display screen according to Embodiment 13 of the present invention;

FIG. 14-10 is a schematic structural diagram 2 of a display screen according to Embodiment 13 of the present invention;

FIG. 15-1 is a schematic structural diagram 1 of a display module according to Embodiment 14 of the present invention;

FIG. 15-2 is a schematic structural diagram 2 of a display module according to Embodiment 14 of the present invention;

FIG. 15-3 is a schematic structural diagram 3 of a display module according to Embodiment 14 of the present invention;

FIG. 15-4 is a schematic structural diagram 4 of a display module according to Embodiment 14 of the present invention;

FIG. 15-5 is a schematic structural diagram 5 of a display module according to Embodiment 14 of the present invention;

FIG. 15-6 is a schematic structural diagram 6 of a display module according to Embodiment 14 of the present invention;

FIG. 16-1 is a structural top view of a packaging layer according to Embodiment 15 of the present invention;

FIG. 16-2 is a schematic diagram 1 of an A5-A5 cross-section of a packaging layer according to Embodiment 15 of the present invention;

FIG. 16-3 is a schematic diagram 2 of an A5-A5 cross-section of a packaging layer according to Embodiment 15 of the present invention;

FIG. 16-4 is a schematic diagram 3 of an A5-A5 cross-section of a packaging layer according to Embodiment 15 of the present invention;

FIG. 16-5 is a schematic diagram 4 of an A5-A5 cross-section of a packaging layer according to Embodiment 15 of the present invention;

FIG. 16-6 is a structural top view of a packaging layer covering a substrate according to Embodiment 15 of the present invention;

FIG. 16-7 is a schematic diagram 1 of an A6-A6 cross-section of a packaging layer covering a substrate according to Embodiment 15 of the present invention;

FIG. 16-8 is a schematic diagram 2 of an A6-A6 cross-section of a packaging layer covering a substrate according to Embodiment 15 of the present invention;

FIG. 16-9 is a schematic diagram 3 of an A6-A6 cross-section of a packaging layer covering a substrate according to Embodiment 15 of the present invention;

FIG. 16-10 is a schematic diagram of an A6-A6 cross-section of a packaging layer covering a substrate and after press-fit according to Embodiment 15 of the present invention;

FIG. 16-11 is a schematic diagram 4 of an A6-A6 cross-section of a packaging layer covering a substrate according to Embodiment 15 of the present invention;

FIG. 16-12 is a schematic diagram of an A6-A6 cross-section of a packaging layer covering a substrate and after press-fit according to Embodiment 15 of the present invention;

FIG. 16-13 is a schematic structural diagram of a rectangular window on a black adhesive layer according to Embodiment 15 of the present invention;

FIG. 16-14 is a schematic structural diagram of a rectangular window of a packaging layer with a long side provided with a protruding portion according to Embodiment 15 of the present invention;

FIG. 16-15 is another schematic structural diagram of a rectangular window of a packaging layer with a long side provided with a protruding portion according to Embodiment 15 of the present invention;

FIG. 16-16 is another structural top view of a packaging layer covering a substrate according to Embodiment 15 of the present invention;

FIG. 16-17 is a diagram of an A7-A7 cross-section in FIG. 16-16 according to Embodiment 15 of the present invention;

FIG. 16-18 is a structural top view of a manufactured display module according to Embodiment 15 of the present invention;

FIG. 16-19 is a diagram 1 of an A8-A8 cross-section in FIG. 16-18 according to Embodiment 15 of the present invention; and

FIG. 16-20 is a diagram 2 of an A8-A8 cross-section in FIG. 16-18 according to Embodiment 15 of the present invention.

### DETAILED DESCRIPTION

For ease of understanding the present invention, the present invention is described more comprehensively below with reference to the accompanying drawings. The accompanying drawings show exemplary embodiments of the present invention. However, the present invention may be implemented in many different forms, and is not limited to the embodiments described in this specification. On the contrary, the embodiments are provided to make understanding of the disclosed content of the present invention more comprehensive.

Unless otherwise defined, meanings of all technical and scientific terms used in this specification are the same as those usually understood by a person skilled in the art to which the present invention belongs. In the present invention, terms used in the specification of the present invention are merely intended to describe objectives of the specific embodiments, but are not intended to limit the present invention.

It should be noted that in this specification, claims, and accompanying drawings of the present invention, the terms “first”, “second”, and so on are intended to distinguish similar objects but do not necessarily indicate a specific order or sequence. It should be understood that such data used in this way can replace each other in an appropriate situation for describing the embodiments of the present invention herein. In addition, terms “include” and “have” and any of their variations are intended to cover nonexclusive inclusion, for example, a process, method, system, product, or device that includes a series of steps or units does not have to be limited to those clearly listed steps or units, but may include another step or unit that is not clearly listed or is inherent to the process, method, product, or device.

In the present invention, orientation or position relationships indicated by the terms such as “upper”, “lower”, “inner”, “middle”, “outer”, “front”, and “back” are based on orientation or position relationships shown in the accompanying drawings. The terms are used mainly for better describing the present invention and the embodiments thereof, rather than indicating that the mentioned apparatus, element, or component needs to have a particular orientation or needs to be constructed and operated in a particular orientation. In addition, some of the foregoing terms may be further used for representing other meanings in addition to an orientation or a position relationship. For example, the term “upper” may alternatively be used for representing an attachment relationship or a connection relationship in some cases. A person of ordinary skill in the art may understand the specific meanings of the terms in the present invention according to specific situations. In addition, terms such as “arrangement”, “connection”, and “fixation” shall be understood in a broad sense. For example, “connection” may be a fixed connection, a detachable connection, or an integral connection; may be a mechanical connection or an electrical connection; or may be a direct connection, an indirect connection by using an intermediate medium, or internal communication between two apparatuses, elements, or components. A person of ordinary skill in the art may understand the specific meanings of the foregoing terms in the present invention according to specific situations.

It should be noted that the embodiments in the present invention and features in the embodiments may be mutually combined in case that no conflict occurs. The present invention is described in detail in the following with reference to the accompanying drawings by using embodiments.

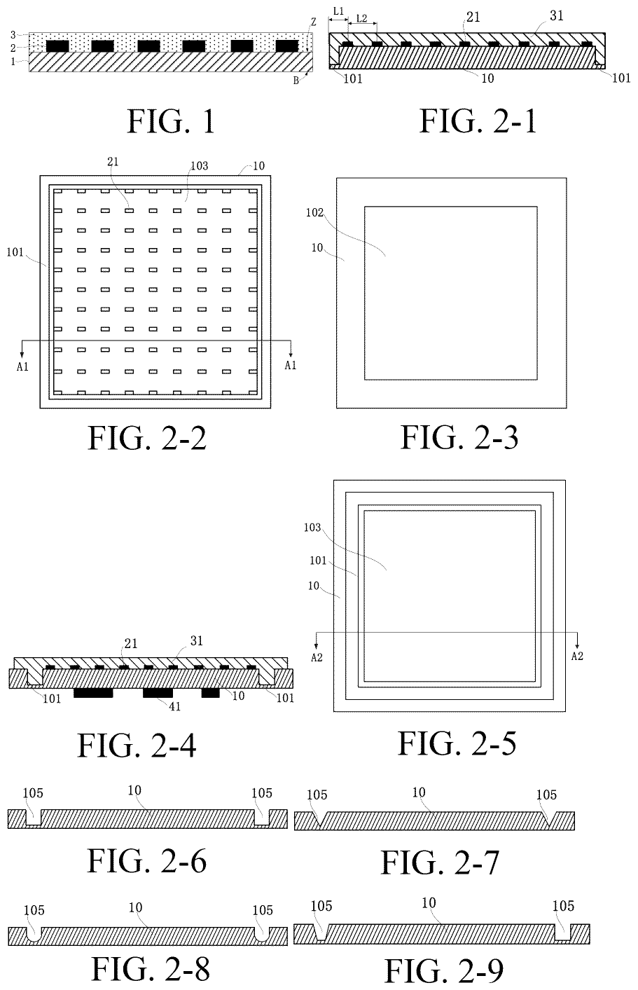

The present invention provides a display module and an LED device, applicable to various fields such as household display, medical display, decoration display, transportation display, and advertisement display. For example, the display module is specifically applicable to various electronic devices, including but not limited to, a monitor, a mobile terminal, a computer, a wearable device, an advertisement device, and an in-vehicle device. As shown in FIG. 1, the display module includes a substrate 1, a plurality of light-emitting units 2, and a packaging layer 3, where:

The substrate 1 in the present invention may be used as a display backplane of the display module, or may be independent of a display backplane and be a bearing substrate used for bearing the light-emitting units. In addition, the substrate 1 may be a single-layer substrate or a composite substrate including at least two layers, and may be a flexible substrate or a rigid substrate, which is not limited in this embodiment. In FIG. 1, a surface shown by Z is a top surface of the substrate, a surface shown by B is a back surface of the substrate, and substrate side surfaces are located between the top surface of the substrate and the back surface of the substrate.

The light-emitting units 2 are arranged on the top surface of the substrate, one light-emitting unit 2 may include only one LED chip or two or more LED chips, and at least one of quantities of LED chips included in the light-emitting units 2 and light emission colors may be the same. Alternatively, at least one of quantities of LED chips included in some light-emitting units 2 and light emission colors may be different. The LED chips in the present invention may be micron-sized LED chips (for example, Mini LED chips or Micro LED chips), and may be, for example, micron-sized flip LED chips. Certainly, all or some of the LED chips may alternatively be replaced with micron-sized face-up or vertical LED chips, and certainly may alternatively be replaced with ordinary-sized LED chips according to a size requirement.

The packaging layer 3 is arranged on the substrate 1, to cover each light-emitting unit 2, and is configured to transmit light emitted by an LED chip of the light-emitting unit 2, and the packaging layer 3 has a thickness greater than a thickness of the light-emitting unit 2; the packaging layer 3 may be arranged on only the top surface of the substrate, and completely cover the top surface of the substrate, or may partially cover only the top surface of the substrate; the packaging layer 3 may alternatively extend from the top surface of the substrate to at least one side surface of the substrate, and even extend to the back surface of the substrate; and the packaging layer 3 may be a single-layer structure or a multi-layer structure including at least two layers.

It can be learned that the display module provided in the present invention may have a flexibly changeable structure and a wide range of applicable scenarios; and have a smaller whole thickness and lower costs while satisfying an air-tightness requirement. For ease of understanding, some changed specific structures of the display module and manufacturing methods therefor are exemplified below with reference to the following embodiments.

### Embodiment 1

In this embodiment, an LED chip included in each light-emitting unit may be directly arranged on the substrate through, but not limited to, COB (chip-on-board). The substrate may directly dissipate heat, which can reduce manufacturing process steps and costs, further has an heat dissipation advantage of reducing thermal resistance, can further display images and videos with higher resolution, and can perform arbitrary splicing. During COB packaging, an LED chip is soldered onto the substrate, then the packaging layer is arranged the substrate, and finally a process bezel on the edge of the substrate is cut away along a predetermined cutting edge, to obtain a unit board display module with a required size. In this display module, after the process edge is cut and removed, the LED chip is very close to a process cutting line, and moisture is very prone to entering the interior of the display module through an interface between the packaging layer and the substrate. As a result, the LED chip fails, and the packaging layer and the substrate are layered.

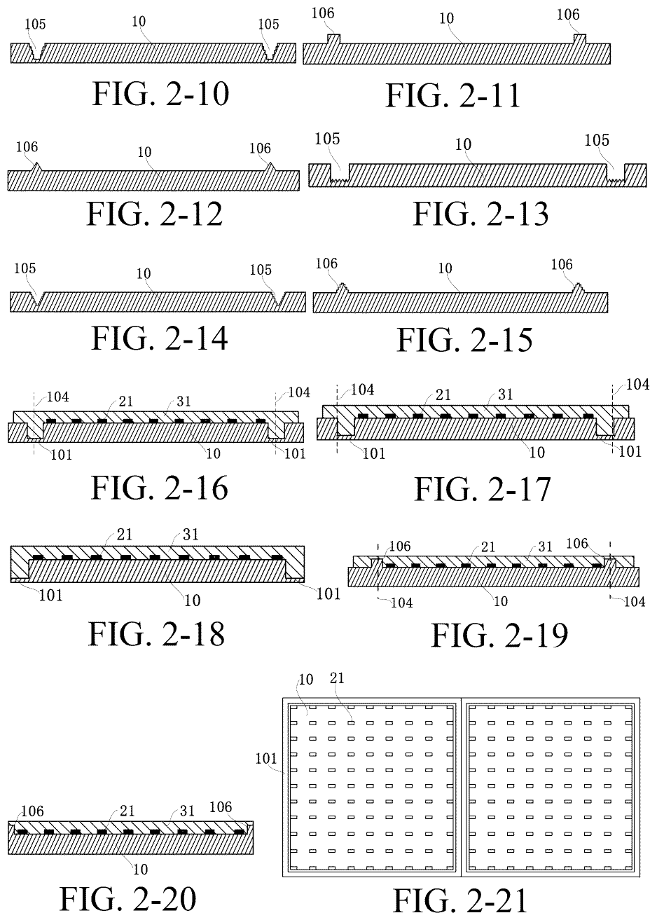

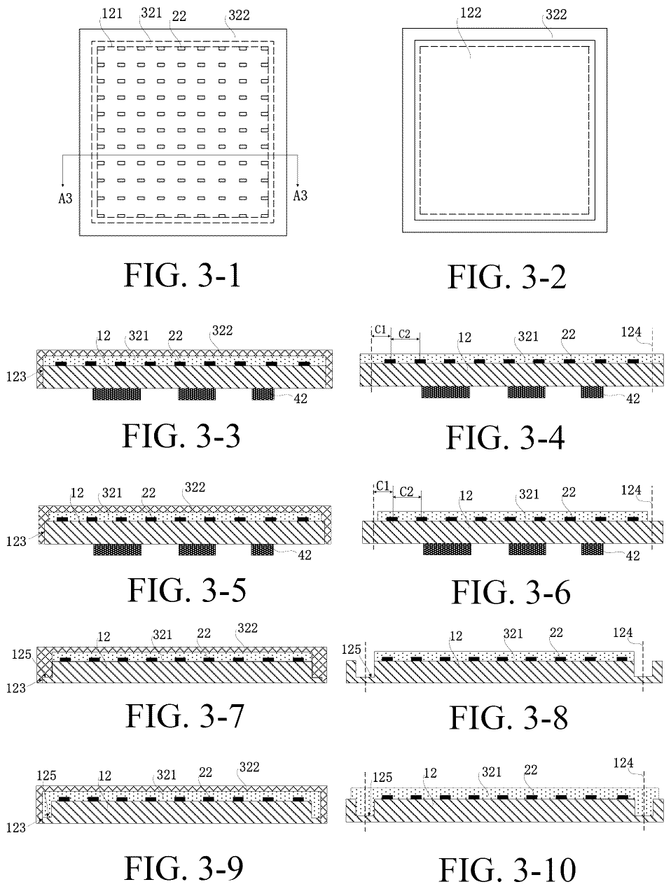

For the foregoing problem, this embodiment provides a display module. As shown in FIG. 2-1 to FIG. 2-3, FIG. 2-2 is a top view of the display module (for ease of understanding, the drawing is subject to perspective treatment); FIG. 2-1 is a cross-sectional view along A1-A1 in FIG. 2-2; and FIG. 2-3 is a bottom view of the display module. The display module in this embodiment includes a substrate 10, light-emitting units 21, and a packaging layer, and the packaging layer includes a first packaging layer 31. The substrate 10 includes a first mounting portion 103 located on a top surface of the substrate and a second mounting portion 102 located on a back surface of the substrate, and a path extension portion 101 located on the periphery of the first mounting portion 103. In this embodiment, the plurality of light-emitting units 21 are arranged on the first mounting portion 103 in an array (certainly, alternatively in another distribution manner, for example, a staggered arrangement between adjacent rows of light-emitting units 21 or a random distribution). The path extension portion 101 includes at least one of a protruding portion and a concave portion, the protruding portion protrudes from the top surface of the substrate, and the concave portion extends from the top surface of the substrate toward the back surface of the substrate. The first packaging layer 31 is arranged on the top surface of the substrate, to cover the path extension portion 101 and the light-emitting units 21. As shown in FIG. 2-1, a first distance L1 between an outer side surface of the path extension portion 101 and the center of a light-emitting unit 21 nearest to the outer side surface (that is, on the outer edge of the first mounting portion 103) (which is specifically a vertical distance from the outer side surface of the path extension portion 101 to a center point of the light-emitting unit 21) is less than half of a row pitch (which is specifically a distance between center axes of two adjacent rows of light-emitting units 21, where the center axis of each row of light-emitting units 21 is formed by a connection line between center points of the row of light-emitting units 21) L2 between two adjacent rows of light-emitting units 21 on the first mounting portion that are parallel to the outer side surface. Therefore, when a plurality of display modules are spliced to manufacture a display screen, a splicing seam between the display modules can be reduced. In addition, it is ensured that, after adjacent display modules are spliced, a pitch between the centers of the two adjacent rows of light-emitting units 21 at a splicing position is the same as a pitch L2 between two adjacent rows of light-emitting units 21 in another region on the substrate 10, or even is less than L2, thereby improving integrity between the spliced display modules and a display effect.

In addition, the arrangement of the path extension portion 101 may cause the interface between the first packaging layer 31 and the substrate 10 not to be a structure in a single straight line. Therefore, the path through which moisture enters the interior of the display module from the interface between the first packaging layer 31 and the substrate 10 can be extended, to avoid a case as much as possible that the light-emitting unit 21 fails because moisture enters, thereby improving reliability of the display module. In addition, the path extension portion 101 and the first packaging layer 31 are less prone to being layered, and the packaging effect is better.

It should be understood that the substrate 10 in this embodiment may be a PCB board, a glass substrate, a silicon substrate, or the like. The substrate 10 may be flexibly set in shape and size. For example, in some application examples, the thickness of the substrate 10 located between the first mounting portion 103 and the second mounting portion 102 may range, but not limited to, from 1.5 mm to 2.5 mm. The substrate 10 with this thickness better facilitates processing of the path extension portion 101, and the path extension portion 101 may extend the path of moisture in a thickness direction of the substrate. In addition, the substrate 10 may be a regularly shaped substrate such as a rectangular substrate, a circular substrate, a rhombic substrate, or a triangular substrate, or may be an irregularly shaped substrate.

It should be understood that the light-emitting unit 21 in this embodiment may include only one LED chip or a plurality of LED chips. For example, in some application examples, the light-emitting unit may include, but not limited to, a red light LED chip, a green light LED chip, and a blue light LED chip.

In this embodiment, as shown in FIG. 2-4, the second mounting portion 102 on the back surface of the substrate may be used for arranging an electronic driving circuit, and a driving element 41 electrically connected to the electronic driving circuit and used for driving the light-emitting unit 21, the light-emitting unit 21 may be flexibly controlled according to a specific display mode or display requirement through the driving element 41, thereby controlling display of the display module. The driving element 41 in this embodiment may include, but not limited to, a driving chip, and the driving chip may be a driving bare chip or a driving chip obtained after a driving bare chip is packaged.

In this embodiment, the path extension portion 101 is in a ring-shaped structure around the periphery of the first mounting portion 103. Certainly, it should be understood that the path extension portion 101 in this embodiment is not limited to being arranged in a ring-shaped structure. Alternatively, the path extension portion 101 may be arranged on only one or more edges of the first mounting portion 103, but a closed ring-shaped structure is not defined. The path extension portion 101 in this embodiment includes at least one of a protruding portion 106 protruding from the top surface of the substrate and a concave portion extending from the top surface of the substrate toward the back surface of the substrate.

In this embodiment, the first packaging layer 31 may be molded on the substrate 10 through, but not limited to, mold-pressing, printing, hot-pressing, or another manner, or may be molded on the substrate 10 through potting, and a specific setting process thereof is not limited. It should be understood that in this embodiment, the material of the first packaging layer 31 may be flexibly set. For example, the material may be, but not limited to, an adhesive layer, and the adhesive layer may be a transparent adhesive layer or a mixed adhesive layer containing light conversion particles (for example, fluorescent powder) and/or diffusion particles. In addition, the first packaging layer 31 in this embodiment may be set as a single-layer structure or set as a multi-layer structure according to a requirement. In some examples, an upper surface of the first packaging layer 31 may be set as a plane or a curved surface according to a requirement.

In some application examples of this embodiment, the light-emitting units 21 are evenly distributed on the substrate 10, and the light-emitting units 21 are mounted in corresponding positions on the top surface of the substrate. In this case, pitches between adjacent light-emitting units 21 on the first mounting portion 103 are the same. In another application example, to improve heat dissipation performance of the display module, a pitch between light-emitting units 21 on the substrate 10 that are close to the driving element 41 may be set larger compared with a pitch between light-emitting units 21 far away from the driving element 41. In addition, to ensure evenness of light emission, a pitch between adjacent light-emitting units 21 may be set to gradually decrease from the middle to the edge of the substrate 10.

It should be understood that in this embodiment, the concave portion and/or the protruding portion 106 included in the path extension portion 101 may be flexibly set. For example, in some application examples, the path extension portion 101 may include only the concave portion extending from the top surface of the substrate toward the back surface of the substrate, and the concave portion may be a groove or a concave portion remaining after a part of a groove is cut away. In some other application examples, the path extension portion 101 may be the protruding portion 106 protruding from the top surface of the substrate. In still some other application examples, the path extension portion 101 may alternatively include both the concave portion and the protruding portion 106.

For ease of understanding, this embodiment is described below using several shapes of the path extension portion 101 as examples respectively.

An example is shown in FIG. 2-4 and FIG. 2-5. FIG. 2-4 is a cross-sectional view along A2-A2 in FIG. 2-5. In this example, the path extension portion 101 is a concave portion extending from the top surface of the substrate toward the back surface of the substrate, and the concave portion may be a complete groove. In this example, a groove may be first processed on an outer edge of the substrate 10 to form the path extension portion 101, and then the light-emitting units 21 and the first packaging layer 31 are arranged on the substrate 10. It should be understood that in this embodiment, the shape of the groove may be flexibly set. For example, as shown in FIG. 2-6, a groove 105 may be set as a square groove. As shown in FIG. 2-7, the groove may alternatively be set as a V-shaped groove. As shown in FIG. 2-8 and FIG. 2-9, the groove may alternatively be set as a U-shaped groove or trapezoidal groove. In addition, it should be understood that in this embodiment, the shape of the groove 105 is not limited to the foregoing several examples, and may be flexibly set in another regular shape according to a specific application requirement. For example, as shown in FIG. 2-10, the groove 105 may alternatively be set as a stepped groove. Certainly, the groove 105 in this embodiment may alternatively be set in an irregular shape. Details are not described herein again.

In this embodiment, when the path extension portion 101 is the concave portion, the specific size of the concave portion may be specifically set according to a row pitch between two adjacent rows of light-emitting units 21. When a row pitch between two adjacent rows of light-emitting units 21 is sufficiently large, the concave portion may include, but not limited to, a complete groove in at least one of the foregoing examples. When a row pitch between two adjacent rows of light-emitting units 21 is small, to ensure that a pitch between two adjacent rows of light-emitting units 21 at a splicing position is the same as a pitch L2 between two adjacent rows of light-emitting units 21 in another region on the substrate 10, or even is less than L2, the concave portion may be set as a concave portion remaining after a part of a complete groove is cut away. For example, an example is shown in FIG. 2-1 to FIG. 2-3. The path extension portion 101 is a concave portion remaining after a part of a groove is cut away. For example, the concave portion shown in FIG. 2-1 may be the concave portion obtained after the groove in FIG. 2-6 is cut according to a process cutting line 104 shown in FIG. 2-16. It may be learned from FIG. 2-16 that in this embodiment, a specific setting position (that is, cutting position) of the process cutting line 104 may be flexibly set according to an application requirement. For example, another example is shown in FIG. 2-17. The position of the process cutting line 104 shown in FIG. 2-17 is closer to the outer edge compared with FIG. 2-16. The display module obtained after cutting is shown in FIG. 2-18. It should be understood that in this embodiment, after the first packaging layer 31 is arranged on the substrate 10, the first packaging layer 31 is cut together with the substrate 10. Alternatively, the substrate 10 may be cut first, and then the first packaging layer 31 is arranged on the substrate 10.

Still another example is shown in FIG. 2-11 to FIG. 2-12. The path extension portion 101 is the protruding portion 106 protruding from the top surface of the substrate, and the protruding portion 106 may be one complete protrusion or a part remaining after one complete protrusion is cut away. For example, the protruding portion 106 shown in FIG. 2-11 is one complete rectangular protrusion, and the protruding portion 106 shown in FIG. 2-12 is one complete triangular protruding portion. Still another example is shown in FIG. 2-20. The protruding portion 106 is the protruding portion 106 remaining after a part of the rectangular protruding portion 106 shown in FIG. 2-11 is cut away. A cutting example is shown in FIG. 2-19. The shape of the protruding portion 106 in this embodiment may also be flexibly set, and is not limited to the shapes in the foregoing examples, or may be in a regular shape such as a curved protrusion or a trapezoidal protrusion or in another irregular shape.

It should be understood that in this embodiment, the path extension portion 101 is not limited to the concave portion and the protruding portion 106 shown in the foregoing examples; and may include both the concave portion and the protruding portion 106. In addition, in some examples of this embodiment, the quantity of concave portions included in the path extension portion 101 may be flexibly set according to a requirement. For example, in some examples, the path extension portion 101 may be one concave portion arranged on the substrate 10, thereby ensuring that a distance L1 between an outer side surface of the path extension portion 101 and a light-emitting unit 21 on an outer edge of the first mounting portion 103 is less than ½ of a minimum pitch between adjacent light-emitting units 21 on the first mounting portion 103. In some other examples, the path extension portion 101 may be one protruding portion 106 arranged on the substrate 10, or one protruding portion 106 and one concave portion arranged adjacent to each other on the substrate 10. In addition, sizes of the protruding portion 106 and the concave portion may be flexibly set while ensuring that a distance L1 between an outer side surface of the path extension portion 101 and a light-emitting unit 21 on an outer edge of the first mounting portion 103 is less than ½ of a minimum pitch between adjacent light-emitting units 21 on the first mounting portion 103.

The path extension portion 101 shown in each of the foregoing examples causes a contact interface between the first packaging layer 31 and the edge of the substrate 10 not to be a structure in a single straight line, thereby extending an intrusion path through which moisture enters the interior of the module from the edge of the contact interface between the first packaging layer 31 and the substrate 10, so that it is difficult for moisture to enter the interior of the display module, the path extension portion 101 and the first packaging layer 31 are less prone to being layered, and the packaging effect is better. In addition, it may be further ensured that a distance between an edge line of the display module and the display region is sufficiently small. When a plurality of display modules are spliced for display, a splicing seam between display modules may be reduced, a distance between the first mounting portions of the spliced display modules is shortened, and the display effect of the display screen is better. In addition, that L1 is less than ½ of L2 may ensure that the area of a non-display part on the display module located on the periphery of the first mounting portion 103 is sufficiently small, to reduce a splicing seam between display modules.

In still another example of this embodiment, when the path extension portion 101 includes the concave portion, the depth of the concave portion may be set to be greater than or equal to ½ of the pitch L2 between adjacent light-emitting units on the first mounting portion 103. The concave portion in such size may realize extension of the path, and may ensure the strength of the substrate 10 at the path extension portion 101. In an example, a ratio of the depth of the concave portion to the width of the first concave portion may be further set to, but not limited to, a range from 2 to 20, thereby further extending the path. Certainly, it should be understood that the foregoing size of the concave portion is not limited to the foregoing example, and may be further flexibly replaced with another size according to a specific application requirement. Details are not described herein again.

In still some other application examples of this embodiment, when the path extension portion 101 includes the protruding portion 106, the height by which the protruding portion 106 is higher than the top surface of the substrate may be set to be less than the height of the light-emitting unit 21 and/or less than the maximum thickness of the first packaging layer 31, thereby better helping the display module present a good display effect. In addition, optionally, in some applications, to prevent the protruding portion 106 from affecting light, a light reflection layer or refraction layer may be arranged on a surface of the protruding portion 106, thereby further improving the display effect.

In this embodiment, to further extend the path, and improve compactness of bonding between the first packaging layer 31 and the substrate 10, a surface of the path extension portion 101 may be set in an uneven shape, or a surface of the path extension portion 101 may be set as a rough surface. The setting of the uneven shape or rough surface may further extend the path, and improve the strength of bonding between the first packaging layer 31 and the path extension portion 101, to further prevent external moisture from entering. For ease of understanding, description is made below with reference to several examples in which the surface of the path extension portion 101 is in an uneven shape.

As shown in FIG. 2-13, the path extension portion 101 shown in the drawing is the groove 105, and certainly may alternatively be a concave portion remaining after a part of the groove is cut away. A bottom surface of the groove 105 is set in an uneven shape, and certainly at least one side surface of the groove 105 may alternatively be set in an uneven shape according to a requirement. For example, as shown in FIG. 2-14, a main difference of the drawing compared with FIG. 2-13 is that the groove 105 is a V-shaped groove, and each side surface of the groove 105 is set in an uneven shape.

As shown in FIG. 2-15, the path extension portion 101 shown in the drawing is a protruding portion 106, and a top surface and at least one side surface of the protruding portion 106 are in an uneven shape. It should be understood that a surface of the path extension portion 101 shown in other drawings in this embodiment may also be set in an uneven shape or as a rough surface, as shown in FIG. 2-13 to FIG. 2-15.

In this embodiment, the path extension portion 101 may be a complete ring-shaped structure surrounding the periphery of the first mounting portion 103, and the ring-shaped structure corresponds to a shape formed by the outer edge of the first mounting portion 103, and may be, but not limited to, a rectangular, polygonal, circular, or elliptical structure. In some application examples, the foregoing ring-shaped structure may alternatively be an incomplete ring-shaped structure formed by combining a plurality of segments. The path extension portion 101 may be one ring-shaped structure surrounding the first mounting portion 103, or may be a ring-shaped structure formed by a plurality of loops and surrounding the first mounting portion 103. When the path extension portion is formed by a plurality of loops, the process cutting line 104 is located on the path extension portion 101 in the outermost loop.

This embodiment further provides a display screen, and the display screen is a spliced display screen, which is formed by splicing at least two display modules shown in the foregoing examples, as shown in FIG. 2-21. It should be understood that the quantity of display modules used in this embodiment may be selected according to an application requirement. For example, two, three, four, five, or six or more display modules may be selected and spliced to obtain a display screen, the display modules of the display screen are less susceptible to intrusion of moisture, light-emitting units for display are less prone to failing, and the service life of the display screen is extended. In addition, in the display screen obtained by splicing the plurality of display modules, a splicing seam between the display modules is small, thereby improving the display effect of the display screen.

### Embodiment 2

In a display module, an LED chip on an edge is close to an edge of a substrate, and a packaging layer covers only a top surface of the substrate. As a result, moisture is very prone to entering the interior of the display module through an interface between the packaging layer and the substrate, thereby causing the LED chip to fail, and the packaging layer and the substrate are prone to being layered, thereby reducing reliability of the display module. For this problem, this embodiment further provides a structure example of another display module that can resolve the problem. In addition, it should be understood that the display module provided in this embodiment may be individually implemented independently of other embodiments.

An example of the display module provided in this embodiment is shown in FIG. 3-1 to FIG. 3-3. FIG. 3-1 is a top view of the display module (for ease of understanding, the drawing is subject to perspective treatment); FIG. 3-2 is a bottom view of the display module; and FIG. 3-3 is a cross-sectional view along A3-A3 in FIG. 3-1. As shown in the drawing, the display module in this example includes a substrate 12 and a plurality of light-emitting units 22, and the plurality of light-emitting units 22 are all mounted in a display region 121 arranged on a top surface of the substrate. In this embodiment, the display region 121 on the top surface of the substrate is a region provided with an element for the light-emitting units 22 to be electrically connected to drive and control the light-emitting units 22 to illuminate for display, and the region is further used for bearing the light-emitting units 22. For the quantity, light emission colors, sizes, and types of LED chips included in the light-emitting units 22 in this embodiment, and the material, shape, and size of the substrate 12, reference may be made to, but not limited to, the foregoing embodiments. Details are not described herein again.

A back surface of the substrate is provided with a wiring function region 122, and an electronic driving element 42 for driving and controlling the light-emitting units 22 is mounted on the wiring function region 122. A packaging layer covering all the light-emitting units 22 is arranged on the display region 121 on the top surface of the substrate, where the packaging layer includes a first packaging layer 321 covering the top surface of the substrate, and further includes a second packaging layer 322. The second packaging layer 322 covers the first packaging layer 321, and extends toward the back surface of the substrate to cover at least one part of a side surface 123 of the substrate 12, thereby covering a juncture of the first packaging layer 321 and the substrate 12, as shown in FIG. 3-3. Therefore, moisture can be prevented from entering the interior of the display module directly from the juncture of the first packaging layer 321 and the substrate 12. In addition, when moisture exists in the use environment, the moisture can extend to the juncture of the first packaging layer 321 and the substrate 12 only after passing through a bonding region between the second packaging layer 322 and the side surface 123 of the substrate 12. Therefore, a path through which the moisture intrudes into the interior of the display module can be extended, which can further better protect the light-emitting units 22, and can further improve reliability of the display module. It should be understood that in this embodiment, the size of the specific region of the side surface 123 of the substrate 12 covered by the second packaging layer 322 may be flexibly set according to an application requirement. For example, the second packaging layer 322 may cover only a part of the side surface 123 of the substrate 12, or the second packaging layer 322 may cover all side surfaces of the substrate 12, to further extend the path through which the moisture intrudes into the interior of the display module, and improve reliability of the display module.

It should be understood that in this embodiment, a specific forming manner of the first packaging layer 321 and the second packaging layer 322 may be, but not limited to, mold-pressing, printing, or potting, and is not limited herein. The first packaging layer 321 and the second packaging layer 322 are both light-transmitting layers, and may be both made of the same material (for example, may be both transparent adhesive layers) or different materials. In addition, the first packaging layer 321 and the second packaging layer 322 may both be single-layer structures, or at least one of the two may be set as a composite-layer structure formed by at least two sub-layers.

In some examples of this embodiment, at least one of light conversion particles and diffusion particles may be added in at least one of the first packaging layer 321 and the second packaging layer 322 according to a requirement. For example, in an application scenario, light conversion particles are included in the first packaging layer 321, to implement light color conversion, and diffusion particles are included in the second packaging layer 322, to further improve luminous efficiency.

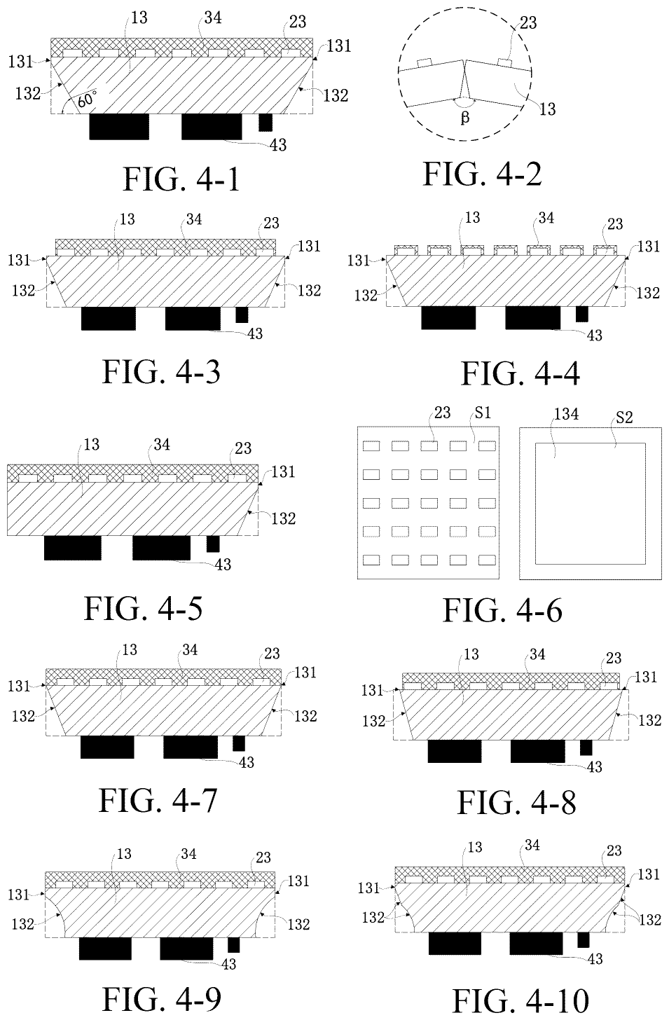

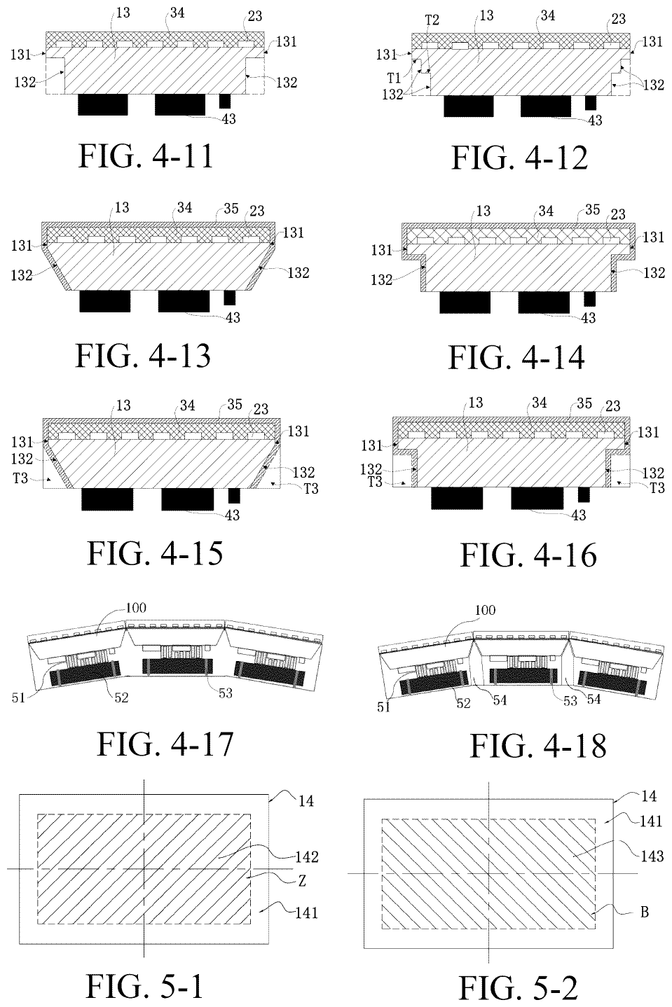

In some examples of this embodiment, light-emitting units 22 may be first arranged in the display region 121 on the top surface of the substrate, and then a first packaging layer 321 is formed on the top surface of the substrate, where the formed first packaging layer 321 may cover all of the top surface of the substrate. For example, as shown in FIG. 3-3, the first packaging layer 321 covers all of the top surface of the substrate. In addition, during manufacturing, as shown in FIG. 3-4, after light-emitting units 22 are arranged in the display region 121 on the top surface of the substrate, the first packaging layer 321 is formed on the top surface of the substrate, and then the substrate 12 and the first packaging layer 321 are cut along the process cutting surface 124, to obtain the substrate 12 and the first packaging layer 321 on the substrate 12 in FIG. 3-3.

In some other examples of this embodiment, the first packaging layer 321 may cover a part of the top surface of the substrate. For example, as shown in FIG. 3-5, the first packaging layer 321 covers only a display region 121 on the top surface of the substrate and light-emitting units 22 in the display region 121, and the second packaging layer 322 covers a region of the top surface of the substrate exposed from the first packaging layer 321. During manufacturing, as shown in FIG. 3-6, after light-emitting units 22 are arranged in the display region 121 on the top surface of the substrate, the first packaging layer 321 is formed on the top surface of the substrate, where the first packaging layer 321 does not cover all of a top surface 103 of the substrate 12, and then the substrate 12 and the first packaging layer 321 are cut along the process cutting surface 124, to obtain the substrate 12 and the first packaging layer 321 on the substrate 12 in FIG. 3-5.

Certainly, it should be understood that in this embodiment, the region of the substrate 12 covered by the first packaging layer 321 may be flexibly set according to an application requirement, and is not limited to the case in the foregoing example. Details are not described herein again. In addition, in the foregoing example of this embodiment, the first packaging layer 321 and the substrate 12 are first cut, and then the second packaging layer 322 is molded. The molded second packaging layer 322 extends toward the side surface 123 of the substrate 12, and completely or partially covers the side surface 123 of the substrate 12. The light-emitting units 22 may be protected through the first packaging adhesive layer, to prevent dust and the like during cutting from affecting the light-emitting units 22, and further improve reliability of the manufactured display module. The second packaging layer 322 protects the first packaging layer 321 and the light-emitting units 22, and moisture can enter the display region 121 of the display module only after passing through the interface between the second packaging layer 322 and the side surface 123 of the substrate 12 and the interface between the first packaging layer 321 and the top surface of the substrate, to extend the path through which the moisture intrudes into the interior of the display module and protect the light-emitting units 22 better, so that the light-emitting units 22 are less prone to failing, to improve reliability of the display module.

It may be learned from FIG. 3-4 or FIG. 3-6 that the first packaging layer 321 may cover the process cutting surface 124 of the substrate 12 and even exceed the process cutting surface 124, and may alternatively not exceed the process cutting surface 124. The cut side surface of the first packaging layer 321 may be flush with or not be flush with the side surface 123 of the substrate 12. As shown in FIG. 3-6, the side surface of the first packaging layer 321 may alternatively be located within the process cutting surface 124 of the substrate 12, a length of the first packaging layer 321 is less than a length of the substrate 12, parts of the edges of two sides of the top surface of the substrate extend, and next the second packaging layer 322 is then molded to enable the second packaging layer 322 to cover the exposed part on the edge of the top surface of the substrate and completely or partially cover the side surface 123 of the substrate 12.

In an example, to further extend the path through which the moisture intrudes into the interior of the display module, a concave portion 125 may be further arranged on the periphery of the display region 121 of the substrate 12, and compared with a plane structure, the arrangement of the concave portion 125 can further extend the path through which the moisture intrudes into the interior of the display module. The concave portion 125 in this embodiment may be one complete groove, and may alternatively be a concave portion formed after a part of a groove is cut away, which may be specifically flexibly set according to an application requirement.

For example, an example is shown in FIG. 3-7. A concave portion 125 is arranged on the periphery of the display region 121 on the top surface of the substrate, and the concave portion 125 is a concave portion formed after a part of a groove is cut away. For example, as shown in FIG. 3-8, a groove may be arranged on the periphery of the display region 121 on the substrate 12, and then is cut along the process cutting surface 124. After the cutting, a remaining part of the groove forms a concave portion 125 on the edge of the substrate 12, so that the side surface 123 of the substrate 12 forms a stepped structure. In this case, the contact area between the first packaging layer 321 or the second packaging layer 322 and the substrate 12 is increased, which can also extend the path through which the moisture enters from the interface between the packaging adhesive layer and the substrate 12, so that the packaging effect of the display module is better. In FIG. 3-7, the path through which the moisture intrudes is: from an interface between the second packaging layer 322 and the side surface 123 of the substrate 12, to an interface between the second packaging layer 322 and a groove bottom and a groove wall of the concave portion 125, then to an interface between the first packaging layer 321 and the top surface of the substrate, to realize the extension of the path through which the moisture intrudes.

In this embodiment, the depth of the concave portion 125 may be flexibly set. For example, the depth may be set to, but not limited to, a range from 0.1 to 0.9 times the thickness of the substrate 12. It may be understood that the depth of the concave portion 125 is a distance between the bottom and the concave portion 125 and the top surface of the substrate. That a larger depth of the concave portion 125 is set indicates that the path through which the moisture enters from the interface between the second packaging layer 322 and the substrate 12 is extended more.

In this embodiment, the first packaging layer 321 may cover the concave portion 125 on the substrate 12, and may alternatively not cover the concave portion 125 on the substrate 12. For example, as shown in FIG. 3-7, the first packaging layer 321 does not cover the concave portion 125 on the substrate 12. When the display module shown in FIG. 3-7 is manufactured, as shown in FIG. 3-8, the first packaging layer 321 may be first formed on the top surface of the substrate 12, but the first packaging layer 321 does not cover the groove. Then, cutting is performed along the process cutting surface 124, the substrate 12 and the first packaging layer 321 shown in FIG. 3-7 are obtained after the cutting, and then the second packaging layer 322 is formed on the substrate 12, where the second packaging layer 322 covers all of the concave portion 125.

For another example, as shown in FIG. 3-9, the first packaging layer 321 covers the concave portion 125 on the substrate 12. When the display module shown in FIG. 3-9 is manufactured, as shown in FIG. 3-10, the first packaging layer 321 may be first formed on the top surface of the substrate, and the first packaging layer 321 covers the groove. Then, cutting is performed along the process cutting surface 124, the substrate 12 and the first packaging layer 321 shown in FIG. 3-9 are obtained after the cutting, and then the second packaging layer 322 is formed on the substrate 12, where the second packaging layer 322 does not cover the concave portion 125. In FIG. 3-9, the path through which the moisture intrudes is: from an interface between the second packaging layer 322 and the side surface 123 of the substrate 12, to an interface between the first packaging layer 321 and a groove bottom and a groove wall of the concave portion 125, then to an interface between the first packaging layer 321 and the top surface of the substrate, which can also realize extension of the path through which the moisture intrudes.

Certainly, this embodiment is not limited to arranging the second concave portion 125 to extend the path through which the moisture enters. Alternatively, the concave portion 125 may be replaced with a boss or replaced with a combination of the concave portion and a boss (that is, replaced with an uneven structure). To further extend the path through which the moisture enters, a surface of the concave portion 125 or the boss may be further set as a rough surface, for example, may be set as a stepped surface or a zigzag surface, which can further extend the path through which the moisture enters, and can further improve the bonding strength between the packaging adhesive layer and the substrate 12. In this embodiment, when the concave portion 125 is replaced with a boss or replaced with a combination of the concave portion and a boss, the boss may be set to be not higher than the light-emitting surface of the light-emitting unit 22, thereby preventing the boss from blocking or causing other interference to the light emitted from the light-emitting surface of the light-emitting unit 22, to ensure the light-emitting effect. Certainly, in some other examples of this embodiment, the boss may alternatively be set to be higher than the light-emitting surface of the light-emitting unit 22, thereby blocking at least a part of the light emitted from the light-emitting surface of the light-emitting unit 22. When a plurality of display modules are spliced to form a display screen, a case that optical crosstalk occurs between adjacent display modules can be avoided to some extent.

In this embodiment, the refractive index of the first packaging layer 321 is greater than or equal to the refractive index of the second packaging layer 322. Therefore, the luminous efficiency of the light-emitting unit 22 can be improved, and the display effect of the display module is better. For example, in some application scenarios, the refractive index of the first packaging layer 321 may be selected from a range from 1.50 to 1.58, and the refractive index of the second packaging layer 322 may be selected from a range from 1.50 to 1.52.

When at least two display modules are spliced for display, the distance C1 between the predetermined process cutting surface 124 in the foregoing examples in FIG. 3-4, FIG. 3-6, FIG. 3-7, and FIG. 3-10 and the light-emitting unit 22 on the extreme edge on the substrate 12 may be less than half of the row pitch C2 between adjacent rows of light-emitting units 22. In this case, it may be ensured that the splicing seam is sufficiently small, and it may be ensured that a distance between an edge line of the display module and the display region is sufficiently small. After a plurality of display modules are spliced for display, a splicing seam between display modules may be reduced, so that and the integrity and the display effect of the display screen are better. When an individual display module is used for display, the distance between the process cutting surface 124 and the light-emitting unit 22 on the extreme edge on the substrate 12 is not specifically limited in this embodiment as long as the distance can achieve a good display effect.

To achieve a better seal effect, the second packaging layer 322 may further extend to the back surface of the substrate along the side surface 123 of the substrate 12, so that the second packaging layer 322 covers the side surface 123 of the substrate 12 and the back surface of the substrate. Therefore, no moisture intrusion opening exists on the side surface 123 of the substrate 12, and the seal effect of the display module is better.

This embodiment further provides a display screen, and the display screen includes a display module shown in the foregoing examples. In an application example, only one of the foregoing display modules may be used for manufacturing a display screen. In another example, at least two display modules may be spliced to obtain a spliced display screen. A splicing effect in an example is shown in FIG. 2-21. The display modules of the display screen are less susceptible to intrusion of moisture, and the display modules are less prone to failing, to ensure a good display effect of the display screen and extend the service life of the display screen. In addition, when a plurality of display modules are spliced for display, a splicing seam is also small, and the display effect is better.

### Embodiment 3

A typical application scenario of display modules is to splice a plurality of display modules together to form one large display screen for display. Because of having specific thicknesses and rigidities, the display modules are easily spliced with no seam or a small seam when being spliced in a two-dimensional plane. However, in some special application scenarios, a plurality of display modules need to be spliced into a curved surface structure. In this case, an obvious splicing seam inevitably exists between the plurality of display modules. Particularly, when the curvature of the spliced curved surface is larger, the splicing seam also becomes larger, which greatly affects the continuity and the sensory effect of pictures.

For the foregoing problem, this embodiment provides a display module and a substrate for the display module. In addition, it should be understood that the display module and the substrate in this embodiment may be individually implemented independently of other embodiments. For ease of understanding, the substrate and the display module manufactured using the substrate are exemplified below in this embodiment.

The substrate provided in this embodiment may be used for bearing and arranging light-emitting units. For example, the light-emitting units may be arranged on a top surface of the substrate; and the top surface of the substrate is further used for bearing a packaging layer, and the packaging layer in this embodiment includes a packaging layer arranged on the top surface of the substrate and covering the light-emitting units. At least one side surface of the substrate is a spliced side surface spliced with a substrate of another display module, a region of the spliced side surface close to a back surface of the substrate is contracted to form an avoidance region, and a region of the spliced side surface close to the top surface of the substrate is used as a spliced region. When two substrates spliced to back surfaces of the two substrates through a spliced region are at a preset angle greater than 0° and less than 180°, avoidance regions of spliced side surfaces of the two substrates do not interfere with each other. It should be noted that not interfering with each other by the avoidance regions may be not contacting each other, and may alternatively be contacting each other but not interfering with each other. When the avoidance regions do not contact each other, a specific gap is formed between the avoidance regions. When the two substrates are spliced through the spliced side surfaces, the spliced regions of the two substrates are close to each other and are spliced, and the back surfaces of the two substrates may be spliced at an angle less than 180°. A visual effect viewed on the top surfaces of the substrates is that the spliced regions slightly protrude outward. Because the avoidance regions are present and the avoidance regions are formed by contracting regions close to the back surface of the substrates, the back surfaces of the two substrates may be closer. Therefore, the spliced regions of the two substrates are closer, and a splicing seam formed between the spliced regions of the two substrates becomes smaller. For example, FIG. 4-1 is a schematic cross-sectional view of a display module manufactured using the substrate according to this embodiment. Light-emitting units 23 are arranged on a top surface of the substrate, a packaging layer 34 completely covers a top surface region of the substrate 13 while covering the light-emitting units 23 on the top surface of the substrate 13, an electronic driving element 43 is arranged on a back surface of the substrate, and a left side surface and a right side surface of the substrate 13 are spliced side surfaces. When the substrate 13 is spliced with a substrate of another display module, a spliced region 131 close to the top surface of the substrate and a spliced region corresponding to the substrate of the another display module are spliced, and a region close to the back surface of the substrate is contracted to form an avoidance region 132 which does not contact the substrate of the another display module. It should be noted that when the two substrates are spliced, regions closest to two visible backplanes are viewed from the top surfaces of the substrates, and a splicing seam is formed between avoidance regions 132. The spliced side surface of the substrate 13 may be formed in a manner including, but not limited to, cutting, tailoring, or machining, and a dashed line part shown in FIG. 4-1 is a part that is cut away.

It should be noted that FIG. 4-2 is a locally enlarged schematic diagram of splicing two substrates shown in FIG. 4-1. In the drawing, β is an angle between back surfaces of the two substrates, the angle is an angle formed when the two substrates are spliced, and a person skilled in the art may set the angle according to an actual case and a requirement. For example, in this embodiment, the angle β may be set to 160°, 85°, 60°, or the like, and may be any angle greater than 0° and less than 180°, and a specific value of the angle is not limited in the present invention.

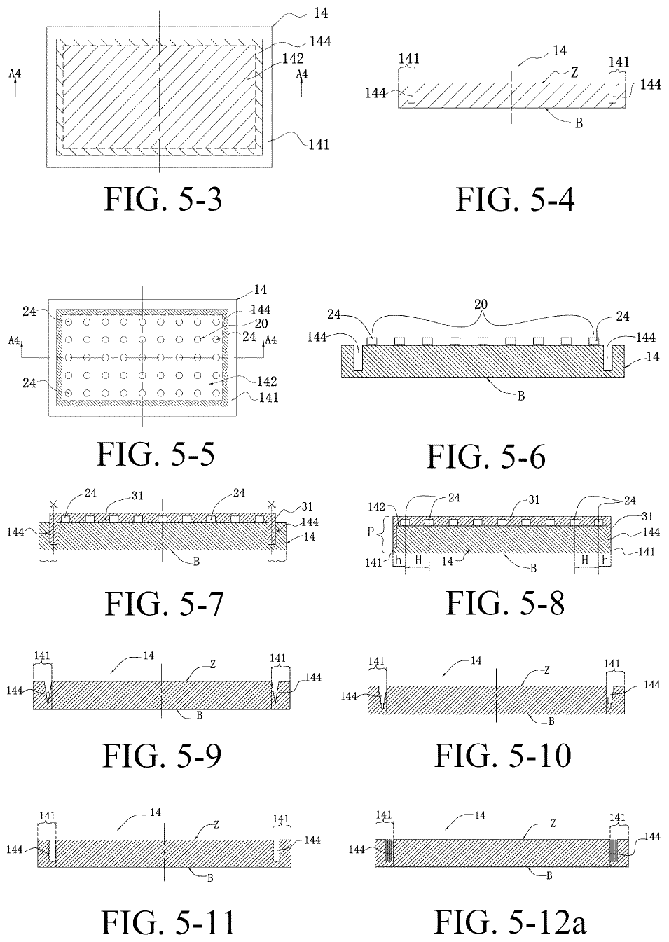

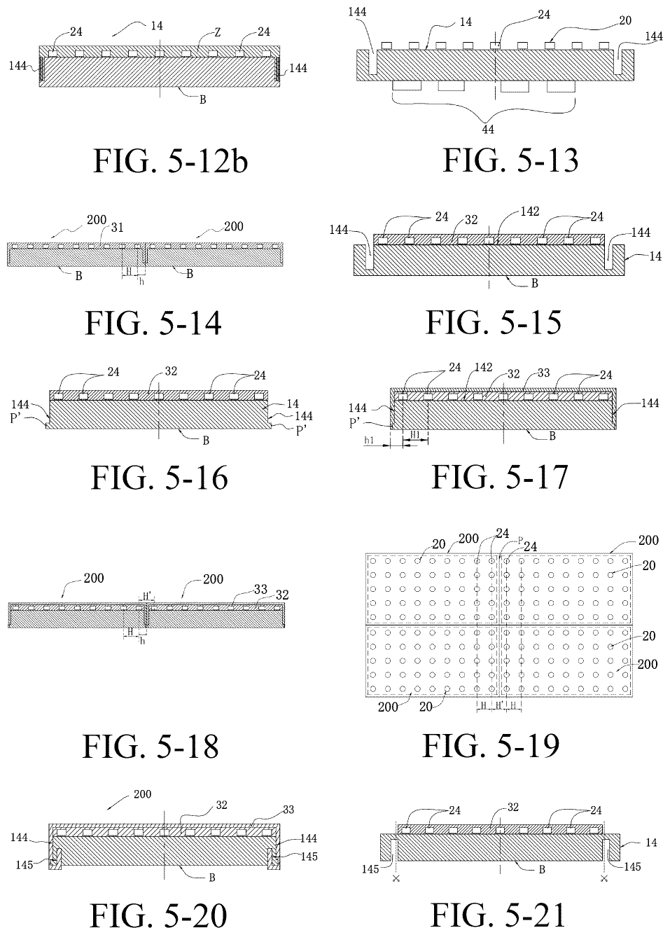

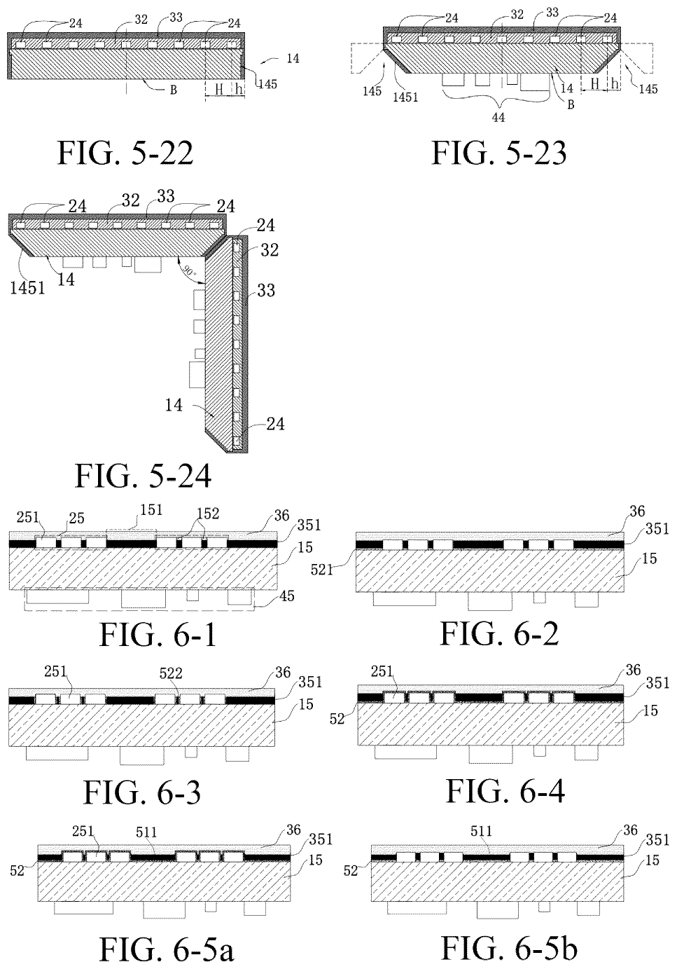

In some examples, the packaging layer 34 further includes a covered region shown in FIG. 4-3 or FIG. 4-4. The thickness of the packaging layer 34 may be controlled in a range from 150 microns to 300 microns. For example, the thickness may be 150 microns. A packaging layer 34 shown in FIG. 4-3 covers all light-emitting units 23 to form a whole, and a packaging layers 34 shown in FIG. 4-4 individually covers each light-emitting unit 23. Certainly, the two arrangement manners may alternatively be combined, which is not limited in this embodiment. It may be understood that in some examples, one, two, three, or four spliced side surfaces of a substrate 13 may be set according to a requirement. For example, a substrate 13 shown in FIG. 4-5 includes only one spliced side surface. The substrate 13 provided in this embodiment is particularly applicable to splicing of thick substrates, and the effect is more obvious. When curved surfaces of a plurality of display modules are spliced, continuity of pictures displayed after splicing and user experience can be greatly improved.

It should be noted that in this embodiment, lines on the top surface of the substrate and the back surface of the substrate are designed as follows: a line layout area S1 on the top surface of the substrate is greater than or equal to an area S2 of a wiring function region 134 on the back, and S1:S2=1.1 to 1.5, as shown in FIG. 4-6. For example, in an example, S1:S2=1.5. For the material of the substrate in this embodiment, reference may be made to, but not limited to, the foregoing embodiments. Details are not described herein again.

In some examples, the avoidance region 132 of the substrate 13 is contracted into an inclined surface. The inclined surface may be a plane, a curved surface, or a combination of a plane and a curved surface. When being a plane, the inclined surface may be the structure shown in FIG. 4-1. In some application scenarios, a case that the inclined surface is a plane may alternatively be shown in FIG. 4-7 or FIG. 4-8. As shown in FIG. 4-7, the inclined surface is chamfered at an intersection line of the back surface of the substrate and a side surface, and is just cut until an intersection line of the top surface of the substrate and the side surface. As shown in FIG. 4-8, the inclined surface is chamfered at an intersection line of the back surface of the substrate and a side surface, and an intersection line of the top surface of the substrate and the side surface is completely cut away. When the inclined surface is a curved surface, as shown in FIG. 4-9, the inclined surface is a structure in an arc shape, and the avoidance region close to the back surface of the substrate is cut into one arc shape. When the inclined surface is a combination of a plane and a curved surface, as shown in FIG. 4-10, the inclined surface is a structure in a combination of a plane and a curved surface, and the avoidance region close to the back surface of the substrate is cut into a shape of a combination of an inclined surface and a curved surface. It should be noted that an inclined surface in an arc shape or a combination of an inclined surface and an arc shape further includes two other cutting manners similar to that in a case that the inclined surface is a plane. Details are not described again in this embodiment. Besides, when a plurality of spliced side surfaces exist on the substrate 13, at least one of shapes and sizes of avoidance regions 132 on the spliced side surfaces may be the same or different, to adapt to different splicing requirements.

In some examples, the avoidance region 132 of the substrate 13 may alternatively be contracted into a stepped surface. As shown in FIG. 4-11, the avoidance region 132 close to the back surface of the substrate is cut into one rectangle, and the area of the rectangle may be set by a person skilled in the art according to an actual case and a requirement. It should be noted that the avoidance region 132 being a stepped surface may alternatively include at least two stepped surfaces. As shown in FIG. 4-12, the avoidance region close to the back surface of the substrate is cut into a stepped shape including a stepped surface T1 and a stepped surface T2, and the quantity of stepped surfaces may be set by a person skilled in the art according to an actual case and a requirement.

In the examples shown in FIG. 4-7 to FIG. 4-12, each avoidance region 132 may be formed by removing a region defined by dashed lines from the substrate 13.

In some examples, when the avoidance region 132 is an inclined surface, an inclination angle of the inclined surface may be set to be greater than or equal to 5° and less than or equal to 60°. A specific inclination angle may be set according to an actual case and a requirement. For example, as shown in FIG. 4-1, the inclination angle of the inclined surface is set to 60°, and certainly may alternatively be set to 5°, 10°, 30°, 45°, 50°, or the like according to a requirement.

In some examples, the top surface of the substrate and the back surface of the substrate may be both set to be rectangular, and one, two, three, or four of four side surfaces of the substrate are spliced side surfaces.

In this embodiment, the packaging layer of the display module may further include a packaging layer covering the packaging layer 34. For example, in an example, referring to FIG. 4-13, a packaging layer 35 is added to the display module based on the display module shown in FIG. 4-1. For another example, another example is shown in FIG. 4-14. A packaging layer 35 is added to the display module based on the display module shown in FIG. 4-11. In the foregoing examples, the packaging layer 35 covers all of the packaging layer 34 and the spliced side surface of the substrate 13, thereby improving air-tightness and reliability of the display module as a whole. In this case, an outer side surface of the packaging layer 35 is used as a new spliced side surface. Correspondingly, the packaging layer 35 has a part covering the spliced region 131 to serve as a new spliced region, and has a part covering the avoidance region 132 to serve as a new avoidance region. It should be understood that in some implementations, the packaging layer 35 may not cover the side surface of the substrate 13, or may cover a part of the side surface of the substrate 13 (for example, may cover only the spliced region 131).

When the display modules shown in FIG. 4-13 and FIG. 4-14 are manufactured, regions covered by the packaging layer 35 may include regions shown by T3 in FIG. 4-15 and FIG. 4-16, and then the parts are cut away to manufacture the display modules shown in FIG. 4-13 and FIG. 4-14 respectively. By arranging the packaging layer 35, the path through which the moisture enters the interior of the display module may be extended, to improve air-tightness of the display module, and the packaging layer 34 is uneasily separated from the substrate, to improve reliability of the display module.

This embodiment further provides a display apparatus, and the display apparatus includes at least two display modules spliced together and shown in the foregoing examples. A schematic diagram of a splicing effect is shown in FIG. 4-17. During splicing, display modules 12 may be connected through an adaptation member. In this embodiment, the adaptation member includes a plug-connection member 51 and an adaptation board 52. It should be noted that the plug-connection member 51 and the adaptation board 52 may be in detachable connection or non-detachable fixed connection, and may be connected through, for example, a fastening member, glue, or soldering, as long as the two can be connected. Then, the adaptation board 52 may be mounted and fixed at a required mounting place in a fixation manner including, but not limited to, a copper pillar 53, a screw, or soldering.

A display apparatus in still another example is shown in FIG. 4-18. Based on FIG. 4-17, when an angle between avoidance regions of spliced side surfaces of adjacent display modules is greater than 0°, an accommodating space exists between two spliced regions. In this case, connection between two substrates further includes a connection member 54, an embedding portion of the connection member 54 collaborates with the angle, to fill an accommodating space between the avoidance regions and contact the spliced regions, and the connection member 54 may play a role in reinforcing the display apparatus. In addition, when the display modules are mounted, it is convenient to quickly position the two substrates, to improve mounting efficiency, and a part of the connection member 54 in collaboration with the spliced regions may further play a role in supporting the spliced regions, so that the display modules are also supported on the spliced side surfaces, the structure is compact, and the strength is better.

### Embodiment 4

This embodiment provides a manufacturing method for a display module, and the manufacturing method may be used for, but not limited to, manufacturing a display module shown in the foregoing embodiments or may be individually implemented to manufacture a display module different from that shown in the foregoing embodiments. A manufactured display module may be individually used, or a plurality of manufactured display modules may be spliced together to form a large display screen.

The manufacturing method for a display module in an example of this embodiment includes the following steps:

Step a1: provide a substrate. The provided substrate 14 includes a top surface of the substrate Z (shown in FIG. 5-1), a back surface of the substrate B (shown in FIG. 5-2) opposite to the top surface of the substrate Z, and a process edge 141 located around the substrate 14, and a display region 142 (a region covered by inclined lines framed by dashed lines in FIG. 5-1) used for mounting light-emitting units is defined on the top surface of the substrate Z. In this embodiment, the substrate 14 is a rectangular substrate, and the top surface of the substrate Z and the back surface of the substrate B are both planes. In FIG. 5-1, the process edge 141 surrounds four side surfaces of the display region 142. In another embodiment, according to an actual case and a processing requirement, the process edge 141 may alternatively surround one or two opposite or adjacent side edges of the display region 142, which is not limited herein. In another embodiment, the substrate 14 may alternatively be another polygonal substrate, for example, a triangular substrate or a regular hexagonal substrate, which is not limited herein The top surface of the substrate Z may alternatively be presented as a regular or specially designed uneven surface, to create a special visual effect, for example, a wave-shaped effect or an embossed effect, and may be set according to a required presentation effect, which is not limited herein.

Step b1: as shown in FIG. 5-3 and FIG. 5-4, a groove 144 is cut around the process edge 141 close to (that is, on a border of the display region 142 and the process edge 141) the display region 142 (as shown by a region covered by an inclined line box around an outer side of a dashed line box region in FIG. 5-3, the groove 144 is located on a side of the process edge 141). The groove 144 does not run through the substrate 14 (shown in FIG. 5-4), and the depth of the groove 144 is greater than the thickness of a part of the substrate that is not run through. In this embodiment, the groove is a rectangular groove, and is perpendicular to the top surface of the substrate, making processing convenient. In another embodiment, as shown in FIG. 5-9, the groove 144 may alternatively be a “V”-shaped groove. In a range that the existing processing technique can satisfy, the shape of the groove 144 is not limited in this embodiment. For example, the shape may alternatively be a shape of an inverted trapezoid, a shape of U, or the like. The groove 144 may be formed by etching away, through machining, etching, or another method, a part in a position not blocked by a mask.

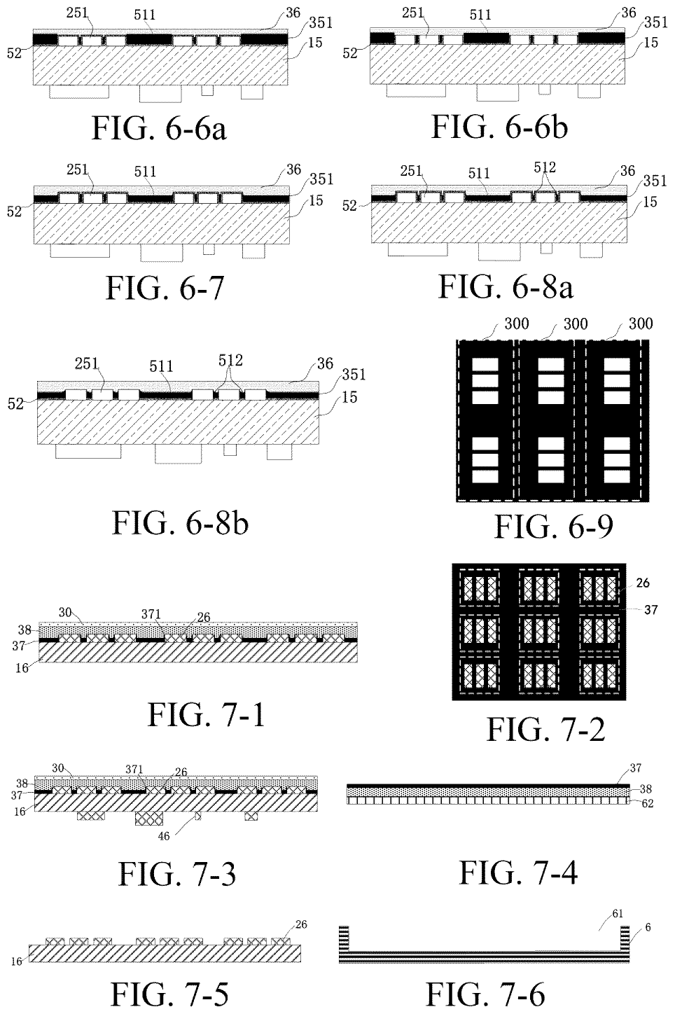

Step c1: as shown in FIG. 5-5 and FIG. 5-6, a light-emitting unit array 20 is mounted on the display region 142. In this embodiment, a plurality of light-emitting units 24 are arranged in a rectangular equidistant array. In a region surrounded by dashed lines in FIG. 5-5, a light-emitting unit array of 5 rows and 9 columns is schematically shown. In another embodiment, there may alternatively be another type of array manner. To ensure light-emitting evenness of the display module, a row pitch or a column pitch between the light-emitting units 24 of the light-emitting unit array 20 is designed. The row pitch or the column pitch between the light-emitting units 24 refers to a straight line distance between center lines of rows or columns where adjacent rows/columns of light-emitting units 24 are located. The row pitch or the column pitch is generally fixed to a uniform value, and certainly may alternatively not be fixed to a uniform value. For example, in consideration of heat dissipation, a row pitch between light-emitting units 24 close to the electronic driving element 44 in the substrate 14 is larger compared with a row pitch between light-emitting units far away from the LED electronic driving element 44, but based on consideration of light-emitting evenness, a row pitch between adjacent rows or columns of light-emitting units is gradually changed. However, to ensure the visual effect of the display module, the row pitches are not significantly inconsistent visually. Therefore, the equidistant distribution of this embodiment refers to visually equal pitches, but is not limited to equidistant distribution based on a refined measurement concept. In addition, the equidistant distribution in this embodiment should be understood according to a display effect requirement. For example, if the display effect requirement is being equidistant only in a transversal direction or a longitudinal direction, the light-emitting units 24 of this embodiment may be equidistantly distributed only in the transversal direction or the longitudinal direction but are unnecessarily equidistantly distributed in both the transversal direction and the longitudinal direction. In this embodiment, the light-emitting unit 24 may include an LED chip, and may alternatively include an LED packaging body with a packaging structure. For the light-emitting unit 24 of this embodiment, an LED chip is used as an example, and the LED chip may be appropriately selected from light-emitting chips in a wavelength range of visible light, for example, a red light LED chip, a green light LED chip, and a blue light LED chip. One light-emitting units 24 may include only one red light LED chip or one green light LED chip or one blue light LED chip, and may alternatively be packaging body including one or more of a red light LED chip, a green light LED chip, and a blue light LED chip.

Step d1: as shown in FIG. 5-7, a first packaging layer 31 is mold-pressed on the substrate 14, where the first packaging layer 31 covers the display region 142 and fills in the groove 144. The first packaging layer 31 may be a light-transmitting resin, for example, an epoxy resin or a siloxane resin. The first packaging layer 31 is most preferably made of a hard material, to protect the light-emitting units 24. In addition, the first packaging layer 31 is preferably formed using a resin with good heat resistance, weather resistance, and light resistance through a process such as transfer molding or compression molding.

Step e1: as shown in FIG. 5-8, a part of a process edge 141 is cut away along a side of the process edge 141 (that is, along a position shown by a dashed line in FIG. 5-7). During cutting, cutting is performed perpendicular to the top surface of the substrate, to form a cutting surface P on an outer side of the display module, so that after the cutting, an outer side surface of the packaging adhesive layer is coplanar with an outer side surface of the substrate located on the process edge, and a distance h from a center point of a light-emitting unit 24 closest to the cutting surface P (that is, an outermost side surface of the remaining part of the process edge 141) on a plane in which the display region 142 is located to the cutting surface P is less than or equal to ½ of a row pitch H between two rows of light-emitting units (that is, a distance between center lines of two rows of light-emitting units) parallel to the cutting surface P. Therefore, after display modules 200 of this embodiment are spliced into a large screen (FIG. 5-19 shows an example of a large screen into which four display modules 200 are spliced; and FIG. 5-14 is a schematic structural diagram of a cross-section of splicing two adjacent display modules 200), a distance H′ between light-emitting units 24 on two sides of the splicing seam is equal to or substantially equal to a row pitch H between two rows of light-emitting units parallel to the cutting surface P, light-emitting unit arrays 20 are visually continuous, and the light-emitting units 24 emit light evenly.

It should be noted that steps in this embodiment may be sequentially performed. Alternatively, an order of some steps may be changed or a new operation step may be added without conflict. For example, step b1 and step c1 may be interchanged. In the foregoing method, the process edge 141 is clamped by a corresponding jig when the display module 200 is manufactured, to avoid damaging the substrate 14 or other components mounted on the substrate 14 during processing; and the process edge 141 may be partially cut away during assembly of the display module 200, so as not to affect the display effect of the final display module 200. During product use or transportation, to prevent moisture from entering from the outside of the display module through the juncture of the first packaging layer 31 and the substrate 14, the groove 144 is cut along the periphery of the display region 142 on a side of the process edge 141 in this embodiment, and the first packaging layer 31 fills in the groove 144, thereby increasing the contact area between the first packaging layer 31 and the substrate 14, so that the path of the moisture may be extended in the thickness direction of the substrate 14, to extend the path through which the moisture intrudes, and the moisture is not prone to entering the interior of the display region 142 to contact the light-emitting units 24, to reduce damage caused by the moisture to the light-emitting units 24. In addition, the groove 144 further increases the contact area between the first packaging layer 31 and the substrate 14, to increase a bonding force between the first packaging layer 31 and the substrate 14. Therefore, the service life of the light-emitting units 24 is prolonged. In addition, in this embodiment, a distance h from a center point of a light-emitting unit 24 closest to the cutting surface P on a plane in which the display region 142 is located to the cutting surface P is less than or equal to ½ of a row pitch H between two rows of light-emitting units parallel to the cutting surface P. Therefore, when display modules 200 are spliced, as shown in FIG. 5-19, a distance H′ between light-emitting units on two sides of the splicing seam (that is, a distance between row centers of two rows of light-emitting units at the splicing place) is equal to or substantially equal to a row pitch H between two adjacent rows of light-emitting units 24, so that the spliced display screen emits light evenly, to resolve the problem existing in the existing technology. In addition, in the manufacturing method provided in this embodiment, the process edge 141 of the substrate 14 is ingeniously used, the groove 144 is provided only on the process edge 141, and the groove 144 is filled when the first packaging layer 31 is mold-pressed, so that anti-moisture performance of the display module 200 can be improved, the implementation difficulty is low, and the production efficiency is high.

Preferably, in this embodiment, as shown in FIG. 5-7, in step e1, when a part of the process edge 141 is cut away along a side of the process edge 141, the part is cut away from the groove 144, so that an outer side surface of the first packaging layer 31 is coplanar with an outer side surface of the substrate 14 located on the process edge 141. As shown in FIG. 5-8, at least a part of the groove 144 and a part of the process edge 141 are reserved on a side of the display module obtained after the cutting. In FIG. 5-7, the cutting position is in the middle of the groove 144. In this case, a bottom surface of the cut groove 144 is in communication with the outer side surface of the display module 200 (that is, a cutting surface, namely, an outer side surface of the cut process edge 141); and display modules of this embodiment are spliced through the cutting surface P. To narrow the splicing seam, cutting should be close to the display region 142. Therefore, cutting performed at the groove 144 can narrow the splicing seam, making it convenient to splice the display modules.

Specifically, in this embodiment, as shown in FIG. 5-4, one groove 144 is cut in step b1. However, in another embodiment, a plurality of grooves 144 may alternatively be cut in step b1. four grooves 144 are cut on the substrate 14 shown in FIG. 5-12a. Correspondingly, a cross-sectional structure of a display module 200 formed after the first packaging layer 31 is mold-pressed on the substrate 14 shown in FIG. 5-12a and a part of the process edge is cut away is shown in FIG. 5-12b. To extend the path through which the moisture intrudes into the interior of the display region 142, as many as possible grooves 144 are cut certainly. However, when a tiny splicing seam is required, too many grooves 144 cannot be cut due to limitations on the process precision and the material strength of the substrate 14, but at least one groove 144 should be cut. This may be determined according to an actual case, which is not limited herein.

Specifically, as shown in FIG. 5-4, in this embodiment, an inner wall of the groove 144 is smooth. However, in another preferable embodiment, a side wall of the groove 144 cut in step b1 close to a side of the display region 142 is uneven. An advantage is that a bonding area between the first packaging layer 31 and the side wall can be increased, so that the two are bonded more tightly and are not prone to separating from each other. For example, in another embodiment, as shown in FIG. 5-10, a side wall of the groove 144 close to a side of the display region 142 is in a stepped shape, so that a bonding force between the first packaging layer 31 and the substrate 14 is better. As shown in FIG. 5-11, a side wall of the groove 144 close to a side of the display region 142 is in a zigzag shape, so that a bonding force between the first packaging layer 31 and the substrate 14 is better, and the path through which the moisture intrudes into the interior of the display region 142 may be prolonged. In addition, an uneven side wall of the groove 144 close to a side of the display region 142 may alternatively be formed through etching, to further prolong the extension path of the moisture.

Referring to FIG. 5-2 and FIG. 5-13, in this embodiment, step c1 may further include: defining, on the back surface of the substrate B, a driving mounting region 143 (a region covered by inclined lines framed by dashed lines in FIG. 5-2) used for mounting an electronic driving element; and mounting an electronic driving element 44 in the driving mounting region 143 (shown in FIG. 5-13). The electronic driving element 44 is electrically connected to the light-emitting units 24 through a pre-fabricated circuit arranged in the substrate 14, and is used for driving the light-emitting units 24 to emit light, and no driving circuit needs to be additionally arranged, so that integration of the display module is higher. The electronic driving element may include a resistor, a capacitor, an inductor, an integrated circuit, and the like.

In this embodiment, in step e1, a ratio of the thickness of the remaining part of the process edge 141 to the depth of the groove 144 ranges from 2 to 20. The thickness of the remaining part of the process edge 141 is the thickness of a part of the groove 144 that does not run through the substrate 14; and the depth of the groove 144 is a distance from an opening of the groove 144 to the bottom of the groove. Because the groove 144 plays a role in extending the path in which the moisture intrudes into the interior of the display region, the groove 144 should be as deep as possible, but cannot be too deep to cause the strength of a junction of the process edge 141 and the substrate 14 to be insufficient. In actual application, a ratio of the thickness to the width of the remaining part of the process edge 141 appropriately ranges from 2 to 20.

In this embodiment, the thickness of the substrate 14 ranges from 1 to 5 mm. In this embodiment, the substrate 14 may be selected from a printed circuit board or a glass substrate or another type of substrate, and an appropriate substrate may be selected according to a use environment requirement. In this embodiment, the substrate is preferably a printed circuit board. A pre-fabricated circuit may be arranged on the substrate, and metal pads may be arranged in the display region 142 and the driving mounting region, making it convenient to mount the light-emitting units 24 and the electronic driving element 44 using a surface mount technology (SMT) process. If the thickness of the substrate 14 is too small, the depth of the groove 144 is too small to cause the path of the moisture to be too short. Therefore, to extend the path of the moisture as much as possible, the groove 144 should be as deep as possible and the substrate 14 should be as thick as possible. However, the too thick substrate 14 increases the volume of display module, and lightening and thinning cannot be implemented. In actual application, the thickness of the substrate 14 appropriately ranges from 1 to 5 mm, and a multi-layer printed circuit board formed by alternately arranging a plurality of layers of insulting substrates and a plurality of circuit layers may be selected.

During long-term use of the display module, a large gap may occur between the first packaging layer and the substrate because of mismatch between expansion coefficients of the first packaging layer and the substrate (for example, the expansion coefficient of the substrate and the expansion coefficient of the light-transmitting packaging adhesive differ greatly, so that the expansion extents of the substrate and the light-transmitting packaging adhesive are different when the temperature rises, where in this embodiment, the expansion coefficient of the first packaging layer is far greater than the expansion coefficient of the substrate) to reduce air-tightness. As a result, the moisture very easily enters the interior of the module through the interface between the first packaging layer and the substrate, to cause the light-emitting units to fail. In this embodiment, for the first packaging layer, a nanometer-sized powder material (the particle size of the nanometer-sized powder material preferably ranges from 5 nm to 200 nm) is mixed in a light-transmitting adhesive to form a mixed adhesive (the mixing is preferably even mixing, so that characteristics of parts of the mixture are consistent) to improve the expansion coefficient of the first packaging layer, to narrow the gap with the expansion coefficient of the substrate. In this embodiment, an epoxy resin, a silica gel, or a silicon resin is selected. A nano silicon dioxide powder material, a nano aluminum oxide powder material, a nano zirconium tungstate powder material, or a mixture of at least two of the three materials is selected as a nanometer-sized powder material to be mixed into the light-transmitting adhesive. Because the expansion coefficient of the nano silicon dioxide powder material, the expansion coefficient of the nano aluminum oxide powder material, and the expansion coefficient of the nano zirconium tungstate powder material are far less than the expansion coefficient of the epoxy resin, the expansion coefficient of the silica gel, and the expansion coefficient of the silicon resin, and particularly the nano zirconium tungstate material is a material with a negative expansion coefficient, the expansion coefficient of the light-transmitting packaging adhesive formed after mixing is reduced, to narrow the gap with the expansion coefficient of the substrate. In this embodiment, by adding the nanometer-sized powder material to the light-transmitting adhesive to perform modification, the expansion coefficient of the epoxy resin, the expansion coefficient of the silica gel, and the expansion coefficient of the silicon resin can be effectively regulated, so that the mismatch between the expansion coefficient of the epoxy resin, the expansion coefficient of the silica gel, and the expansion coefficient of the silicon resin and the expansion coefficient of the substrate is alleviated, thereby improving the air-tightness of the first packaging layer and the substrate, to avoid, during long-term use of the display module, a case that moisture enters the interior of the module through the interface between the packaging adhesive and the substrate because the air-tightness is reduced, to cause the LED chip to fail or the adhesive layer and the substrate to be layered.

This embodiment provides another manufacturing method for a display module, including the following steps:

Step a2: provide a substrate. The substrate is similar to the substrate provided in the foregoing step a1. Details are not described herein again.

Step b2: cut a groove on the periphery of the process edge close to the display region, where the groove does not run through the substrate, and the groove has a depth greater than a depth of a part of the substrate that is not run through. Step b2 in this embodiment is the same as step b1 in Embodiment 1, and reference may be made to the description about step b1 in the foregoing embodiment 1. Details are not described herein again.

Step c2: mount light-emitting units on the display region, and mold-press a first packaging layer 32 on the display region. This embodiment is different from step c1. In this embodiment, as shown in FIG. 5-15, after a light-emitting unit array 20 is mounted on the display region 142, the first packaging layer 32 is first mold-pressed; and the first packaging layer 32 covers the light-emitting units 24 in the display region, so that when the part of the process edge is cut away in step d2, a case that the light-emitting units 24 are loosened because of vibration caused by cutting is avoided.

Step d2: as shown in FIG. 5-16, the part of the process edge is cut away along a side of the process edge 141, to form a cutting surface P′ on an outer side of the display module, and a distance from a center point of a light-emitting unit 24 closest to the cutting surface P′ on a plane in which the display region is located to the cutting surface P′ is less than ½ of a row pitch between two rows of light-emitting units parallel to the cutting surface P′.

Step e2: as shown in FIG. 5-17, a second packaging layer 33 is mold-pressed on the substrate, where the second packaging layer 33 covers the first packaging layer 32 and a top surface of the substrate Z (that is, located above the top surface of the substrate Z, and directly or indirectly contacting the top surface of the substrate Z), fills in the groove 144, and extends to cover the cutting surface P′ to be flush with a back surface of the substrate B, and a distance h1 from a center point of a light-emitting unit 24 closest to the outermost side surface of the second packaging layer 33 on a plane in which the display region 142 is located to the outermost side surface of the second packaging layer 33 is less than or equal to ½ of a row pitch H1 between two rows of light-emitting units parallel to the outermost side surface of the second packaging layer 33.

In this embodiment, the second packaging layer 33 fills in the groove 144 and clothes a side of the driving mounting region (that is, the substrate 14 the back surface of the substrate B), so that the path of the moisture is longer than that in Embodiment 1. Therefore, although steps of this embodiment are more complicated than those in Embodiment 1, the anti-moisture effect is better.

It should be noted that the steps in the foregoing method of this embodiment may be sequentially performed. Alternatively, an order of some steps may be changed or a new operation step may be added without conflict. In this embodiment, before the process edge is cut away, the light-emitting units 24 are first mounted on the display region, and the first packaging layer 32 is mold-pressed on the display region, to protect the light-emitting units. Therefore, when the process edge is cut, a case that the light-emitting units 24 are separated from the substrate 14 because of vibration of the substrate caused by cutting is avoided. After the process edge is cut, the mold-pressed second packaging layer 33 may fill in the groove and clothe driving mounting region on the back, thereby increasing the contact area between the first packaging layer and the outer side of the substrate, extending the path of the moisture, so that the moisture is not prone to entering the interior of the display region to contact the light-emitting units 24, thereby extending the service life of the light-emitting units 24. As shown in FIG. 5-17 and FIG. 5-18, a distance from a center point of a light-emitting unit 24 closest to the outermost side surface of the second packaging layer 33 on a plane in which the display region is located to the outermost side surface of the second packaging layer 33 is less than or equal to ½ of a row pitch between two rows of light-emitting units 24 parallel to the outermost side surface of the second packaging layer 33. Therefore, when display modules used for splicing are spliced, a distance H′ between light-emitting units on two sides of the splicing seam is equal to or substantially equal to a row pitch H between two rows of light-emitting units parallel to the cutting surface, and the spliced display effect is not affected, so that the spliced display screen emits light evenly. In addition, the process edge of the substrate is ingeniously used, the groove is provided only on the process edge, and the groove is filled when the first packaging layer 32 is first mold-pressed and then the second packaging layer 33 is mold-pressed, so that anti-moisture performance of the display module can be improved, the implementation difficulty is low, and the production efficiency is high.

In this embodiment, when the first packaging layer 32 is mold-pressed, the groove 144 is not filled. In this way, the cutting resistance may be reduced during cutting. However, in another embodiment, the groove 144 may alternatively be first filled when the first packaging layer 32 is mold-pressed. In another embodiment, as shown in FIG. 5-20, the second packaging layer 33 may alternatively extend onto the back surface of the substrate B. Alternatively, a back groove 145 may be cut on the back surface of the substrate B, so that the second packaging layer 33 also fills in the back groove 145, to further extend the path of the moisture, and further enhance the bonding force between the substrate and the first packaging layer.

In this embodiment, the refractive index of the second packaging layer 33 is greater than the refractive index of the first packaging layer 32, so that an angle at which light emitted by the light-emitting unit 24 diffuses outward after being refracted through the first packaging layer 32 and the second packaging layer 33 becomes larger, to help scatter the light, making the light-emitting effect more even.

In another example of this embodiment, as shown in FIG. 5-21, in step b2, the groove 144 may be cut around the display region 142 (as shown in FIG. 5-3), that is, the groove 144 is cut on the top surface of the substrate Z of the substrate. However, in this example, the back groove 145 is cut on the back surface of the substrate B. As shown in FIG. 5-22, after the first packaging layer 32 is mold-pressed, the part of the process edge is cut away from the back groove 145, and then the third light-transmitting the packaging layer 33 is mold-pressed. In this embodiment, the path of the moisture extends to be flush with the back surface of the substrate B of the substrate 14, and is longer than the path of the moisture of the display module provided in Embodiment 1, and the third light-transmitting the packaging layer 33 is bonded to the substrate 14 more tightly.

No light-emitting unit 24 is mounted on the back surface of the substrate B, and even if electronic driving elements 44 are mounted on the back surface of the substrate B, the electronic driving elements do not need to be evenly distributed. Therefore, the back surface of the substrate has a sufficient space to cut a back groove, and a larger back groove may be designed. For example, as shown in FIG. 5-23, the back groove 145 is an inverted “V” groove, and is cut (in FIG. 5-23, cut-away parts are shown by dashed lines at two ends of the substrate 14) and then is finally formed, on a side surface of the substrate 14, into an inclined surface 1451 inclined toward the middle of the back surface of the substrate B of the substrate. An advantage of such a practice is that three-dimensional splicing shown in FIG. 5-24 may be implemented, that is, in addition to planar splicing, angular splicing may be further implemented. As shown in FIG. 5-24, two display modules are spliced at 90°, and certainly may alternatively be spliced in a range from being greater than 90° to being less than or equal to 180°, and the inclined surface 1451 may prevent the two display modules from interfering with each other at a splicing place when being spliced at an angle. Therefore, the display module of this embodiment has better practicability and a wider application range.

as shown in FIG. 5-19, in this embodiment, an LED display screen formed by splicing display modules in the foregoing examples is further provided, where display modules 200 are connected to adaptation boards (not shown in the drawing) through plug-connection members (not shown in the drawing), and then the adaptation boards are fixed to structural outer frames tightly through copper pillars, to form an LED display screen with a tiny splicing seam.

### Embodiment 5

When a display module or an LED optical device is manufactured using a COB packaging technology, COB integrated packaging may achieve a smaller point pitch, and can bring a more excellent display effect. A COB display packaging product mainly has two technical advantages: First: COB belong to modularized packaging, and all the surface of the entire product is packaged and protected by an adhesive, to effectively reduce a packaging interface and improve product reliability. Second: The technology using COB integrated packaging has a natural technical advantage in the field of a smaller pitch. However, for a current flip COB display packaging product, industrial pain point problems such as undesired contrast of the product, an undesired black display effect achieved after a screen is mounted, and ink color inconsistency occurring after the screen is off are prominent. A current industrial common practice is to add a black ingredient to a packaging adhesive, to achieve high contrast after packaging, but a problem of ink color inconsistency between modules is usually caused. As a result, the entire screen of the COB display packaging product has low contrast and luminance and an undesired display effect.

For the foregoing problem, this embodiment provides a display module that can improve contrast and luminance of an entire screen, and the display module provided in this embodiment may be individually implemented independently of other embodiments. An example of the display module provided in this embodiment is shown in FIG. 6-1. The display module includes a substrate 15 and a plurality of light-emitting units 25 arranged on a top surface of the substrate, where each light-emitting unit 25 includes a plurality of LED chips 251; a black adhesive layer 351, which is also referred to as a black optical layer in the present invention, arranged on the top surface of the substrate, where the black adhesive layer 351 covers a first region 151 on the top surface of the substrate located between the light-emitting units 25 and a second region 152 between the LED chips 251 in each of the light-emitting units 25, a light-emitting surface of each of the LED chips 251 is exposed from the black adhesive layer 351, and a height of the black adhesive layer 351 is less than a height of the LED chips 251; and a packaging layer 36 arranged on the top surface of the substrate and covering the black adhesive layer 351 and each of the light-emitting units 25. It should be noted that as shown in FIG. 6-1, an electronic element 45 is arranged on a back surface of the substrate, to drive the LED chips 251 to emit light. It may be understood that in actual application, the LED chips 251 may be arranged on the top surface of the substrate through soldering, and may alternatively be arranged on the top surface of the substrate through mounting, and a specific arrangement manner is not limited in the present invention. The packaging layer 36 may be formed on the substrate in a manner, including but not limited to, injection molding, adhesive dispensing, or mold-pressing, and is tightly bonded to the black adhesive layer 351 and the light-emitting units 25. In some examples, the packaging layer 36 may cover all light-emitting units 25 on only the top surface of the substrate, and may alternatively cover all the entire top surface of the substrate. It should be noted that the packaging layer 36 may have, including but not limited to, a specific proportion of diffusion particles added, to improve the light-emitting effect thereof. For example, a specific proportion of diffusion powder or fluorescent powder may be added.

In some examples, the display module further includes a moisture-proof layer 52, and the moisture-proof layer 52 includes at least one of the following: a first moisture-proof layer 521 arranged between the black adhesive layer 351 and the top surface of the substrate; and a second moisture-proof layer 522 covering the LED chips 251. For example, FIG. 6-2 is a schematic structural diagram of a cross-section of a moisture-proof layer of a display module or an LED optical device. It should be noted that in FIG. 6-2, a first moisture-proof layer 521 is arranged between a black adhesive layer 351 and a top surface of the substrate. FIG. 6-3 is a schematic structural diagram of a cross-section of a moisture-proof layer of another display module or another LED optical device. A second moisture-proof layer 522 in FIG. 6-3 covers LED chips 251, and the foregoing moisture-proof layer 52 may be formed in a manner including, but not limited to, mold-pressing or hot-pressing. Certainly, the moisture-proof layer 52 may alternatively be arranged between the black adhesive layer and the top surface of the substrate and cover the LED chips. For example, FIG. 6-4 is a schematic structural diagram of a cross-section of a moisture-proof layer of still another display module or still another LED optical device. The moisture-proof layer 52 in FIG. 6-4 is arranged between the black adhesive layer and the top surface of the substrate and covers the LED chips 251, and a side surface of the LED chip 251 is a surface located between a light-emitting surface and a bottom surface thereof.

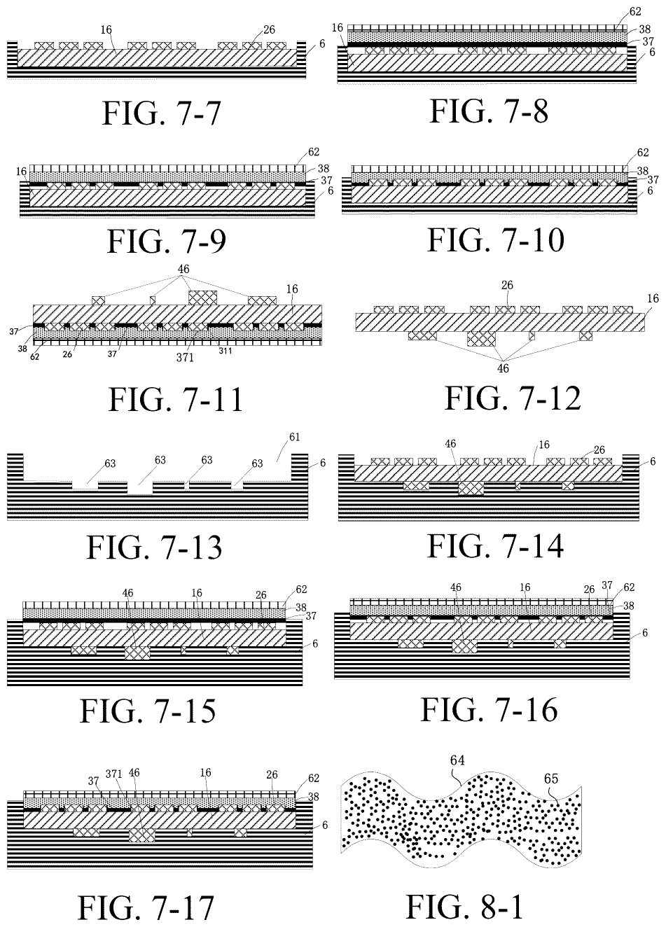

In some examples, the moisture-proof layer 52 shown in FIG. 6-4 includes a first moisture-proof layer 521 and a second moisture-proof layer 522, and the first moisture-proof layer 521 and the second moisture-proof layer 522 may be molded, including but not limited to, in one piece, and may alternatively not be molded in one piece. It should be noted that when the first moisture-proof layer 521 and the second moisture-proof layer 522 are not molded in one piece, the first moisture-proof layer 521 and the second moisture-proof layer 522 should be tightly connected to each other at a border between the two moisture-proof layers when being arranged, to prevent moisture from entering. It should be noted that the moisture-proof layer 52 may include, but not limited to, a macromolecule nano layer, may completely prevent intrusion of water molecules, and may be further bonded to a chip, a PCB board, and packaging glue very well, to improve the mechanical strength thereof; and does not affect the display effect, to improve use satisfaction of the user. In some examples, as shown in FIG. 6-8a, a top surface 511 of a black adhesive layer 351 located in a first region 151 is parallel to both a top surface of the substrate and a top surface 512 of a black adhesive layer 351 located in a second region 152. In an example of a display module shown in FIG. 6-8b, a region of a top surface 511 of a black adhesive layer 351 of the display module located in a first region 151 close to light-emitting units 25 may alternatively be an inclined surface or a curved surface, and a maximum height of the top surface 511 of the black adhesive layer 351 of the display module is less than a height of a light-emitting surface of an LED chip 251, so that a larger region of a side surface of the LED chip 251 is covered, thereby significantly reducing crosstalk between the light-emitting units. Certainly, for example, FIG. 6-6a and FIG. 6-6b are schematic diagrams of another display module. The height of a top surface 511 of a black adhesive layer 351 in the display module is greater than the height of a light-emitting surface of an LED chip 251, to prevent crosstalk between light-emitting units which affects a display effect. By setting the height of the black adhesive layer between the light-emitting units to be greater than the height of the light-emitting surface of the LED chip, when light mixing happens among the light-emitting units, other light-emitting units are not affected, and the display effect is better. It should be noted that FIG. 6-7 is a schematic diagram of still another display module. A top surface 511 of a black adhesive layer 351 may alternatively be a curved surface concave toward a top surface of the substrate, and a maximum height of the top surface 511 of the black adhesive layer is the same as the height of a light-emitting surface of an LED chip, that is, the black adhesive layer may extend along a side surface of the LED chip toward the light-emitting surface thereof, and is finally flush with the light-emitting surface.

In some embodiments, for example, FIG. 6-8a and FIG. 6-8b are schematic diagrams of another display module. A top surface 512 of a black adhesive layer 351 of the display module located in a second region 152 may alternatively be a curved surface concave toward a top surface of the substrate. It should be noted that the top surface 512 of the black adhesive layer located in the second region is not higher than a light-emitting surface of an LED chip. The second region is located between LED chips in light-emitting units 25. Therefore, if the height of the top surface of the black adhesive layer in the second region is greater than the height of the light-emitting surface of the LED chip, a light mixing effect of the LED chips is greatly affected, or even light mixing cannot happen. To improve the light mixing effect thereof and the display effect, the top surface of the black adhesive layer in the second region should not be higher than the light-emitting surface of the LED chip.

It should be noted that in this embodiment, the top surface of the black adhesive layer in the first region and the top surface of the black adhesive layer in the second region may be both parallel to the top surface of the substrate, and may alternatively be both curved surfaces or inclined surfaces concave toward the top surface of the substrate; or the top surface of the black adhesive layer in the first region is parallel to the top surface of the substrate, and the top surface of the black adhesive layer in the second region is a curved surface or an inclined surface concave toward the top surface of the substrate; or the top surface of the black adhesive layer in the first region is a curved surface or an inclined surface concave toward the top surface of the substrate, and the top surface of the black adhesive layer in the second region is parallel to the top surface of the substrate; or certainly the top surfaces of the black adhesive layers in the first region and the second region may be parallel to the top surface of the substrate in parts of the regions and be curved surfaces or inclined surfaces concave toward the top surface of the substrate in other parts of the regions, which may be set by a person skilled in the art according to an actual case and a requirement and is not limited herein.

It should be noted that one display module in this embodiment may include, but not limited to, a case that the height of the top surface of the black adhesive layer in the first region is greater than the height of the light-emitting surface of the LED chip and the height of the top surface of the black adhesive layer in the second region is less than the height of the light-emitting surface of the LED chip; may alternatively include a case that the height of the top surface of the black adhesive layer in the first region is less than the height of the light-emitting surface of the LED chip and the height of the top surface of the black adhesive layer in the second region is less than the height of the light-emitting surface of the LED chip; and certainly may alternatively be a case that the height of the top surface of the black adhesive layer in the first region is equal to the height of the light-emitting surface of the LED chip and the height of the top surface of the black adhesive layer in the second region is equal to the height of the light-emitting surface of the LED chip. A person skilled in the art may set the heights of the top surfaces of the black adhesive layers in the first region and the second region according to an actual case and a requirement, as long as the height of the top surface of the black adhesive layer in the second region is not greater than the height of the light-emitting surface of the LED chip, which is not limited in this embodiment. Preferably, in this embodiment, the height of the top surface of the black adhesive layer in the first region is greater than the height of the light-emitting surface of the LED chip, to prevent crosstalk between light-emitting units. It should be noted that a case that the top surface of the black adhesive layer is higher than the light-emitting surface of the LED chip refers to a case that at least one part of the top surface of the black adhesive layer is higher than the light-emitting surface of the LED chip; and a case that the top surface of the black adhesive layer is not higher than the light-emitting surface of the LED chip refers to a case that no part of the top surface of the black adhesive layer is higher than the light-emitting surface of the LED chip, but may include a case that at least one part thereof is flush with the light-emitting surface of the LED chip. It should be noted that whether the black adhesive layers in the first region and the second region are parallel to the top surface of the substrate or concave toward the top surface of the substrate, and the heights of the black adhesive layers in the first region and the second region may be combined in a plurality of manners, which may be set by a person skilled in the art according to an actual case and a requirement.

For the quantity, light emission colors, sizes, and the like of LED chips included in the light-emitting units 25 in this embodiment, reference may be made to, but not limited to, the arrangement of light-emitting units in other embodiments. Details are not described herein again.

In some implementations, the black adhesive layer 351 is a mold-pressed black adhesive layer mold-pressed on the top surface of the substrate or a hot-pressed black adhesive layer hot-pressed on the top surface of the substrate. In some examples, if the black adhesive layer 351 is a mold-pressed black adhesive layer mold-pressed on the top surface of the substrate, a substrate made of a PCB material may be selected, cleaned, and dehumidified, then LED chips are fixed on a top surface of the substrate of the PCB, and an electronic element is mounted on a back surface of the PCB, to ensure that all the LED chips can be normally illuminated after a period of time of aging verification. Then, the black adhesive layer is mold-pressed to cover surfaces of the LED chips, baked, and cured, and then the black adhesive on the surfaces is etched through, including but not limited to, chemical etching or physical etching, until the surfaces of the chips are completely bared. Finally, a packaging layer is mold-pressed on the mold-pressed black adhesive layer and the surfaces of the LED chips, to improve reliability of a product and achieve a light mixing effect. In some examples, if the black adhesive layer 351 is a hot-pressed black adhesive layer hot-pressed on the top surface of the substrate, a pre-manufactured hot-pressed black adhesive film sheet may be hot-pressed onto the substrate and surfaces of LED chips, baked, and cured, and the hot-pressed black adhesive film sheet is hot-pressed and then formed into a shape of being concave toward the top surface of the substrate together with the peripheries of the LED chips. Then, the hot-pressed black adhesive film sheet on the surfaces of the LED chips is etched in a manner including, but not limited to, chemical etching or physical etching, until the surfaces of the LED chips are completely bared, to ensure that light is out from light-emitting surfaces of the LED chips normally. Finally, a packaging layer is mold-pressed on the hot-pressed black adhesive film sheet and the surfaces of the LED chips, to improve reliability of a product and achieve a light mixing effect.

In this embodiment, black adhesive layers with different heights and different shapes are arranged between light-emitting units on the top surface of the substrate and between LED chips in a light-emitting unit, to improve its contrast and luminance, improve its display effect, and moisture-proof layers are arranged between the black adhesive layer and the top surface of the substrate and on surfaces of the LED chips, to prevent intrusion of moisture, resolve problems of the display module of poor ink color consistency, poor contrast, and failure caused by humidification, improve the contrast and the display effect, and greatly improve use satisfaction of the user.

This embodiment further provides a display screen, as shown in FIG. 6-9. To more clearly indicate a structure of the display screen, a packaging layer is subject to perspective treatment in the drawing. The display screen includes at least one display module shown in the foregoing examples. For example, as shown in FIG. 6-9, three display modules 300 are spliced to form the display screen, and two adjacent display modules are fixed through, including but not limited to, a fixation bracket, a screw, or glue. It should be noted that the display screen may be set as a plane, and may alternatively be set as a curved surface. A specific setting manner may be set by a person skilled in the art according to an actual case and a requirement, and is not limited in the present invention.

### Embodiment 6

Compared with the display module in Embodiment 5, arrangement of a moisture-proof layer may be omitted in a display module in this embodiment. In addition, the display module in this embodiment may be individually implemented independently of the foregoing embodiments. For ease of understanding, in this embodiment, a packaging layer of the display module includes a seventh packaging layer and an eighth packaging layer arranged on the seventh packaging layer, where the seventh packaging layer is a second black adhesive layer (which may be, but not limited to, the black adhesive layer shown in the previous embodiment), and the eighth packaging layer is a first light-transmitting adhesive layer (which may be, but not limited to, the packaging layer shown in the previous embodiment). However, the packaging layer in this embodiment is press-fit on a top surface of the substrate after an LED chip of each light-emitting unit is arranged on the top surface of the substrate.

An exemplary display module provided in this embodiment is shown in FIG. 7-1 and FIG. 7-2. The display module includes a substrate 16 and light-emitting units arranged on the substrate 16, where each light-emitting unit includes at least one LED chip 26; and a packaging layer of the display module includes a black adhesive layer 37 and a first packaging layer 38. Optionally, in this embodiment, the display module may further include a transparent protection film 30 covering the first packaging layer 38. Arrangement of the transparent protection film 30 may further improve protection performance of the display module. In addition, the thickness of the transparent protection film in this embodiment may also be flexibly set according to a requirement. For example, the thickness may be set to, but not limited to, a range from 10 μm to 300 μm. It should be understood that in this example, the transparent protection film 30 may be a composite-layer structure formed by at least two adhesive sub-layers, and may alternatively be a single-layer structure; and the transparent protection film 30 may be, but not limited to, a transparent adhesive layer, a plastic sheet, or the like.

For ease of understanding, a manufacturing method for a display module is exemplified below in this embodiment, and includes, but not limited to:

Step a3: manufacture a substrate and a packaging layer.

In this embodiment, the manufacturing a substrate includes: arranging the substrate 16, and arranging LED chips on a top surface of the substrate 16. In some examples, an electronic element may be further arranged on a back surface of the substrate 16, that is, an electronic element is arranged on a back surface of the substrate 16 first before a surface of the packaging layer provided with the black adhesive layer 37 is press-fit to the top surface of the substrate 16. Certainly, in some other examples, an electronic element may alternatively be arranged on the back surface of the substrate 16 after the packaging layer is formed on the top surface of the substrate 16.

In this embodiment, the manufacturing a packaging layer includes: arranging a first bearing film 62, arranging a first packaging layer 38 on the first bearing film 62, and then arranging a black adhesive layer 37 on the first packaging layer 38. It should be understood that in this embodiment, a process used for arranging an first packaging layer 38 on the first bearing film 62 and arranging a black adhesive layer 37 on the first packaging layer 38 may be flexibly selected. For example, the process may be, but not limited to, coating, silk-screen printing, printing, mold-pressing, or the like.

It should be understood that in this embodiment, the substrate and the packaging layer may be manufactured synchronously, or the substrate 16 is first manufactured and then the packaging layer is manufactured. Alternatively, the substrate and/or the packaging layer is directly purchased upstream.

It should be understood that the first packaging layer 38 and the black adhesive layer 37, which is also referred to as a black optical layer in the present invention, sequentially arranged on the first bearing film 62 in this step may be in a cured state, and are subsequently heated and converted from the cured state into a semi-cured state when being press-fit to the top surface of the main body of the substrate 16. Certainly, the first packaging layer 38 and the black adhesive layer 37 sequentially arranged on the first bearing film 62 in this step may alternatively be in the semi-cured state, and therefore are subsequently directly press-fit to the top surface of the main body of the substrate 16 easily. In this case, the press-fitting may be a hot press-fitting manner or another press-fitting manner. Details are not described herein again.

Step b3: press-fit a surface of the packaging layer provided with the black adhesive layer or a black optical layer 37 and the top surface of the substrate 16, where in a press-fitting process, the first packaging layer 38 and the black adhesive layer 37 sequentially arranged on the first bearing film 62 are in a semi-cured state, a light-emitting surface of each of the LED chips are gradually exposed from the black adhesive layer 37, and the first packaging layer 38 covers the black adhesive layer 37 and the light-emitting surface of each of the LED chips.

In an example of this embodiment, a surface of the packaging layer provided with the black adhesive layer or a black optical layer 37 may be press-fit to the top surface of the substrate 16 in a manner of, but not limited to, hot-pressing. In this case, a surface of the packaging layer provided with the black adhesive layer 37 may be laminated on the top surface of the substrate 16, and the packaging layer is heated and applied with pressure facing the main body of the substrate 16, to press-fit the packaging layer to the main body of the substrate 16. During the press-fitting, because the first packaging layer 38 and the black adhesive layer 37 are in a semi-melted state and are subjected to pressure facing the main body of the substrate 16, the light-emitting surfaces of the LED chips are gradually exposed from the black adhesive layer 37.

In some examples of this embodiment, to improve the yield and the manufacturing efficiency, a substrate jig 6 may be provided, and the substrate jig 6 is provided with an accommodating cavity adapted for the substrate. When a surface of the packaging layer provided with the black adhesive layer is press-fit to the top surface of the substrate, the substrate may be fixed on the substrate jig 6. After the fixation, the main body of the substrate is fixedly arranged in the accommodating cavity of the substrate jig 6. In addition, the back surface of the substrate faces the bottom of the accommodating cavity, and the top surface of the substrate and the LED chips face a top opening of the accommodating cavity, to laminate the surface of the packaging layer provided with the black adhesive layer. In this example, before a surface of the packaging layer provided with the black adhesive layer is press-fit to the top surface of the substrate 16, electronic elements are first arranged on the back surface of the substrate 16. The bottom of the accommodating cavity is further provided with an accommodating groove corresponding to each electronic element. After the substrate is fixed on the substrate jig, each electronic element is located in a corresponding accommodating groove. It can be learned that the substrate jig used in this embodiment has a simple structure, is easy to manufacture, and has low costs.

It can be learned with reference to the foregoing manufacturing method that because the black adhesive layer used in this embodiment has a specific viscosity and is more easily bonded to the main body of the substrate and the LED chips, air-tightness can be improved, and the LED chips can be better protected; and during press-fitting, seams between the main body of the substrate and the LED chip and the like may be fully filled using fluidity of the black adhesive layer, and the contrast can be further improved.

Compared with a manner in which the black adhesive layer is first arranged on the main body of the substrate and then the first packaging layer is arranged on the black adhesive layer, this embodiment in which the first packaging layer and the black adhesive layer are sequentially arranged on the first bearing film and press-fit onto the main body of the substrate at a time can simplify the process, improve the manufacturing efficiency, and reduce the manufacturing costs. In addition, when the first packaging layer and the black adhesive layer are press-fit onto the main body of the substrate at a time, integrity of the black adhesive layer and the first packaging layer is better, to better help improve the press-fitting density. In addition, in this embodiment, it is not necessary to additionally spray a black ink layer or the like on the top surface of the substrate to set the top surface of the substrate in black, so that the manufacturing process can be further simplified, to reduce the manufacturing costs. In addition, because the black ink layer is omitted, the thickness of the display panel can be reduced.

In some examples of this embodiment, the first bearing film in the packaging layer may be directly set as a transparent protection film. In this example, after a surface of the packaging layer provided with the black adhesive layer is press-fit to the top surface of the substrate, the first bearing film may be reserved, and the reserved first bearing film is the transparent protection film formed on the first packaging layer. In this case, it is not necessary to remove the first bearing film, and it is not necessary to additionally manufacture the transparent protection film on the first packaging layer either, so that the manufacturing process can be further simplified, to improve the manufacturing efficiency and reduce the costs.

Certainly, in some other examples of this embodiment, after a surface of the packaging layer provided with the black adhesive layer is press-fit to the top surface of the substrate, the first bearing film may alternatively be removed, and then one or more pre-fabricated adhesive sheets are sequentially laminated on the first packaging layer to form the transparent protection film. Certainly, the transparent protection film may alternatively be formed on the first packaging layer in a manner, but not limited to, coating, mold-pressing, silk-screen printing, or printing. In addition, in this example, the first bearing film may alternatively be replaced with a bearing substrate.

For ease of understanding, this embodiment is described below using two manufacturing methods for the display module shown in FIG. 7-3 as examples. An exemplary manufacturing method is shown in FIG. 7-4 to FIG. 7-11, and includes, but not limited to:

Step a4: manufacture the packaging layer shown in FIG. 7-4.

For example, in an example, a film sheet of the first bearing film 62 (the film sheet may be a transparent film) is laid flat first. The first bearing film 62 has a thickness range from 10 μm to 300 μm, a thickness evenness range from 1% to 10%, and a light transmittance range from 30% to 100%. Then, two layers of glue are sequentially arranged on the first bearing film 62. First, light-transmitting glue is arranged to form an first packaging layer 38. The first packaging layer 38 has a thickness range from 5 μm to 300 μm, a thickness evenness range from 1% to 10%, and a light transmittance range from 30% to 100%. Then, black glue is arranged on the first packaging layer 38 to form a black adhesive layer 37. The black adhesive layer 37 has a thickness range from 5 μm to 200 μm, a thickness evenness range from 1% to 10%, and a light transmittance range from 0% to 30%. The structure of the formed packaging layer is shown in FIG. 7-4. The black adhesive layer 37 and the first packaging layer 38 formed in step a4 in this example may be in a semi-cured state or a cured state.

In this example, a specific value of the thickness of the black adhesive layer 37 may be flexibly set based on ensuring as much as possible that the black adhesive layer 37 does not cover a light-emitting surfaces of an LED chip 26 to cause low luminous efficiency thereof and enabling the black adhesive layer 37 to cover a side surface of the LED chip 26 as much as possible. Therefore, when the black adhesive layer 37 is press-fit to the top surface of the substrate, an outer surface 371 formed by a part suspended on the side surface of the LED chip 26 when the black adhesive layer 37 in the semi-cured state is compressed to run through the corresponding LED chip 26 is an inclined surface or a curved surface, to better avoid impact of crosstalk between the LED chips, thereby further improving the contrast and improving the yield.

Step b4: manufacture the substrate shown in FIG. 7-5.

In an example, completing die bonding of an LED chip 26 on the top surface of the substrate is included. In this example, the LED chip 26 may be transferred onto the top surface of the substrate in various chip transfer manners (for example, a mass transfer manner), the LED chip 26 may be, but not limited to, a face-up, flip, or vertical LED chip, and an light-emitting color of the LED chip 26 may include at least one of red, green, blue, white, and the like. A pitch between the LED chips 26 ranges from 200 μm to 1000 μm.

Step c4: manufacture the substrate jig 6 shown in FIG. 7-6.

As shown in FIG. 7-6, the substrate jig 6 in this example includes an accommodating cavity 61 adapted for the substrate, and the bottom of the accommodating cavity 61 in this example is not provided with an accommodating groove for accommodating an electronic element 46. In this embodiment, the material of the substrate jig may be, but not limited to, metal, ceramic, or another material. Details are not described herein again.

Step d4: fix the manufactured substrate on the substrate jig 6. A state after the fixation is shown in FIG. 7-7. The substrate jig 6 fixes the substrate, so that the substrate can be maintained in a steady state.

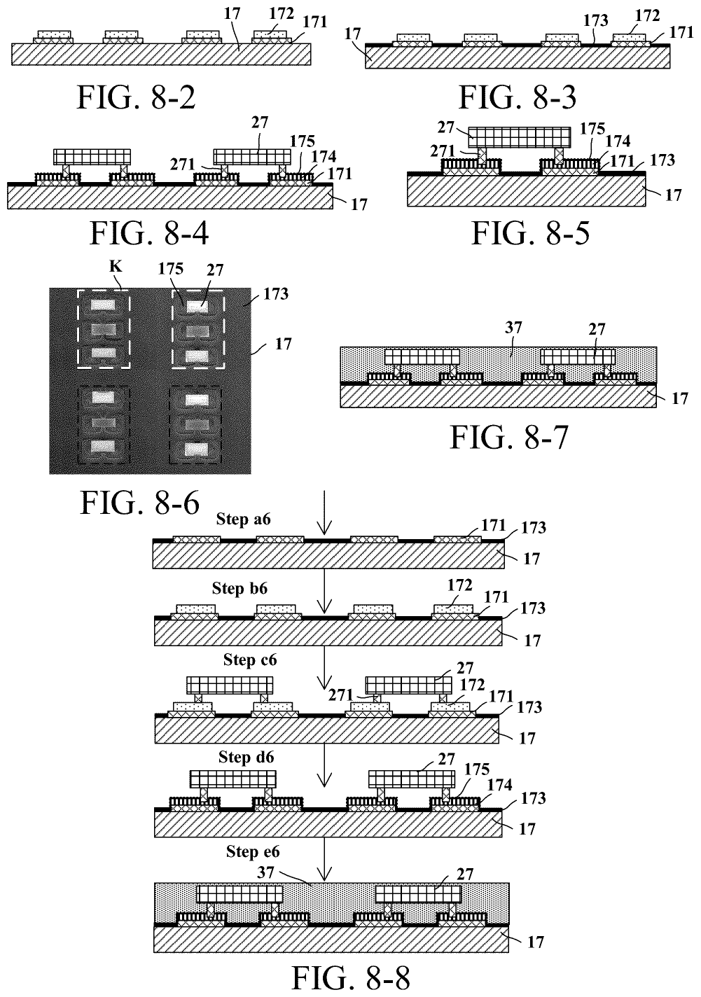

Step e4: laminate a surface of the packaging layer provided with the black adhesive layer 37 with the top surface of the substrate. A state after the lamination is shown in FIG. 7-8.

Step f4: heat and apply pressure facing the substrate 16 to the packaging layer, and press-fit the packaging layer to the substrate 16. During the press-fitting, because the black adhesive layer 37 is in a semi-melted state and is subjected to pressure facing the substrate 16, the light-emitting surfaces of the LED chips 26 are gradually exposed from (that is, run through) the black adhesive layer 37. In addition, an outer surface 371 formed by a part suspended on the side surface of the LED chip 26 is an inclined surface or a curved surface. Refer to FIG. 7-9 and FIG. 7-10.

Step g4: as shown in FIG. 7-11, after the black adhesive layer 37 and the first packaging layer 38 are cured, the substrate jig 6 is removed, and the electronic element 46 is arranged on the back surface of the substrate.

Another exemplary manufacturing method is shown in FIG. 7-12 to FIG. 10-8. includes, but not limited to:

Step a5: manufacture the substrate shown in FIG. 7-12.

In this example, completing die bonding of an LED chip 26 on the top surface of the substrate is included, and the electronic element 46 is arranged on the back surface of the substrate.

Step b5: manufacture the substrate jig 6 shown in FIG. 7-13.

As shown in FIG. 7-13, the substrate jig 6 in this example includes an accommodating cavity 61 adapted for the substrate, and the bottom of the accommodating cavity 61 in this example is provided with an accommodating groove 63 for accommodating an electronic element 46.

Step c5: fix the manufactured substrate in FIG. 7-12 on the substrate jig 6 shown in FIG. 7-13. A state after the fixation is shown in FIG. 7-14. The electronic element 46 on the back surface of the substrate 16 is accommodated in the accommodating groove 63. The substrate jig 6 fixes the substrate, so that the substrate can be maintained in a steady state.

Step d5: laminate a surface of the packaging layer (the packaging layer shown in FIG. 7-4 is still used in this example) provided with the black adhesive layer 37 with the top surface of the substrate. A state after the lamination is shown in FIG. 7-15.

Step e5: heat and apply pressure facing the substrate 16 to the packaging layer, and press-fit the packaging layer to the substrate 16. During the press-fitting, because the black adhesive layer 37 is in a semi-melted state and is subjected to pressure facing the substrate 16, the light-emitting surfaces of the LED chips 26 are gradually exposed from (that is, run through) the black adhesive layer 37, as shown in FIG. 7-16 and FIG. 7-17.

Step f5: after the black adhesive layer 37 and the first packaging layer 38 are cured, the substrate jig 6 is removed, to obtain the display module shown in FIG. 7-6.

In an application scenario of this embodiment, in the foregoing two exemplary manufacturing methods, when the first bearing film 62 is directly set as the transparent protection film 30, the transparent protection film 30 may be reserved. When the first bearing film 62 is not set as the transparent protection film 30, the transparent protection film 30 may be arranged on the first packaging layer 38 after the black adhesive layer 37 is press-fit onto the substrate 16 and after the first bearing film 62 is removed. Certainly, when the display module shown in FIG. 7-1 to FIG. 7-4 is manufactured, the first bearing film 62 may alternatively be removed in this example.

It can be learned that in the manufacturing method for a display module provided in this embodiment, an adhesive sheet production process may be used, and the light-emitting surface of the LED chip in the COB LED technology is exposed from the black adhesive layer through press-fitting. Because the used black adhesive layer has specific viscosity and is more easily bonded to the main body of the substrate and the LED chips, air-tightness can be improved, and the LED chips can be better protected; and during press-fitting, seams between the main body of the substrate and the LED chip and the like may be fully filled using fluidity of the black adhesive layer. In this way, on the top surface of the substrate, other regions beyond the LED chips are all filled in black, and therefore the contrast can be further improved. In addition, the light-emitting surface of the LED chip is covered by the first packaging layer, to reduce the light transmittance loss rate.

In addition, it is not necessary to additionally spray a black ink layer or the like on the top surface of the substrate to set the top surface of the substrate in black, so that the manufacturing process can be simplified, to reduce the manufacturing costs. In addition, because the black ink layer is omitted, the thickness of the display panel can be reduced. In addition, the transparent protection film is further arranged on the first packaging layer, so that the display performance can be optimized and the protection effect can be improved. Therefore, the display module and the manufacturing method therefor provided in this embodiment take into consideration high contrast, low light transmittance loss, and high protection performance.

### Embodiment 7

In the related technology, after an LED chip is soldered onto a substrate through a solder pad, a part of the solder pad is not covered by the LED chip. During soldering, a used tin solder paste becomes silver after being melted and covers a surface of the solder pad, and silver has a light reflection characteristic. As a result, a display screen is insufficiently black when the screen is off, the contrast of the display screen is reduced, and the display effect is affected. For this problem, one practice is to package, on a surface of the LED chip, a black adhesive layer, which is also referred to as a black optical layer in the present invention, covering the LED chip and the surface of the solder pad, and a silver outer surface is covered through the black adhesive layer to intend to improve the contrast. However, the black adhesive layer causes a decrease in an light-emitting rate of the LED chip, and increases power consumption and dissipated heat of the LED chip. This embodiment provides a solder paste that can resolve this technical problem, and the solder paste is applicable to soldering of an LED chip in the foregoing embodiments and a corresponding solder pad on a substrate. Certainly, it should be understood that the solder paste in this embodiment is not limited to being applied to a display module, and may also be applied to another application scenario.

The solder paste provided in this embodiment includes a metal solder, a soldering flux, and a melanin that are mixed together. In addition, in this embodiment, the density of the melanin is less than the density of the metal solder, thereby ensuring that when the solder paste is heated and melted to be used for soldering, the melanin can be extruded to a surface of the solder paste under an agglomeration effect of the metal solder, so that the surface is presented in black. Therefore, when the solder paste is applied to soldering of an LED chip, it can be ensured that after the LED chip is soldered to a corresponding solder pad on the substrate, a surface of the solder paste covering a surface of the solder pad is presented in black. Compared with the existing technology in which the surface of the tin solder paste covering the surface of the solder pad is presented in silver, in this embodiment, optical characteristics of the black may be used to absorb incident light, thereby avoiding a case that the solder pad reflects light because the surface of the solder pad is presented in silver, so that the contrast can be improved. In addition, it is not necessary to use an additional process or additionally arrange a black adhesive layer structure on the surface of the LED chip, thereby further simplifying the structure and reducing the costs.

In some examples of this embodiment, the melanin may be mixed in the solder paste in a physical form of particles. In addition, in some application scenarios, these particles may be evenly mixed in the solder paste. Certainly, in some other application scenarios, these particles may alternatively be mixed in the solder paste in an uneven state. In this embodiment, when the melanin is mixed in the solder paste in the physical form of particles, the size of these particles may be set at a micron level or nanometer level, that is, the melanin in this case may include, but not limited to, at least one of micron-sized non-metal black particles and nanometer-sized non-metal black particles. To be specific, in this example, the melanin may include only micron-sized non-metal black particles or include only nanometer-sized non-metal black particles, or may be set according to a requirement to include both micron-sized non-metal black particles and nanometer-sized non-metal black particles. In addition, a specific size may be set according to a specific application scenario requirement.

In some other examples of this embodiment, the melanin may alternatively not exist in the solder paste in a physical form of particles. For example, the melanin may be dissolved in the solder paste.

In this embodiment, the agglomeration effect of the metal solder means that when the solder paste is heated and melted during soldering, the metal solder in the solder paste sinks and is attached onto to-be-soldered objects (for example, a solder pad and an electrode of a chip), and the melanin in the solder paste is compressed oppositely and buoyed up when the metal solder is sinking, and is finally extruded to a surface of the solder paste, thereby attached to the surface of the solder paste, so that the surface is presented in black. In this embodiment, to ensure that the depth of the surface of the solder paste in black satisfies a requirement and to ensure black distribution evenness on the surface of the solder paste, a weight ratio of the melanin in the solder paste may be set to a range from 1% to 1.4%. For example, a weight ratio of the melanin in the solder paste may be set to 1%, 1.1%, 1.12%, 1.15%, 1.2%, 1.25%, 1.3%, 1.35%, or 1.4%.

In this embodiment, the melanin may be made of various black materials that can achieve the foregoing objective, for example, but not limited to, carbon. When the melanin is mixed in the solder paste in the physical form of particles, the melanin in this embodiment includes carbon particles mixed in the solder paste, and the carbon particles may have a particle size at a micron level, for example, carbon particles less than or equal to 2 microns, or at a nanometer level, for example, carbon particles less than or equal to 500 nanometers.

In this embodiment, the metal solder included in the solder paste may be, but not limited to, a tin alloy solder. In this case, the solder paste in this embodiment may also be referred to as tin paste. In addition, it should be understood that in this embodiment, the material of the tin alloy solder may be flexibly set. For example, the tin alloy solder may be made of a leaded solder alloy, for example, a tin-lead alloy, a tin-lead-bismuth alloy, or a tin-lead-silver alloy; or the tin alloy solder may be made of a lead-free solder alloy, for example, a tin-silver alloy, a tin-bismuth alloy, a tin-zinc alloy, a tin-antimony, a tin-silver-copper alloy, or a tin-bismuth-silver alloy.

In this embodiment, the soldering flux of the solder paste may include, but not limited to, at least one of the following:
Resin: a resin may be arranged to increase adhesion of the solder paste, and can play a role in fixing a to-be-soldered object very well and play a role in protecting the soldered solder pad and preventing the soldered solder pad from being oxidized again;
Thixotropic agent: a thixotropic agent may be arranged to regulate viscosity and printing performance of the solder paste, and can play a role in preventing a phenomenon such as tailing or adhesion from occurring in printing;
Activator: an activator may be arranged to play a role in removing a surface layer of the solder pad and an oxidizing substance in a soldering position on a to-be-soldered object (for example, an electrode of an LED chip), and play a role in reducing tin surface tension and lead surface tension; and
Solvent: the ingredient is a solvent for a flux component, and can play a role in performing regulation evenly when the solder paste is being stirred.

For ease of understanding, the solder paste shown in FIG. 8-1 is used as an example below for description. In the example shown in FIG. 8-1, the solder paste is a tin paste 64 including a tin alloy solder, and the tin paste 64 contains carbon particles 65 used as a melanin. When the tin paste 64 is heated and melted during soldering, the metal solder in the tin paste 64 sinks and is attached onto to-be-soldered objects, and the carbon particles 65 in the solder paste are compressed oppositely and buoyed up when the metal solder is sinking, and is finally extruded to a surface of the tin paste 64, so that the surface is presented in black, that is, the surface of the tin paste 64 covering the surface of the solder pad is presented in black. Therefore, the contrast can be improved, to improve the illumination or display effect.

This embodiment further provides a substrate, as shown in FIG. 8-2. A solder pad 171 used for soldering an electrode of an LED chip is arranged on a top surface of the substrate 17. It should be understood that in this embodiment, the quantity of and the arrangement of solder pads 171 on the top surface of the substrate 17 may be flexibly set according to an application requirement. For example, a plurality of solder pads 171 may be arranged, and the plurality of solder pads 171 are arranged in an array on the substrate 17 or adjacent rows of solder pads 171 are staggered with each other. In some examples of this embodiment, the material of the solder pad 171 may be, but not limited to, copper, silver, gold, or the like. In this embodiment, the solder pad 171 may be electrically connected to, but not limited to, an electrode of an LED chip. In addition, for the LED chip in this embodiment, reference may be made to, but not limited to, the LED chip shown in the foregoing embodiments. Details are not described herein again. In addition, the substrate 17 in this embodiment may be, but not limited to, the substrate in the foregoing embodiments.

As shown in FIG. 8-2, in this embodiment, a solder paste 172 is further arranged on each solder pad 171 on the substrate 17. In this embodiment, a manner in which the solder paste 172 is arranged on each solder pad 171 may be flexibly selected from, for example, manners, but not limited to, printing and mold-pressing. The solder paste 172 includes the melanin. Therefore, after an electrode of an LED chip is soldered to a corresponding solder pad 171, the melanin in the solder paste 172 is extruded to a surface of the solder paste 172 under the agglomeration effect of the metal solder, and the surface is presented in black, thereby improving the contrast of a display module manufactured using the substrate.

As shown in FIG. 8-3, in some examples of this embodiment, to further improve the contrast of the display module manufactured using the substrate shown in FIG. 8-2, a black masking layer 173 may be further arranged in a region on the top surface of the substrate beyond the solder pad 171. The black masking layer 173 in this embodiment may be, but not limited to, a black adhesive layer or a black ink layer, and may be formed through, but not limited to, a mold-pressing process when being a black adhesive layer; or may be formed through, but not limited to, a spraying process when being a black ink layer. The arrangement of the black masking layer 173 avoids a case that a region beyond the solder pad 171 on the top surface of the substrate 17 reduces the contrast of the display module because of light reflection, and can further improve the display or illumination effect.

When a display module is manufactured through the substrate shown in FIG. 8-2 or FIG. 8-3, because the solder paste 172 is arranged on each solder pad 171 in advance, it is only necessary to arrange and solder an LED chip and a corresponding solder pad 171 in alignment. However, it should be understood that in some examples, the solder paste 172 may alternatively not be arranged on each solder pad 171 in advance, and instead a cladding solder paste 172 is preset on an electrode of an LED chip. Certainly, in some examples, the solder paste 172 may alternatively be preset on both the solder pad 171 on the substrate and an electrode of an LED chip, which may be specifically flexibly selected according to an application requirement. Details are not described herein again.

In addition, it should be understood that in some application scenarios of this embodiment, a solder pad may also be arranged correspondingly on the back surface of the substrate according to a requirement with reference to the solder pad 171 on the top surface thereof, and the solder paste 172 may be preset or the solder paste 172 may not be preset on the solder pad on the back surface of the substrate. The substrate 17 in this case may be used for manufacturing a display module for emitting light from two surfaces.

This embodiment further provides a display module. The display module may be used as a display panel applied to the field of display, and may also be used as an illumination light source applied to the field of illumination. The display module includes a substrate shown in the foregoing examples, and further includes an LED chip. An electrode of the LED chip is soldered onto a solder pad through a solder paste, the solder paste covers the solder pad, and a melanin is located on a surface of the solder paste, thereby avoiding a case that the tin paste covering the solder pad is in silver and reflects light, to cause poor contrast.

For example, an exemplary display module is shown in FIG. 8-4 and FIG. 8-5. FIG. 8-5 is a schematic structural diagram of soldering of a single LED chip on a substrate in FIG. 8-4. The display module includes the substrate shown in FIG. 8-3, and further includes a plurality of light-emitting units arranged on a top surface of the substrate, where each light-emitting unit includes at least one LED chip 27, and electrodes 271 of the LED chips 27 are soldered to respective corresponding solder pads 171 through a solder paste. When the solder paste is being heated and melted, a metal solder in the solder paste sinks and is separately attached to the solder pads 171 and the electrodes 271 of the LED chips 27 to form a metal solder layer 174, and the melanin in the solder paste is compressed oppositely and buoyed up when the metal solder is sinking, and is finally extruded to a surface of the solder paste, thereby being attached to the surface of the solder paste to form a melanin layer 175, so that a region on the solder pad 171 is further presented in black. Referring to a physical reference diagram shown in FIG. 8-6, the surface on the solder pad is a black melanin layer 175, and is not a silver outer surface anymore. The LED chips 27 shown in FIG. 8-4 and FIG. 8-5 are flip chips. It should be understood that the LED chips may alternatively be replaced with another type of LED chip.

In this embodiment, when the display module shown in FIG. 8-6 is used as a display panel, to implement color display, one light-emitting unit in the display module may be set as one pixel point, and support emission of red light, green light, and blue light. In this embodiment, a set of LED chips arranged at a same pixel point may be referred to as one light-emitting unit, as shown by a mark K in FIG. 8-6. Therefore, in some examples of this embodiment, one light-emitting unit includes three LED chips 27. In some other examples, one light-emitting unit may include more LED chips.

As shown in FIG. 8-7, in some examples of this embodiment, the display module may further include a packaging layer 37 arranged on the top surface of the main body of the substrate and covering the LED chips 27; and the packaging layer 37 in this embodiment may be, but not limited to, the packaging layer shown in the foregoing embodiments. In addition, the packaging adhesive layer may have a light transmittance ranging, but not limited to, from 30% to 100%, and may have a thickness ranging from 20 microns to 1000 microns. For ease of understanding, this embodiment further provides a manufacturing method for a display module, as shown in FIG. 8-8. includes, but not limited to:

Step a6: provide a substrate, an LED chip, and a solder paste.

As shown in step a6 in FIG. 8-8, an exemplary substrate includes a substrate 17, and a solder pad 171 and a black masking layer 173 are arranged on the substrate 17. It may be understood that the black masking layer 173 may be lower than the solder pad 171 or may be flush with the solder pad 171 or higher than the solder pad 171. In this example, the LED chip 27 is a flip chip for exemplification.

Step b6: arrange the solder paste between an electrode of the LED chip and a solder pad.

In this example, the arranging the solder paste between an electrode of the LED chip 27 and a solder pad may include at least one of the following:
Arranging the solder paste on the electrode of the LED chip 27; and
Arranging the solder paste on the solder pad of the substrate.

For example, as shown in step b6 in FIG. 8-8, the solder paste 172 is arranged on each solder pad 171 on the top surface of the substrate 17. In this example, the solder paste is optionally not arranged on the electrode of the LED chip 27, or the solder paste is optionally arranged on the electrode of the LED chip 27 according to a requirement.

Step c6: arrange the electrodes of the LED chip and the solder pads in alignment.

It should be understood that in this step, the LED chip may be transferred onto the substrate through, but not limited to, various chip transfer manners such as mass transfer, and arranged together with a corresponding solder pad in alignment. An example of arrangement in alignment is shown in step c6 in FIG. 8-8. The electrodes 271 of the LED chips 27 and respective corresponding solder pads 171 on the substrate 17 are arranged in alignment, and then the solder paste 172 is located between the corresponding solder pads 171 and electrodes 271.

Step d6: heat the solder paste to solder the electrode of the LED chip onto the solder pad, where the solder paste covers the solder pad, and the melanin is extruded to a surface of the solder paste.

For example, as shown in step d6 in FIG. 8-8, the electrodes 271 of the LED chips 27 are soldered to the respective corresponding solder pads 171 through the solder paste. When the solder paste is being heated and melted, a metal solder in the solder paste sinks and is separately attached to the solder pads 171 and the electrodes 271 of the LED chips 27 to form a metal solder layer 174, and the melanin in the solder paste is compressed oppositely and buoyed up when the metal solder is sinking, and is finally extruded to a surface of the solder paste, thereby being attached to the surface of the solder paste to form a melanin layer 175, so that a region on the solder pad 171 is further presented in black.

Step e6: form a packaging layer on the substrate.

For example, as shown in step e6 in FIG. 8-8, the packaging layer 5 may be formed on the top surface of the substrate in a manner of, but not limited to, mold-pressing or coating.

It can be learned that in the manufacturing method for a display module provided in this embodiment, another special process is not required additionally for the manufacturing process, the original production process path may not be changed, and the manufacturing process is simple, convenient, and fast; and in the manufactured display module, a surface of each solder pad on the substrate is covered by the melanin layer 175 and is presented in black, which can improve the contrast of the display module, to further improve its display or illumination effect. In addition, because it is not necessary anymore to arrange a black adhesive layer on the surface of the LED chip, the light transmittance loss rate of the LED chip is reduced, and power consumption and dissipated heat of the LED chip are reduced.

### Embodiment 8

After an LED chip 27 is soldered onto a substrate through a solder pad, a part of the solder pad is not covered by the LED chip 27. During soldering, a used tin solder paste becomes silver after being melted and covers a surface of the solder pad, and silver has a light reflection characteristic. As result, a display screen is insufficiently black when the screen is off, the contrast of the display screen is reduced, and the display effect is affected. For this problem, this embodiment further provides another display module and another manufacturing method therefor that can resolve this technical problem. In addition, the display module and the manufacturing method therefor in this embodiment may be implemented independently of other embodiments.

The manufacturing method for a display module provided in this embodiment includes, but not limited to:

Step a7: arrange a plurality of light-emitting units on a top surface of the substrate. In this embodiment, a plurality of solder pads electrically connected to electrodes of the light-emitting units are arranged on the top surface of the substrate, and distribution of the solder pads may be a matrix distribution, and certainly may alternatively be set as another distribution manner according to a requirement, which is not limited in this embodiment. In some examples of this embodiment, the material of the solder pad may be, but not limited to, copper, silver, gold, or the like. In this embodiment, the solder pads on the top surface of the substrate may be electrically connected to, but not limited to, the electrodes of the light-emitting units, and the electrodes of the light-emitting units may be electrically connected to the corresponding solder pads through, but not limited to, a solder or a conducting adhesive. It should be understood that for the light-emitting units and the substrate in this embodiment, reference may be made to, but not limited to, the light-emitting units and the substrate in the foregoing examples. Details are not described herein again. It should be understood that in this embodiment, a light-emitting unit includes a plurality of LED chips 27, and specific arrangement of the LED chips may be delta-shaped arrangement, linear arrangement, centrosymmetric arrangement, or the like, which is not limited in this embodiment.

Step b7: form a black adhesive layer, which may also be referred to as a black deposition layer or a black molecule layer 66 or a black optical layer. Molecules (which may also be referred to as particles in this embodiment) of a black base material are spluttered onto the top surface of the substrate and a surface of each light-emitting unit (that is, a light-emitting surface and side surfaces of the light-emitting unit are all covered, and the light-emitting surface of the light-emitting unit is a surface of the light-emitting unit far away from the top surface of the substrate, a back surface of the light-emitting unit is a surface of the light-emitting unit close to the top surface of the substrate, and the side surfaces of the light-emitting unit are surfaces between the light-emitting surface and the back surface of the light-emitting unit), to form a black deposition layer 66 covering the top surface of the substrate and a surface of each light-emitting unit.

In some embodiments, a manner of forming the black adhesive layer or the black deposition layer 66 is that the molecules of the black base material are sputtered onto the top surface of the substrate and a surface of each light-emitting unit 28, and therefore there is no impact from a flatness of the top surface of the substrate and a whole flatness after the light-emitting units 28 are arranged on the top surface thereof; and the sputtered molecules may be deposited in a region where a black deposition layer needs to be formed to form a black layer with an even thickness, and the molecules may be sputtered into any region where a black deposition layer needs to be formed, so that there is no blind angle for coverage, thereby ensuring consistency of the formed black deposition layer, reducing a black chrominance difference between positions on the black deposition layer, which can improve the contrast of the display screen manufactured using the display module and can avoid emitting light at a side viewing angle of the display screen to cause a color spot; and the sputtering process has a low production control difficulty and a high finished product rate, and can reduce the production costs. For ease of understanding, several exemplary sputtering processes are described below in this embodiment.

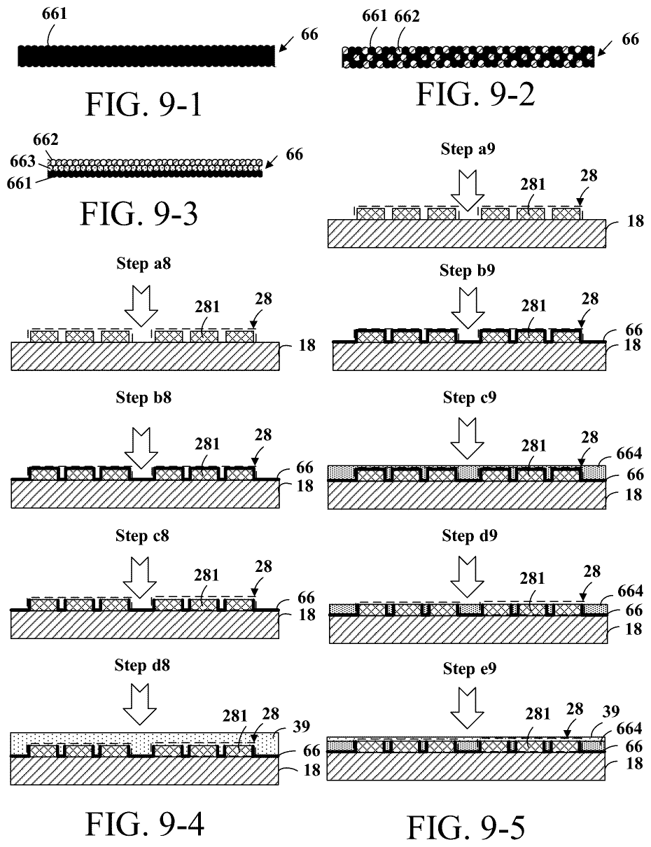

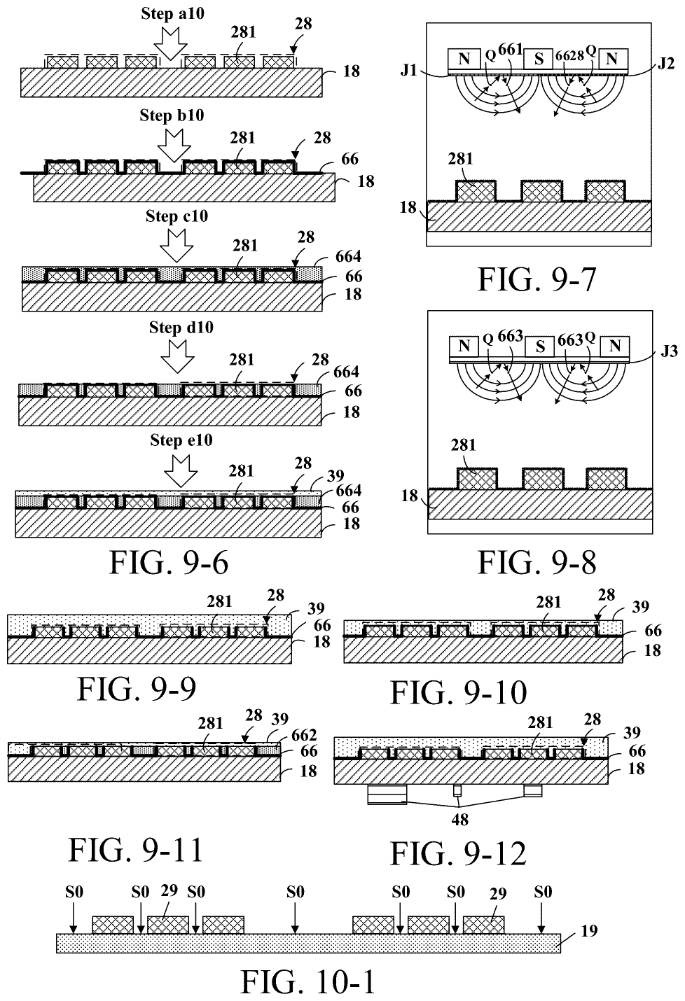

Example 1: in a vacuum magnetically conducting environment, a magnetic field is used to guide ions to bombard a black base material, and molecules of the black base material are evenly sputtered onto a top surface of the substrate and a surface of each light-emitting unit 28, thereby forming a black deposition layer through deposition. An exemplary structure of the black deposition layer formed in this example is shown in FIG. 9-1. A black deposition layer 66 in this example is formed by depositing first molecules 661.

Example 2: in a vacuum magnetically conducting environment, a magnetic field is used to guide ions to bombard at least two black base materials simultaneously, and molecules of the at least two black base materials are evenly sputtered onto a top surface of the substrate and a surface of each light-emitting unit 28, thereby forming a black deposition layer through deposition. In this example, at least two black base materials are bombarded simultaneously. Therefore, molecules of the at least two black base materials may be simultaneously sputtered into a region where a black deposition layer needs to be formed, and a black layer including a plurality of types of molecules that are mixed together is formed through deposition. An exemplary structure of the black deposition layer formed in this example is shown in FIG. 9-2. The black deposition layer 66 in this example is formed by depositing first molecules 661 (from a first black base material) and second molecules 662 (from a second black base material) simultaneously sputtered into a preset region. Certainly, it should be understood that this example is not limited to a case that molecules of two black base materials are sputtered and deposited to form a black layer, and molecules of three or more black base materials may be sputtered and deposited to form a black layer according to a requirement. Details are not described again in this example.

Example 3: in a vacuum magnetically conducting environment, a magnetic field is used to guide ions to bombard at least two black base materials sequentially, and molecules of the at least two black base materials are evenly sputtered onto a top surface of the substrate and a surface of each light-emitting unit 28 sequentially, thereby forming a black deposition layer through deposition. In this example, at least two black base materials are bombarded sequentially. Therefore, molecules of the at least two black base materials may be sequentially sputtered into a region where a black deposition layer 66 needs to be formed, and a black layer including a plurality of types of molecules is formed through deposition. An exemplary structure of the black deposition layer formed in this example is shown in FIG. 9-3. In this example, in a period of time t1, a magnetic field may be first used to guide ions to bombard a first black base material, and first molecules 661 of the first black base material are evenly sputtered onto a top surface of the substrate and a surface of each light-emitting unit 28, to form a first molecule sub-layer; then in a period of time t2, the magnetic field is used to guide ions to bombard a third black base material, and third molecules 663 of the third black base material are evenly sputtered onto the top surface of the substrate and the surface of each light-emitting unit 28, to form a second molecule sub-layer; and finally in a period of time t3, the magnetic field is used to guide ions to bombard a second black base material, and second molecules 662 of the second black base material are evenly sputtered onto the top surface of the substrate and the surface of each light-emitting unit 28, to form a third molecule sub-layer. Certainly, it should be understood that this example is not limited to a case that molecules of three black base materials are sequentially sputtered and deposited to form a black layer, and molecules of two or more than three black base materials may be sequentially sputtered and deposited to form a black layer according to a requirement. In addition, the foregoing molecule sub-layers in this example may alternatively be arranged in an alternate manner. For example, the first molecules 661 and the second molecules 662 are alternated to form a corresponding molecule sub-layer. Details are not described again in this example. In addition, in this example, replacement of different target materials may be, but not limited to, manual replacement or device automation replacement.

It may be learned according to the foregoing examples that, the sputtering process in this embodiment may be, but not limited to, a magnetron sputtering process, control of consistency of the formed black deposition layer 66 and a covering rate is simple, the manufactured black deposition layer 66 has a high finished product rate, efficiency is high, and costs are low. In addition, the black deposition layer 66 in this embodiment may be formed by depositing one type of molecules or may be formed by performing mixed deposition (for example, as shown in FIG. 9-2) or layered deposition (for example, as shown in FIG. 9-3) on two or more types of molecules. Therefore, the black deposition layer may be flexibly correspondingly arranged according to requirements of a specific application scenario on the light transmittance and the black chrominance of the black deposition layer. Particularly, the black deposition layer 66 in the foregoing example 2 and example 3 includes at least two types of molecules. Therefore, characteristics of the black deposition layer 66 such as the black chrominance and the light transmittance may be flexibly adjusted to satisfy an application requirement, to improve the display effect while ensuring the contrast. In addition, it should be understood that this embodiment is not limited to using the magnetron sputtering process, and may alternatively use another sputtering process that can implement the black deposition layer to perform equivalent replacement, which is not limited in this embodiment.

The foregoing black base material in this embodiment may be flexibly selected. For example, in some examples, the black base material in this embodiment may include, but not limited to, at least one of an oxide, a silicide, a nitride, and a composite, and the composite in this embodiment may be, but not limited to, a composite of at least two of an oxide, a silicide, and a nitride. For example, in some application scenarios, the black base material may be, but not limited to, at least one of an AZO base material, a SiO₂ base material, a SiO base material, a SiC base material, a SiN base material, or a composite base material of at least two of the foregoing base materials. For example, the first molecules 661 in the black deposition layer 66 shown in FIG. 9-2 may be, but not limited to, molecules of one of the foregoing base materials, and then the second molecules may be molecules of another one of the foregoing base materials; and the first molecules 661, the second molecules 662, and the third molecules 663 in the black deposition layer 66 shown in FIG. 9-3 may be, but not limited to, molecules of three of the foregoing base materials respectively. In addition, each of the foregoing exemplary oxide base material, silicide base material, nitride base material, and composite base material shown in this embodiment is an existing ordinary material, whose costs are low and commonality is good.

The thickness of the black deposition layer 66 manufactured in this embodiment may also be flexibly set according to requirements on the light transmittance and the black chrominance of the black deposition layer 66. For example, in some application examples, the thickness of the formed black deposition layer is greater than or equal to 2 nanometers and is less than or equal to 300 nanometers. It can be learned that the black deposition layer 66 in this example is an ultra thin layer. Therefore, the whole thickness of the display module is not additionally greatly increased, thereby facilitating ultra thinning of the display module.

Step c7: remove at least one part of the black adhesive layer or the black deposition layer 66 on a light-emitting surface of each of the light-emitting units.

In this embodiment, after the foregoing black deposition layer 66 is formed, at least one part of the black deposition layer 66 on the light-emitting surface of each light-emitting unit 28 is further removed, thereby ensuring the efficiency of emitting light by each light-emitting unit 28 through the light-emitting surface thereof. When the display module is manufactured into a display screen, display luminance of the display screen can be ensured. It should be understood that in this embodiment, whether the black deposition layer 66 on the light-emitting surface of the light-emitting unit 28 is completely removed or only partially removed, and how much is specifically removed when being partially removed may be flexibly set according to a specific application scenario requirement and the light transmittance of the black deposition layer 66. For example, when the black deposition layer 66 is opaque (being opaque in this embodiment is relative, for example, when the light transmittance of the black deposition layer 66 is less than or equal to 20% or 10%, the black deposition layer 66 may be considered as being opaque), the black deposition layer on the light-emitting surface of each light-emitting unit 28 may be completely removed. Certainly, even if the black deposition layer 66 is light-transmitting, the black deposition layer 66 on the light-emitting surface of each light-emitting unit 28 may be completely removed according to a specific requirement. When the black deposition layer 66 is light-transmitting, if only one part of the black deposition layer 66 on the light-emitting surface of each light-emitting unit 28 is removed, for example, the thickness of the black deposition layer 66 before removing is d and the thickness of the black deposition layer 66 after removing is X*d, where a value of X is greater than or equal to 0 and is less than 1, a specific value of X may be flexibly determined according to a current luminance requirement and the light transmittance, the black chrominance, and the thickness of the black deposition layer 66, which is not specifically limited in this embodiment.

In this embodiment, a region where the black deposition layer 66 has a maximum thickness has a lowest light transmittance, and correspondingly a region where the black deposition layer 66 has a minimum thickness has a highest light transmittance. The light transmittance of the region where the black deposition layer 66 has the maximum thickness may be set to be greater than 30%, and a specific value may be set according to an application requirement. For example, in some application scenarios, the light transmittance thereof may be set to be greater than or equal to 30% and less than or equal to 50%, thereby satisfying the light transmission efficiency requirement and ensuring the display effect while improving the contrast.

Certainly, in some application scenarios, according to a requirement, only one part of the black deposition layer 66 on light-emitting surfaces of a part of light-emitting units 28 is removed, and the black deposition layer on light-emitting surfaces of another part of light-emitting units 28 is completely removed; and even only one part of the black deposition layer 66 on light-emitting surfaces of a part of light-emitting units 28 is removed, the black deposition layer on light-emitting surfaces of a part of light-emitting units 28 is completely removed, and the black deposition layer of light-emitting surfaces of the remaining part of light-emitting units is not removed, which may be specifically flexibly set according to an application requirement.

It should be understood that in this embodiment, a manner of removing the black deposition layer is not specifically limited either. For example, in some application examples, after the foregoing black deposition layer is formed, before a next working procedure is performed, the black deposition layer on the light-emitting surface of each light-emitting unit may be directly removed in a manner of, but not limited to, laser removing, where the laser removing has advantages such as high efficiency and precision, a mature process, and low costs. In the present application example, at least one part of the black deposition layer on the light-emitting surface of each of the light-emitting units may be directly removed using laser. For example, the black deposition layer on the light-emitting surface of each of the light-emitting units may be illuminated using laser, to remove at least one part of the black deposition layer on the light-emitting surface of each of the light-emitting units.

For another example, in another example, before the removing at least one part of the black deposition layer on a light-emitting surface of each of the light-emitting units, the manufacturing method may further include: forming a sacrificed packaging layer on the black deposition layer, where the sacrificed packaging layer is an adhesive layer. In the present application example, the removing at least one part of the black deposition layer on a light-emitting surface of each of the light-emitting units may include: removing the sacrificed packaging layer on the light-emitting surface of each light-emitting unit together with the at least one part of the black deposition layer on the light-emitting surface of each light-emitting unit. The present application example may use, but not limited to, a process such as grinding or plasma etching, to remove the sacrificed packaging layer on the light-emitting surface of each light-emitting unit together with the at least one part of the black deposition layer on the light-emitting surface of each light-emitting unit. The processes such as the grinding process and plasma etching also have advantages such as high efficiency and precision, mature process, and low costs. Certainly, this embodiment is not limited to removing only at least one part of the black deposition layer on the light-emitting surface of each light-emitting unit, and at least one part of the black deposition layer in another region may alternatively be removed according to a requirement. For example, the black deposition layer on at least one side surface of the light-emitting unit is removed.

In this embodiment, when the black deposition layer on the light-emitting surface of each light-emitting unit needs to be completely removed, as an alternative process, before the foregoing step b7, a mask in a corresponding shape is used to cover the light-emitting surface of each light-emitting unit, and another region where the black deposition layer needs to be formed is exposed from the mask, thereby directly forming the black deposition layer not covering the light-emitting surface of each light-emitting unit in step c7. In the alternative process, the step of removing the black deposition layer does not need to be performed again. However, for this manner of using a mask, a mask needs to be additionally manufactured, costs are high, efficiency is low, and mask manufacturing precision directly affects coverage precision of the black deposition layer; and compared with a manner of first directly forming the black deposition layer on the light-emitting surface of each light-emitting unit and then removing all of the black deposition layer or removing a part of the black deposition layer according to a requirement, precision control difficulty is higher. Certainly, this alternative process cannot satisfy a requirement of forming the black deposition layer on the light-emitting surface of each light-emitting unit, and application scenarios are more limited.

Step d7: form, on the top surface of the substrate, a packaging layer covering the black deposition layer and each of the light-emitting units, where the packaging layer is a light-transmitting layer.

It should be understood that the forming process and the material of the first packaging layer in this embodiment may be flexibly set, which is not limited in this embodiment. For example, in some examples, the first packaging layer may be, but not limited to, an adhesive layer, and may be formed in a manner of, but not limited to, coating, mold-pressing, printing, or mounting after being manufactured into a film in advance. The first packaging layer in this embodiment may protect the light-emitting units and the black deposition layer. For example, in some application examples, the first packaging layer may be a transparent packaging adhesive layer made of a transparent epoxy glue, thereby sealing and protecting the light-emitting units and the black deposition layer on the substrate. In some application scenarios, at least one of white powder (for example, including, but not limited to, SiO₂ powder), a melanin, light conversion particles (for example, fluorescent powder or quantum dot), and light diffusion particles may be added to the transparent epoxy glue according to a requirement, thereby further adjusting the light-emitting effect of the display module. In addition, in this embodiment, an upper surface of the first packaging layer (that is, a surface of the first packaging layer far away from the top surface of the substrate) may be set as a matte surface, a shiny surface, a frosted surface, a fogged surface, or the like according to a requirement, thereby achieving different appearance effects and light-emitting effects, and further enriching display effects and improving user experience satisfaction.

For ease of understanding, display module manufacturing processes provided in this embodiment are exemplified below in this embodiment with reference to accompanying drawings. An exemplary display module manufacturing process is shown in FIG. 9-4, and includes, but not limited to:

Step a8: arrange a plurality of light-emitting units 28 on a top surface of a substrate 18. The substrate 18 in this example is a display substrate, and at least two LED chips 281 are set to form one light-emitting unit 28. For example, the light-emitting unit 28 includes three LED chips 281 that emit red light, blue light, and green light respectively.

Step b8: sputter molecules of a black base material onto the top surface of the substrate 18 and a surface of each of the light-emitting units 28, to form a black deposition layer 66 covering the top surface of the substrate 18 and the surface of each of the light-emitting units 28. For example, as shown in FIG. 9-7, in this example, a first black base material J1 (for example, SiC base material) and a second black base material J2 (SiN base material) are used. In a vacuum environment, the first black base material J1 and the second black base material J2 are arranged on a platform as target materials, the top surface of the substrate 18 and the light-emitting units 28 arranged on the top surface thereof are arranged opposite to the first black base material J1 and the second black base material J2, and ions Q are guided to simultaneously bombard the first black base material J1 and the second black base material J2, so that first molecules 661 and second molecules 662 of the first black base material J1 and the second black base material J2 are separately sputtered onto the top surface of the substrate 18 and a surface of each light-emitting unit 28, thereby forming the black deposition layer 66 similar to that shown in FIG. 9-2.

Step c8: remove all of the black deposition layer 66 on a light-emitting surface of each of the light-emitting units 28. For example, all of the black deposition layer 66 on the light-emitting surface of each of the light-emitting units 28 may be removed in a manner of, but not limited to, laser removing, and the black deposition layer 66 in other regions is reserved. Certainly, in this example, when the black deposition layer 66 has a light transmission characteristic, only a part of the black deposition layer 66 on the light-emitting surface of each light-emitting unit 28 may alternatively be removed according to a specific application requirement.

Step d8: form, on the top surface of the substrate 18, a first packaging layer 39 covering the black deposition layer 66 and each of the light-emitting units 28.

Another exemplary display module manufacturing process is shown in FIG. 9-5, and includes, but not limited to:

Step a9: arrange a plurality of light-emitting units 28 on a top surface of a substrate 18.

Step b9: sputter molecules of a black base material onto the top surface of the substrate 18 and a surface of each of the light-emitting units 28, to form a black deposition layer 66 covering the top surface of the substrate 18 and the surface of each of the light-emitting units 28. For example, as shown in FIG. 9-8, in this example, a third black base material J3 (for example, SiO base material) is used. In a vacuum environment, the third black base material J3 is arranged on a platform as a target material, the top surface of the substrate 18 and the light-emitting units 28 arranged on the top surface thereof are arranged opposite to the third black base material J3, and ions Q are guided to bombard the third black base material J3, so that third molecules 663 of the third black base material J3 are sputtered onto the top surface of the substrate 18 and a surface of each light-emitting unit 28, thereby forming the black deposition layer 66 similar to that shown in FIG. 9-1.

Step c9: form a sacrificed packaging layer 664 on the black deposition layer 66. The material and the forming process of the sacrificed packaging layer 664 in this example may be the same as those of the foregoing first packaging layer 39, or another forming manner may be used. Details are not described herein again.

Step d9: remove all of the sacrificed packaging layer 664 on a light-emitting surface of each light-emitting unit 28 together with the black deposition layer 66 on the light-emitting surface of each light-emitting unit 28. For example, all of the sacrificed packaging layer 664 on the light-emitting surface of each light-emitting unit 28 together with the black deposition layer 66 on the light-emitting surface of each light-emitting unit 28 may be removed using, but not limited to, a plasma etching process. Certainly, in this example, when the black deposition layer 66 has a light transmission characteristic, only a part of the black deposition layer 66 on the light-emitting surface of each light-emitting unit 28 may alternatively be removed according to a specific application requirement. In addition, the foregoing plasma etching process may alternatively be replaced with a grinding or laser removing process according to a requirement.

Step d9: form a first packaging layer 39 on the sacrificed packaging layer 664. For the material and the forming process of the first packaging layer 39, refer to the foregoing examples. Details are not described herein again.

Still another exemplary display module manufacturing process is shown in FIG. 9-6, and includes, but not limited to:

Step a10: arrange a plurality of light-emitting units 28 on a top surface of a substrate 18.

Step b10: sputter molecules of a black base material onto the top surface of the substrate 18 and a surface of each of the light-emitting units 28, to form a black deposition layer 66 covering the top surface of the substrate 18 and the surface of each of the light-emitting units 28.

In this example, a first black base material J1, a second black base material J2, and a third black base material J3 are used. In a vacuum environment, first, the first black base material J1 is arranged on a platform as a target material, the top surface of the substrate 18 and the light-emitting units 28 arranged on the top surface thereof are arranged opposite to the first black base material J1, and ions Q are guided to bombard the first black base material J1, so that first molecules 661 of the first black base material J1 are sputtered onto the top surface of the substrate 18 and a surface of each light-emitting unit 28; and then the first black base material J1 is replaced with the second black base material J2 to perform the foregoing steps, and finally the second black base material J2 is replaced with the third black base material J3 to perform the foregoing steps, to obtain the black deposition layer structure similar to that shown in FIG. 9-3.

Step c10: form a sacrificed packaging layer 664 on the black deposition layer 66. The material and the forming process of the sacrificed packaging layer 664 in this example may be the same as those of the foregoing first packaging layer 39, or another forming manner may be used. Details are not described herein again.

Step d10: remove the sacrificed packaging layer 664 on a light-emitting surface of each light-emitting unit 28 together with a part of the black deposition layer 66 on the light-emitting surface of each light-emitting unit 28. For example, the sacrificed packaging layer 664 on the light-emitting surface of each light-emitting unit 28 together with a part of the black deposition layer 66 on the light-emitting surface of each light-emitting unit 28 may be removed using, but not limited to, a grinding process. Certainly, the black deposition layer 66 in this example has a light transmission characteristic. As shown in FIG. 9-6, only a part of the black deposition layer 66 on the light-emitting surface of each light-emitting unit 28 is removed, so that in the obtained black deposition layer 66, the thickness of the black deposition layer on the light-emitting surface of each light-emitting unit 28 is less than the thickness of the black deposition layer at another place. Certainly, when all of the black deposition layer 66 on the light-emitting surface of each light-emitting unit 28 is removed, it may be considered that the thickness of the black deposition layer 66 on the light-emitting surface of each light-emitting unit 28 is 0, which also satisfies such a rule that the thickness of the black deposition layer on the light-emitting surface of each light-emitting unit 28 is less than the thickness of the black deposition layer at another place. In addition, it should be understood that the foregoing grinding process may alternatively be replaced with a plasma etching or laser removing process according to a requirement. In this example, the light transmittance of the black deposition layer in the region with the maximum thickness is set to be greater than 30%. Correspondingly, because the thickness of the black deposition layer in the region with the minimum thickness is less than the thickness in the region with the maximum thickness, the light transmittance of the region with the minimum thickness is greater than the light transmittance of the region with the maximum thickness, thereby satisfying the luminous efficiency requirement and ensuring the display effect while improving the contrast.

Step e10: form a first packaging layer 39 on the sacrificed packaging layer 664. For the material and the forming process of the first packaging layer 39, refer to the foregoing examples. Details are not described herein again.

In the foregoing manufacturing process shown in FIG. 9-5 and FIG. 9-6, after the black deposition layer 66 is formed on the light-emitting surface of each light-emitting unit 28, the sacrificed packaging layer 664 is formed on the black deposition layer 66, thereby firmly supporting the periphery of each light-emitting unit 28, to obtain a packaging structure with better integrity. Then, when the sacrificed packaging layer 664 on a light-emitting surface of each light-emitting unit 28 together with at least one part of the black deposition layer 66 on the light-emitting surface of each light-emitting unit 28 is removed, because the sacrificed packaging layer supports the periphery of the light-emitting units 28, operations are easier when a process such as grinding or plasma etching is used, so that the light-emitting units 28 is not prone to falling off, and the black deposition layer 66 on the surface of each light-emitting unit 28 is removed more evenly.

This embodiment further provides a display module, which is manufactured through, but not limited to, a manufacturing method for a display module in the foregoing examples, and the display module includes: a substrate, and a plurality of light-emitting units arranged on a top surface of the substrate; a black deposition layer deposited on the top surface of the substrate and a surface of each light-emitting unit, where the thickness of the black deposition layer on a light-emitting surface of each of the light-emitting units is less than the thickness of the black deposition layer at another place; and a light-transmitting first packaging layer arranged on the top surface of the substrate and covering the black deposition layer and each light-emitting unit. In this embodiment, the thickness of the black deposition layer may be greater than or equal to 2 nanometers and is less than or equal to 300 nanometers.

The thickness of the black deposition layer is greater than or equal to 0 and is less than the maximum thickness. When the thickness of the black deposition layer is equal to 0, the black deposition layer may be opaque or light-transmitting; and when the thickness of the black deposition layer is greater than 0, the black deposition layer is light-transmitting, and may have light transmittance flexibly set. For example, the light transmittance may be set to, but not limited to, be greater than or equal to 30% and less than or equal to 50%, to ensure the display luminance while improving the contrast. For ease of understanding, this embodiment is exemplified below with reference to schematic structure diagrams of several exemplary display modules.

A display module shown in FIG. 9-9 may be manufactured through, but not limited to, the manufacturing process shown in FIG. 9-4, and includes a substrate 18, a plurality of solder pads are arranged on a top surface of the substrate 18, and an electrode of an LED chip 281 included in each light-emitting unit 28 and a corresponding solder pad are soldered through a tin paste or are electrically connected through a conducting adhesive. The display module further includes a black deposition layer 66 deposited on the top surface of the substrate 18 and a surface of each light-emitting unit 28. In addition, in this example, the thickness of the black deposition layer 66 on a light-emitting surface of each light-emitting unit 28 is 0, and the thickness of the black deposition layer 66 at another place ranges from 2 nanometers to 300 nanometers, and may be, for example but not limited to, 10 nanometers, 50 nanometers, 100 nanometers, 200 nanometers, or 300 nanometers. The display module further includes a first packaging layer 39 arranged on the top surface of the substrate 18 and covering the black deposition layer 66 and each of the light-emitting units 28. In this example, the first packaging layer 39 is a transparent adhesive layer, or an adhesive layer mixed with at least one of a melanin, light diffusion particles, and light conversion particles (quantum dots and/or fluorescent powder).

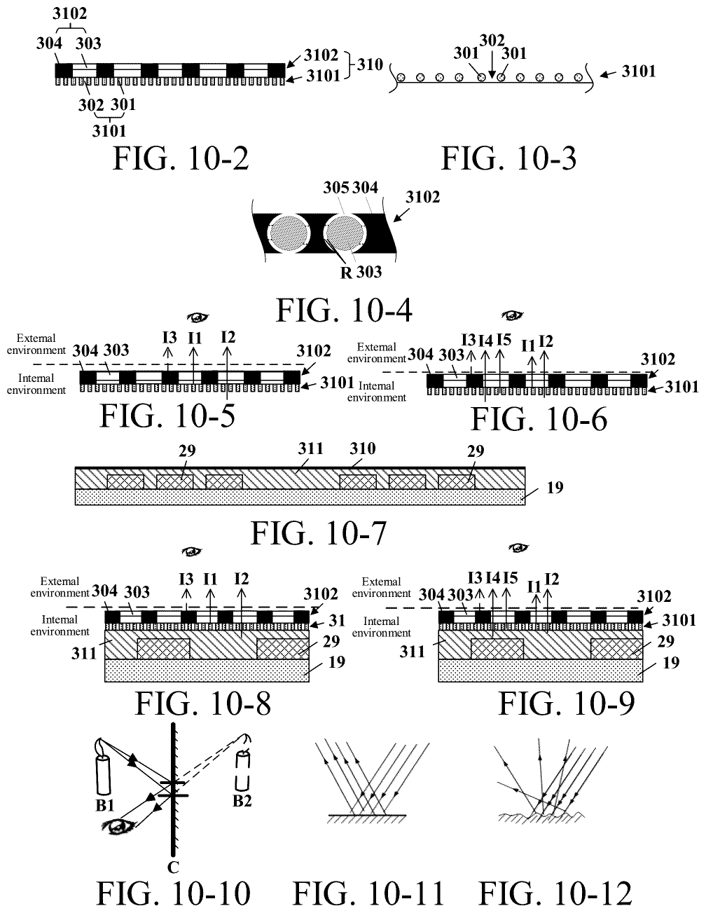

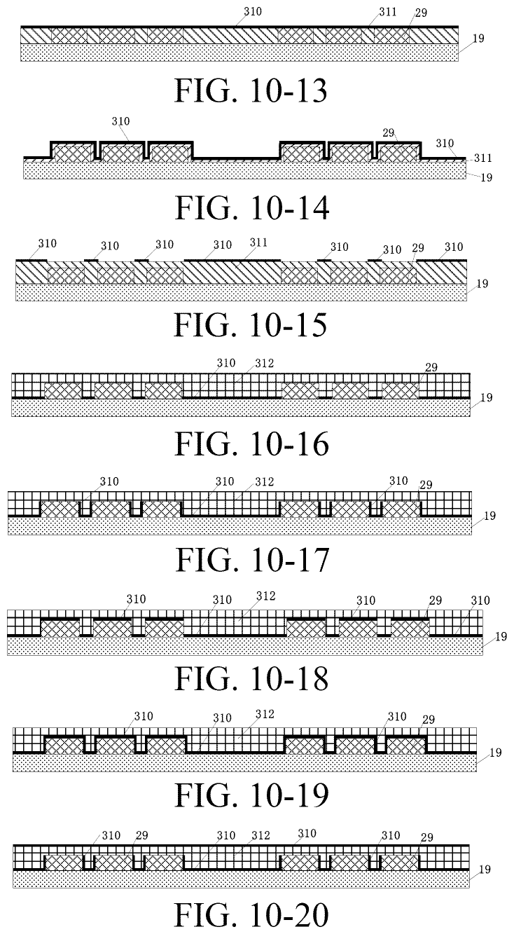

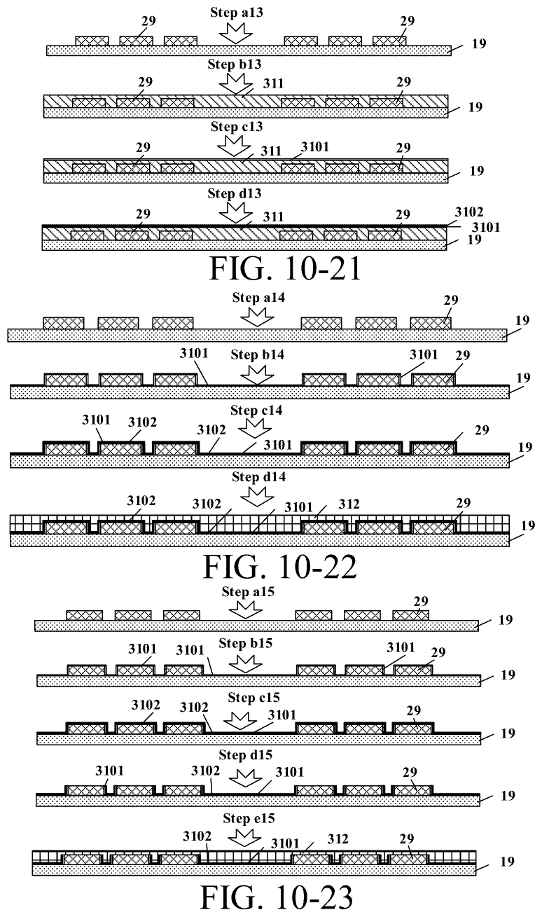

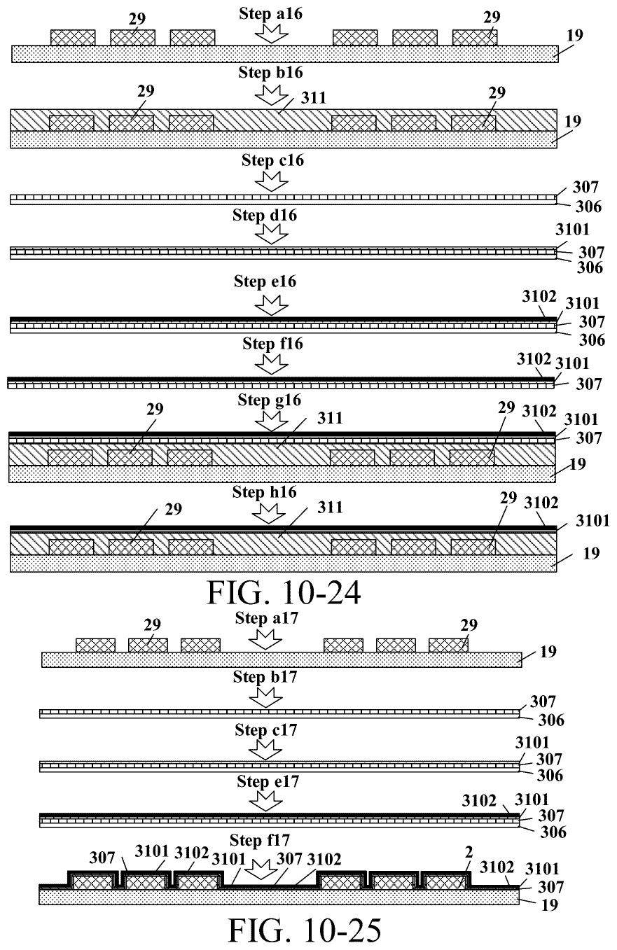

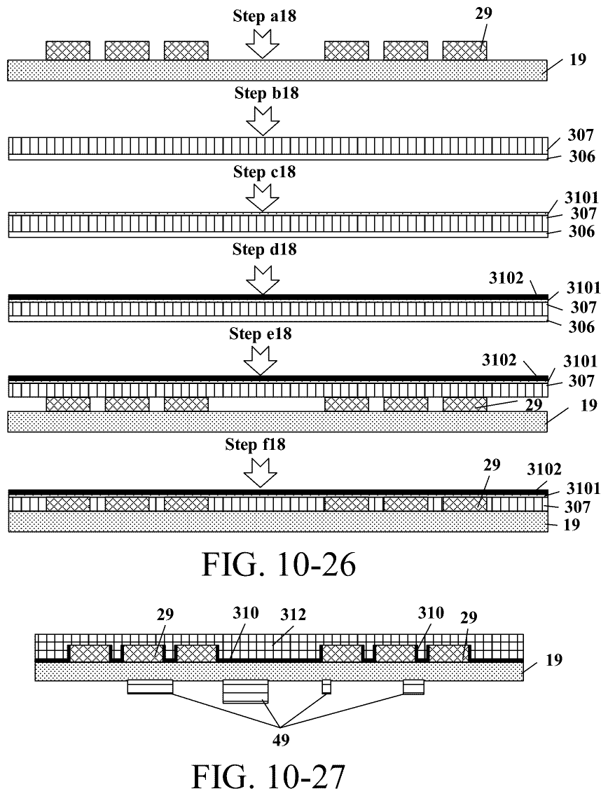

A main difference between a display module shown in FIG. 9-10 and the display module shown in FIG. 9-9 is that the thickness of the black deposition layer 66 on the light-emitting surface of each of the light-emitting units 28 is greater than 0. In addition, the display module in this example may also be manufactured through, but not limited to, the foregoing manufacturing process shown in FIG. 9-4, but only a part of rather than all of the black deposition layer 66 on the light-emitting surface of each of the light-emitting units 28 needs to be removed in FIG. 9-4.

A main difference between another exemplary display module shown in FIG. 9-11 and the display module shown in FIG. 9-9 is that a sacrificed packaging layer 664 is further arranged between the black deposition layer 66 and the first packaging layer 39. The display module in this example may be manufactured through, but not limited to, the foregoing manufacturing process shown in FIG. 9-5, in addition, the sacrificed packaging layer 664 in this example may be a transparent adhesive layer or a packaging layer with at least one of a melanin, light diffusion particles, and light conversion particles, which is not limited in this embodiment.

It can be learned that the black deposition layer in the display module provided in this embodiment is formed by sputtering and depositing the molecules of the black base material onto the top surface of the substrate and the surface of each light-emitting unit, so that the molecules of the black base material may be sputtered onto positions where the black deposition layer needs to be formed, there is no more limitation from flatness of a region where the black deposition layer is to be formed, and the black deposition layer may implement coverage without a blind angle. In addition, the formed black deposition layer is even, which can reduce a black chrominance difference between positions on the black deposition layer, and therefore can improve the contrast of the display screen manufactured using the display module and can avoid emitting light at a side viewing angle of the display screen to cause a color spot. In addition, at least one part of the black deposition layer on the light-emitting surface of each of the light-emitting units is removed, thereby ensuring the luminous efficiency of each light-emitting unit, and improving the display luminance of a display screen manufactured using the display module, to further ensure the display effect of the display screen manufactured using the display module; and the sputtering process has a low production control difficulty and a high finished product rate, and can reduce the production costs.

This embodiment further provides a display screen. The display screen includes at least one display module in the foregoing embodiments, and further includes a driving element, where the driving element is arranged on a back surface or a top surface of a substrate of the display module and electrically connected to each light-emitting unit. It should be understood that the driving element in this embodiment may drive the display module in an AM active driving manner or a PM passive driving manner. For ease of understanding, this embodiment is described below using an example in which an LED display screen uses the display module shown in FIG. 9-9. As shown in FIG. 9-12, a driving element 48 of the display screen is arranged on a back surface of a substrate 18 and electrically connected to each light-emitting unit 28 on a top surface of the substrate 18, to drive an LED chip in each light-emitting unit 28. In addition, in some application scenarios of this example, other electronic elements different from the light-emitting units 28 may be further flexibly arranged on the top surface and/or the back surface of the substrate 18. The arranged electronic elements may include, but not limited to, a resistor, a capacitor, and the like, and may be specifically selected and arranged according to an application requirement

### Embodiment 9

After an LED chip is soldered onto a substrate through a solder pad, a used tin solder paste becomes silver after being melted and covers a surface of the solder pad, and silver has a light reflection characteristic. As result, a display screen is insufficiently black when the screen is off, the contrast of the display screen is reduced, and the display effect is affected. For this problem, this embodiment further provides another packaging layer, display module, and manufacturing method therefor that can resolve this technical problem, and this embodiment may be implemented independently of other embodiments.

The second packaging layer provided in this embodiment is a composite layer including a plurality of sub layers, and the second packaging layer is a translucent layer (which may also be referred to as a unidirectional perspective layer), and may be used for a display module or an optical device to improve the display contrast and the display effect of the display module. As shown in FIG. 10-2 (a schematic structural diagram of a second packaging layer 310 on a light path principle, used to explain and understand the unidirectional perspective arrangement of the second packaging layer of the present invention, not a schematic diagram of an actual structure), the second packaging layer 310 includes a reflection layer 3101 and a black adhesive layer 3102 arranged onto the reflection layer 3101.

The reflection layer 3101 includes reflection particles 301 and gaps located between the reflection particles 301, and the gaps forms first light-transmitting channels 302 for light to pass through the reflection layer 3101. An exemplary schematic structural diagram of the reflection layer 3101 is shown in FIG. 10-3, and the reflection layer includes reflection particles 301 laid flat on a bearing surface of a bearing body (that is, an attachment surface of the reflection layer 3101), and gaps located between the reflection particles 301, and one gap forms one first light-transmitting channel 302. The reflection particles 301 in this embodiment may be in a molecule form or another particle form. The reflection particles 301 in this embodiment may be arranged on the bearing surface through, but not limited to, a mature vacuum ion plating or evaporation process, manufacturing is simple, costs are low, and controllability is good. The reflection particles 301 in this embodiment may include at least one of various metal optical particles (which may include, for example but not limited to, at least one of nanometer-sized aluminum alloy particles, silver nitrate particles, Ag particles, A1 particles, Rh particles, Cr particles, Pt particles, Cu particles, Au particles, and Ti particles, and preferably includes at least one of aluminum alloy particles and silver nitrate particles with low costs, a high reflection effect, and good commonality) and non-metal optical particles (which may include, for example but not limited to, at least one of nanometer-sized TiOz particles, ZnO particles, BaSO₄ particles, and AlzO₃ particles) with specific light reflection performance. The reflection particles 301 in this embodiment may be particles with a particle size at a nanometer level, and the thickness of the reflection layer 3101 depends on the particle size of the reflection particles 301. For example, in some application examples, the reflection particles 301 may be, but not limited to, particles with a particle size ranging from 2 nanometers to 300 nanometers, and the thickness of the corresponding formed reflection layer 3101 ranges from 2 nanometers to 300 nanometers. Setting the thickness of the reflection layer 3101 at the nanometer level can better help reduce the thickness of the display module while improving the contrast, thereby better facilitating ultra thinning design of the display module. In some application scenarios, the reflection particles 301 may be specifically particles with a particle size ranging from 100 nanometers to 300 nanometers, and the thickness of the corresponding formed reflection layer 3101 ranges from 100 nanometers to 300 nanometers. For example, the particle size of the specifically used reflection particles 301 is 100 nanometers, 150 nanometers, 200 nanometers, 250 nanometers, or 300 nanometers. It should be understood that correspondingly, in this embodiment, the width and the height of each first light-transmitting channel 302 (that is, gap) are also at the nanometer level.

In this embodiment, as shown in FIG. 10-2 and FIG. 10-3, the first light-transmitting channels 302 of the reflection layer 3101 are formed and distributed in a similar matrix. In addition, to ensure good luminous efficiency to satisfy a display requirement while improving the contrast, in this embodiment, the first light-transmitting channels 302 are particle gaps in the reflection layer 3101, and the area occupied by the first light-transmitting channels 302 in an orthographic projection of the reflection layer 3101 is set to range from 60% to 70% of the area of the orthographic projection of the reflection layer 3101. For example, in some examples, a proportion of the area may be specifically set to 60%, 65%, or 70%. Correspondingly, the area occupied by the reflection particles 301 in the reflection layer 3101 in the orthographic projection of the reflection layer 3101 ranges from 30% to 40% of the area of the orthographic projection of the reflection layer 3101. This arrangement manner can greatly reduce the proportion of the reflection particles 301 and reduce use of the reflection particles 301, thereby helping reduce costs.

The black adhesive layer 3102 includes a transparent adhesive base material layer (the transparent adhesive base material layer is a bearing base layer used for bearing micron-sized glass beads and nanometer-sized black powder, not shown in FIG. 10-2), micron-sized glass beads 303 distributed in the transparent adhesive base material layer, and nanometer-sized black powder filling between the micron-sized glass beads 303, the nanometer-sized black powder is deposited on the micron-sized glass beads 303 to form a black light-blocking unit 304, and each of the micron-sized glass beads 303 forms a second light-transmitting channel for light to pass through the black adhesive layer 3102. In this example, positions of at least a part of the second light-transmitting channels and positions of at least a part of the first light-transmitting channels 302 may be arranged correspondingly to each other, so that light may pass through the second packaging layer 310 through the first light-transmitting channels 302 and the second light-transmitting channels at the corresponding positions. An exemplary schematic structural diagram of the black adhesive layer 3102 is shown in FIG. 10-4, and includes a transparent adhesive base material layer 305, micron-sized glass beads 303 distributed in the transparent adhesive base material layer 305, and nanometer-sized black powder distributed in the transparent adhesive base material layer 305 and filling between the micron-sized glass beads 303, and the nanometer-sized black powder is deposited together in the transparent adhesive base material layer to form a black light-blocking unit 304. In this embodiment, to avoid a case that the nanometer-sized black powder is attached to the micron-sized glass beads 303 to affect light transmission performance of the micron-sized glass beads 303, when the black adhesive layer 3102 is manufactured, the micron-sized glass beads 303 may be subjected to a charging operation to have negative charges, and the nanometer-sized black powder is also set to have negative charges (shown by R in FIG. 10-4). Therefore, the micron-sized glass beads 303 and the nanometer-sized black powder mixed in the transparent adhesive base material layer 305 may be repulsive to each other, that is, the micron-sized glass beads 303 may repulse the nanometer-sized black powder with negative charges, thereby preventing the nanometer-sized black powder from being attached onto the micron-sized glass beads 303, and the second light-transmitting channels formed by the micron-sized glass beads 303 is widened on a top surface and/or bottom surface of the black adhesive layer 3102.

In this embodiment, to ensure that the black adhesive layer 3102 can improve the contrast and can also ensure the specific luminous efficiency, the volume occupied by the micron-sized glass beads 303 in the black adhesive layer 3102 may be set to range from 50% to 70% of the volume of the black adhesive layer, and the proportion of the volume may be specifically set to 50%, 55%, 60%, 65%, or 70%. In other words, it may also be understood that the area occupied by the micron-sized glass beads 303 in the orthographic projection of the black adhesive layer 3102 may be set to range from 50% to 70% of the area of the orthographic projection of the black adhesive layer.

In this embodiment, the thickness of the black adhesive layer 3102 may be set to range from 50 microns to 100 microns. Setting the thickness of the black adhesive layer 3102 at the micron level can better help reduce the thickness of the translucent layer while improving the contrast, thereby facilitating ultra thin design of the display module. In addition, to ensure that the micron-sized glass beads 303 can reliably form the second light-transmitting channels for light to pass through the black adhesive layer 3102, a ratio of the particle size of the micron-sized glass beads 303 to the thickness of the black adhesive layer 3102 may be set to range from 0.8 to 1.0, that is, the particle size of the micron-sized glass beads 303 may range, but not limited to, from 40 microns to 100 microns. For example, in some application scenarios, when a ratio of the particle size of the micron-sized glass beads 303 to the thickness of the black adhesive layer 3102 is set to 0.8, and the thickness of the black adhesive layer 3102 is 50 microns, the micron-sized glass beads 303 with the particle size of about 40 microns are used; when a ratio of the particle size of the micron-sized glass beads 303 to the thickness of the black adhesive layer 3102 is set to 0.9, and the thickness of the black adhesive layer 3102 is 100 microns, the micron-sized glass beads 303 with the particle size of about 90 microns are used; and when a ratio of the particle size of the micron-sized glass beads 303 to the thickness of the black adhesive layer 3102 is set to 1.0, and the thickness of the black adhesive layer 3102 is 100 microns, the micron-sized glass beads 303 with the particle size of about 100 microns are used. The glass beads may be made of a borosilicate raw material through a high technology, and have advantages such as light weight, low heat conduction, sound insulation, high dispersion, good electric insulation performance, good thermal stability, high strength, good chemical stability, and low costs. In addition, because the micron-sized glass beads 303 have low heat conduction performance and good thermal stability, heat generated by electronic elements on the top surface of the substrate during working and exported from the black adhesive layer 3102 can be further reduced, and stability of the black adhesive layer 3102 can be ensured.

It should be understood that the micron-sized glass beads 303 in this embodiment may be solid glass beads. However, in some application scenarios, the micron-sized glass beads 303 may be preferably micron-sized glass beads 303 in a hollow structure, and the micron-sized glass beads 303 in the hollow structure can further improve heat insulation performance of the black adhesive layer 3102, and can lighten the black adhesive layer 3102. When the micron-sized glass beads 303 in the hollow structure are used, the wall thickness of the micron-sized glass beads 303 may range, but not limited to, from 1 micron to 2 microns. The nanometer-sized black powder in this embodiment may include, but not limited to, nanometer-sized carbon black powder, and may be, but not limited to, nanometer-sized carbon black powder with the particle size ranging from 1 nanometer to 100 nanometers, so that a blackness of the black adhesive layer 3102 can be ensured. The transparent adhesive base material layer 305 in this embodiment may be, but not limited to, a transparent adhesive, and the transparent adhesive may be, but not limited to, polyester, polyvinyl chloride, modified epoxy, modified silica gel, or the like, and has advantages such as low costs and good commonality.

In this embodiment, a surface of the black adhesive layer 3102 far away from the reflection layer 3101 (that is, the top surface of the black adhesive layer 3102) may alternatively be treated according to a visual effect requirement. For example, in some application scenarios, when the black adhesive layer 3102 needs to be presented with a black mirror effect, the top surface of the black adhesive layer 3102 may be set as a smooth surface; and when the black adhesive layer 3102 needs to be prevented from being presented with a black mirror effect, the top surface of the black adhesive layer 3102 may be set as a non-smooth surface. The non-smooth surface may include, but not limited to, a fogged surface, a frosted surface, a matte surface, or a rough surface with different degrees of texture. Setting the top surface of the black adhesive layer 3102 as a non-smooth surface can cause light in an external environment to undergo diffuse reflection on the top surface of the black adhesive layer 3102, can reduce sharpness of an LED and reduce interference from ambient light, can reduce the mirror effect on the surface of the display module, thereby eliminating interference from external ambient light when the display module is illuminated, and achieving a better viewing effect while ensuring a high black contrast, and can be better applied to various application scenarios.

Based on the translucent layer 310 with the foregoing specific structure in this embodiment, when no light is emergent from the reflection layer 3101 to the black adhesive layer 3102, and only light is incident from the black adhesive layer 3102 to the reflection layer 3101, among the incident light, some light I1 is reflected by the reflection particles in the reflection layer 3101 and is emergent through the second light-transmitting channel, some light I3 is reflected by the reflection particles to the nanometer-sized black powder in the black adhesive layer 3102 and is absorbed, and some light I2 is incident through the first light-transmitting channels of the reflection layer 3101 to an object (for example, the substrate or the light-emitting unit) under the reflection layer 3101 and reflected and/or absorbed through the object under the reflection layer 3101 for a plurality of times, and then returns to the second light-transmitting channel to be emergent or returns to the nanometer-sized black powder in the black adhesive layer 3102 and is absorbed. The strength of the light I2 is far less than the strength of the light I1. In this case, a region covered by the translucent layer is presented in black in human vision, and therefore the contrast can be improved; otherwise, when light with sufficient strength is emergent from the reflection layer 3101 to the black adhesive layer 3102, normal display can be implemented. To be specific, the contrast is improved while ensuring the display effect using the unidirectional perspective visual effect of the translucent layer.

For ease of understanding, description is made below using a specific application example in which a translucent layer is applied to a display module. The display module includes: a substrate, where a plurality of solder pads electrically connected to electrodes of light-emitting units are arranged on a top surface of the substrate; and the plurality of light-emitting units arranged on the top surface of the substrate, where an electrode of each light-emitting unit is electrically connected to a corresponding solder pad.

It should be understood that in this embodiment, a distribution manner of the solder pads on the top surface of the substrate may be flexibly set. For example, the distribution manner may be matrix distribution, and may alternatively be set to another distribution manner according to a requirement, which is not limited in this embodiment. In this embodiment, for at least one of the substrate, the solder pad, and the light-emitting unit, reference may be made to, but not limited to, the foregoing embodiments. In some application scenarios of this embodiment, a plurality of light-emitting units arranged on the substrate may form a plurality of pixel units.

The display module in this embodiment further includes a second packaging layer arranged on the top surface of the substrate, and the second packaging layer is a translucent layer in the foregoing examples, and covers at least a region that is on the top surface of the substrate and not covered by an orthographic projection of each light-emitting unit. It should be noted that in this embodiment, a case that the second packaging layer is arranged on the top surface of the substrate may be a case that the second packaging layer is directly attached onto the top surface of the substrate; or may be a case that the second packaging layer is indirectly arranged above the top surface of the substrate (that is, another layer structure is further arranged between the second packaging layer and the top surface of the substrate). In this embodiment, a case that the second packaging layer covers at least the region that is on the top surface of the substrate and not covered by the orthographic projection of each light-emitting unit refers to a case that on the top surface of the substrate, other regions on the top surface different from the region covered by the orthographic projection of each light-emitting unit on the top surface are all covered by the second packaging layer. For example, in an example, refer to FIG. 10-1. FIG. 10-1 shows a substrate 19 of a display module, and a plurality of light-emitting units 29 arranged on a top surface of the substrate, and regions that are on the top surface of the substrate 19 and are not covered by orthographic projections of the light-emitting units 29 include regions shown by S0 in FIG. 10-1. Therefore, the contrast and the display effect of the display module can be improved.

The foregoing second packaging layer used in this embodiment has a visually unidirectional perspective effect, that is, in a scenario in which the strength of external ambient light of the display module is greater than or equal to 1.5 times the strength of internal ambient light of the display module, a region in the display module covered by the second packaging layer is presented in black in human vision, and therefore the contrast can be improved; otherwise, when the luminance of internal light of the display module is greater than 1.5 times the luminance of external light of the display module, the display module can implement normal display. For example, as shown in FIG. 10-5, when the light-emitting units do not emit light, that is, the display module is off, no light is generated in the internal environment, and light that human eyes can view mainly includes the following three parts theoretically: light I1 that is in external ambient light and is reflected by the reflection particles in the reflection layer 3101; light I2 in the internal environment reflected and absorbed for a plurality of times and then returning to the external environment after a small part of external ambient light enters the internal environment through the first light-transmitting channels and the second light-transmitting channels corresponding to each other; and external ambient light absorbed by the black light-blocking unit 304 in the black adhesive layer, where the light is absorbed and therefore is visually black I3. According to a unidirectional perspective principle, when the luminance of the external ambient light is greater than 1.5 times the luminance of the internal environment, human vision ignores the received internal ambient light, and in FIG. 10-5, the strength of the light I2 is far less than the strength of the light I1. In this case, a region covered by the second packaging layer 310 is presented in black in human vision.

as shown in FIG. 10-6, when the light-emitting units emit light, that is, the display module is on, the light-emitting units in the internal environment generate light, and light that human eyes can view mainly includes the following five parts theoretically: light I1 that is in external ambient light and is reflected by the reflection particles in the reflection layer 3101; light I2 in the internal environment reflected and absorbed for a plurality of times and then returning to the external environment after a small part of external ambient light enters the internal environment through the first light-transmitting channels and the second light-transmitting channels corresponding to each other; and external ambient light absorbed by the black light-blocking unit 304 in the black adhesive layer, where the light is absorbed and therefore is visually black I3; light I4 generated by the light-emitting units and directly incident to the external environment from the first light-transmitting channels and the second light-transmitting channels corresponding to each other; and light I5 generated by the LED, and reflected and absorbed in the internal environment for a plurality of times and then incident to the external environment from the first light-transmitting channels and the second light-transmitting channels corresponding to each other. Generally, luminance of the display screen reaching a range from 300 nit to 500 nit can achieve a very good display effect, and luminance of light emitted by the LED, that is, I4+I5 can reach a range from 800 nit to 2000 nit, greater than the range from 300 to 500 nit. In this case, human vision can completely view content displayed on the LED display screen.

As described above, in this embodiment, the second packaging layer 310 may be indirectly arranged on the top surface of the substrate 19 or directly attached to the top surface of the substrate 19. For ease of understanding, this embodiment is described below with reference to several exemplary structures shown in accompanying drawings.

In an example in which the second packaging layer is indirectly arranged on the top surface of the substrate, the display module may further include an eleventh packaging layer arranged between the top surface of the substrate and a translucent layer. The eleventh packaging layer in this embodiment is a light-transmitting layer. It should be understood that the forming process and the material of the eleventh packaging layer in this embodiment may be flexibly set, which is not limited. For example, in some examples, the eleventh packaging layer may be, but not limited to, an adhesive layer, and may be formed in a manner of, but not limited to, coating, mold-pressing, printing, or mounting after being manufactured into a film in advance. The eleventh packaging layer in this embodiment can play a role in resisting water, resisting moisture, and resisting collision, can protect the light-emitting units, and can be used as a substrate on which the translucent layer is arranged. For example, in some application examples, the eleventh packaging layer may be a transparent packaging adhesive layer made of transparent epoxy glue, thereby sealing and protecting the light-emitting units on the substrate. In some application scenarios, at least one of white powder (for example, including, but not limited to, SiO2 powder), a melanin, and light diffusion particles may be added to the transparent epoxy glue according to a requirement, thereby further adjusting the light-emitting effect of the display module. In addition, in this embodiment, an upper surface of the eleventh packaging layer (that is, a surface of the eleventh packaging layer far away from the top surface of the substrate) may be set as a matte surface, a shiny surface, a frosted surface, a fogged surface, or the like according to a requirement, thereby achieving different appearance effects and light-emitting effects, and further enriching display effects and improving user experience satisfaction.

An exemplary structure in which the second packaging layer is indirectly arranged on the top surface of the substrate is shown in FIG. 10-7, and includes a substrate 19, a plurality of light-emitting units 29 arranged on a top surface of the substrate 19, and an eleventh packaging layer 311 arranged on the top surface of the substrate 19 and covering each light-emitting unit 29. In this embodiment, the light-emitting unit 29 has a surface far away from the top surface of the substrate as a light-emitting surface, a surface close to the top surface of the substrate as a bottom surface, and surfaces located between the light-emitting surface and the bottom surface as side surfaces. The display module further includes a second packaging layer 310 formed on the eleventh packaging layer 311. In this example, the second packaging layer 310 covers regions that are on the top surface of the substrate 19 and are not covered by orthographic projections of the light-emitting unit 29, and also covers the light-emitting surfaces of the light-emitting units 29, that is, in this example, the second packaging layer 310 completely covers the eleventh packaging layer. When the light-emitting units 29 of the display module in this example do not emit light, that is, are off, a schematic model of light paths is shown in FIG. 10-8, and when emitting light, a schematic model of light paths is shown in FIG. 10-9. For ease of understanding, this embodiment is exemplified below with reference to some concepts in the existing display field in such a scenario in which a display module is applied to a display screen.

Existing liquid crystal display screen: this term refers to an existing liquid crystal display screen commonly used, whose typical luminance is 350 nit, and is generally at most 500 nit. The existing liquid crystal display screen has low luminance. However, because a light filter is arranged in the structure, and the light filter has a black matrix, the liquid crystal display screen can display high black when being off, and the contrast of the existing liquid crystal display screen is actually the best among all current types of display screens. To be specific, although the luminance is low, an ultra high black contrast can still be reached as long as a ratio of off-screen black luminance to on-screen highest luminance is sufficiently large. For an ordinary COB display screen, solder pads are exposed, natural light reflected by a silver tin paste on surfaces of the solder pads is viewed by human eyes when the screen is off, and a mirror surface cannot be formed since the surface of the tin paste is uneven. Therefore, silver is viewed by the human eyes. It may be learned according to the foregoing analysis that the second packaging layer 310 arranged in this embodiment blocks all silver, and when the screen is off, because of the unidirectional perspective principle, human eyes can view only the second packaging layer 310 to block the silver solder pads, and the second packaging layer 310 is highly black, thereby improving the black contrast.

Descriptions about light received by human eyes in FIG. 10-5 and FIG. 10-8: When the light-emitting units do not emit light (that is, the screen is off), human eyes receive light I1+I2. I3 is light absorbed by black, and is presented in black in human vision, and therefore is represented with a dashed line. If external natural light is represented as I-out, I1, I2, and I3 are three parts into which the external natural light is divided, where a part is directly reflected by the reflection layer and received by the human eyes, that is, I1, a part enters an internal environment, returns to an external environment after being reflected and absorbed for a plurality of times, and then is received by the human eyes, that is, I2, and a part is directly absorbed by black, that is, I3, so that I-out>1.5*(I1+I2+I3). Therefore, a region covered by the second packaging layer 310 is presented in black in human vision. The second packaging layer 310 may be visually used as a black mirror when the top surface of the black adhesive layer 3102 is a smooth surface.

Descriptions about light received by human eyes in FIG. 10-6 and FIG. 10-9: when the light-emitting units emit light, light emitted by the LED is divided into two parts to be received by the human eyes, that is, I4+I5; and it may be learned with reference to the foregoing proportion of the first light-transmitting channels and the second light-transmitting channels that, a minimum value of I4+I5 may be greater than 50% of luminance of the light emitted by the LED. If the luminance of the light emitted by the LED is represented as I-in, I-in>I4+I5>50% of I-in, and 50% of I-in may range from 400 nit to 1000 nit. Therefore, I4+I5>300 nit. In this case, the user can obtain a complete display effect.

Descriptions about a case that the second packaging layer 310 may be visually used as a black mirror when the top surface of the black adhesive layer 3102 is a smooth surface: first, a principle of a mirror is shown in FIG. 10-10: light emitted by a candle B1 is reflected by a smooth reflection layer in a mirror C, human eyes receive the reflected light, and a scene presented in the human brain is a candle B2, to cause an illusion that the candle is in the mirror, that is, a specular reflection principle.

As shown in FIG. 10-5 and FIG. 10-9, the micron-sized glass beads in the black adhesive layer 3102 are glass crystals, and the reflection layer 3101 includes reflection particles. When the light-emitting units do not emit light, the micron-sized glass beads and the reflection particles form a mirror. However, in addition, because of the presence of the black light-blocking units 304 in the black adhesive layer 3102, it may be imagined that one black matrix formed by the black light-blocking units 304 is added to a mirror. Because the micron-sized glass beads are micron-sized crystals, a black mirror is presented in human vision.

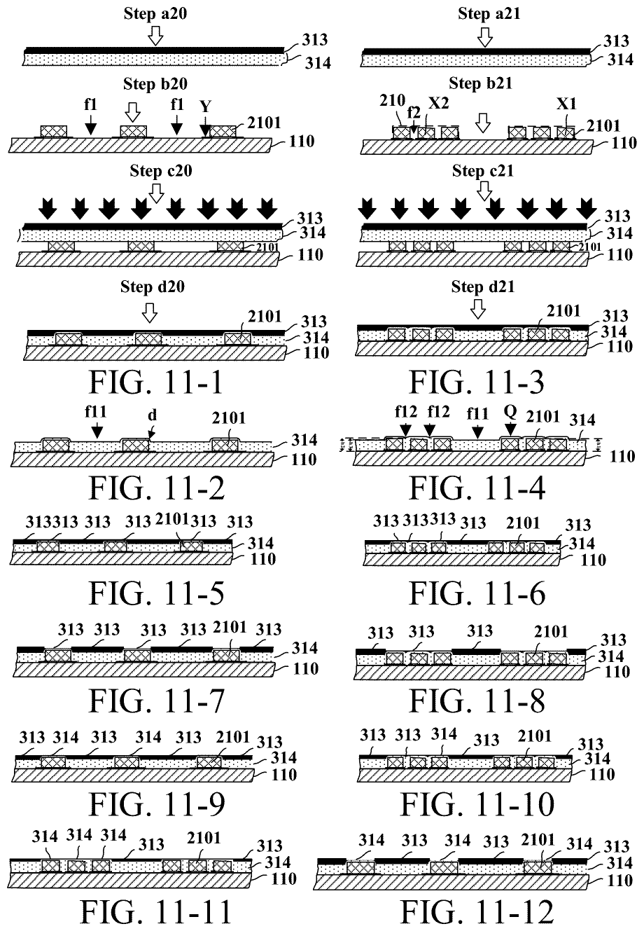

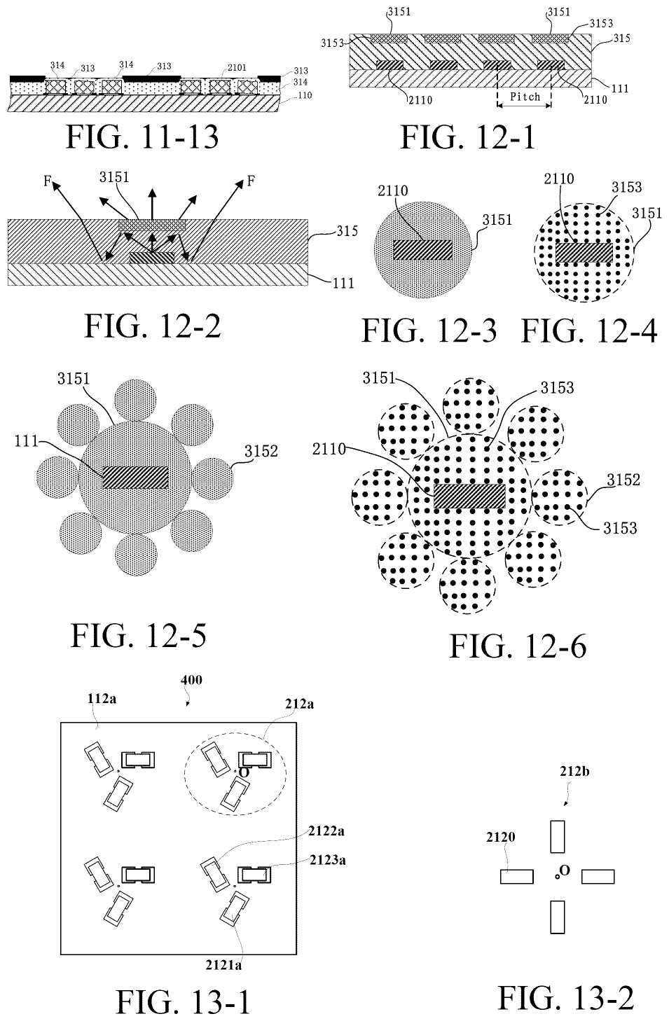

Descriptions about a case that a top surface of the black adhesive layer 3102 is set as a non-smooth surface to form diffuse reflection on the top surface in this embodiment: as shown in FIG. 10-11, when a top surface of the black adhesive layer 3102 is a smooth surface, specular reflection shown in FIG. 10-11 is formed on the top surface. When a top surface of the black adhesive layer 3102 is a non-smooth surface such as a rough surface shown in FIG. 10-12, diffuse reflection shown in FIG. 10-12 is formed on the top surface. In this case, what is viewed by the human eyes is not a complete mirror image (which may be understood as a fogged surface screen). Because diffuse reflection disables the mirror image from being formed, interference from ambient light can be reduced, to improve the display effect.

Another exemplary structure in which the second packaging layer 310 is indirectly arranged on the top surface of the substrate 19 is shown in FIG. 10-13, and compared with the display module shown in FIG. 10-7, has a main difference that the thickness of the eleventh packaging layer 311 is substantially equal to the height of each light-emitting unit 29, a light-emitting surface of each light-emitting unit 29 (that is, a surface of the light-emitting unit 29 far away from the substrate 19) is exposed from the eleventh packaging layer 311, and the second packaging layer 310 located on the light-emitting surface of each light-emitting unit 29 is directly attached onto the light-emitting surface of each light-emitting unit 29; and the second packaging layer 310 completely covers the top surface of the eleventh packaging layer 311. Still another exemplary structure in which the second packaging layer 310 is indirectly arranged on the top surface of the substrate 19 is shown in FIG. 10-14, and compared with the display module shown in FIG. 10-7, has a main difference that the eleventh packaging layer 311 is thinner, and has a top surface that is uneven with layout and distribution of light-emitting units 29.

Still another exemplary structure in which the second packaging layer 310 is indirectly arranged on the top surface of the substrate 19 is shown in FIG. 10-15, and compared with the display module shown in FIG. 10-7, has a main difference that the second packaging layer 310 covers regions that are on the top surface of the substrate 19 and are not covered by orthographic projections of the light-emitting unit 29, and light-emitting surfaces of the light-emitting units 29 are all exposed from the second packaging layer 310, that is, the second packaging layer 310 does not cover the light-emitting surfaces of the light-emitting units 29. In this example, the second packaging layer 310 does not cover the light-emitting surfaces of the light-emitting units 29. Therefore, most of light emitted from the light-emitting surfaces of the light-emitting units 29 may be directly emitted through the eleventh packaging layer 311, and does not need to pass through the second packaging layer 310, thereby improving the display luminance. An exemplary structure in which the second packaging layer 310 is directly attached onto the top surface of the substrate 19 is shown in FIG. 10-16, and includes a substrate 19, a plurality of light-emitting units 29 arranged on a top surface of the substrate 19, and a second packaging layer 310 attached to the top surface of the substrate 19. The second packaging layer 310 covers regions that are on the top surface of the substrate 19 and are not covered by orthographic projections of the light-emitting unit 29, and light-emitting surfaces and side surfaces of the light-emitting unit 29 are exposed from the second packaging layer 310. Therefore, most of light emitted from the light-emitting surfaces and the side surfaces of the light-emitting units 29 may be emitted without passing through the second packaging layer 310, to improve its luminous efficiency and ensure the display luminance. The display module in this example further includes a twelfth packaging layer 312 arranged on the second packaging layer 310 and covering each light-emitting unit 29. The material, the shape, and the forming manner of the twelfth packaging layer 312 in this example may be the same as, but not limited to, those of the eleventh packaging layer 311 in the foregoing examples. Details are not described herein again. Another exemplary structure in which the second packaging layer 310 is directly attached onto the top surface of the substrate 19 is shown in FIG. 10-17, and compared with the display module shown in FIG. 10-16, has a main difference that the second packaging layer 310 further covers a side surface of each light-emitting unit 29, and a light-emitting surface of each light-emitting unit 29 is exposed from the second packaging layer 310. Therefore, most of light emitted from the light-emitting surfaces of the light-emitting units 29 may be emitted without passing through the second packaging layer 310, to improve its luminous efficiency and ensure the display luminance. Still another exemplary structure in which the second packaging layer 310 is directly attached onto the top surface of the substrate 19 is shown in FIG. 10-18, and compared with the display module shown in FIG. 10-16, has a main difference that the second packaging layer 310 further covers a light-emitting surface of each light-emitting unit 29, and a side surface of each light-emitting unit 29 is exposed from the second packaging layer 310. Therefore, most of light emitted from the side surfaces of the light-emitting units 29 may be emitted without passing through the second packaging layer 310, which can also improve its luminous efficiency and ensure the display luminance. Still another exemplary structure in which the second packaging layer 310 is directly attached onto the top surface of the substrate 19 is shown in FIG. 10-19, and compared with the display module shown in FIG. 10-16, has a main difference that the second packaging layer 310 further covers all of the side surfaces and the light-emitting surfaces of the light-emitting units 29. Therefore, in this example, compared with the foregoing several examples, the coverage of the second packaging layer 310 is larger and the black contrast is higher.

Certainly, it should be understood that the foregoing structures shown in FIG. 10-7, and FIG. 10-13 to FIG. 10-19 are only several exemplary structures for ease of understanding, and other equivalent variations may be further performed on this basis. For example, a transformation example is shown in FIG. 10-20. Based on FIG. 10-17, one more second packaging layer 310 is further arranged on the twelfth packaging layer 312, that is, the example shown in FIG. 10-20 includes a double-layer second packaging layer 310, to further improve the contrast. Certainly, to ensure the luminous efficiency, when the double-layer second packaging layer 310 is arranged, the light transmittance and the black chrominance of each second packaging layer 310 may be adaptively adjusted. Details are not described herein again.

For ease of understanding, a manufacturing method for a translucent layer shown in the foregoing examples is exemplified below in this embodiment, and includes, but not limited to:

Step a11: form a reflection layer on a bearing surface of a bearing body through a vacuum ion plating or evaporation process. For ease of understanding, a type of vacuum ion plating is exemplified below. In an example, in a vacuum magnetically conducting environment, a magnetic field is used to guide ions to bombard a preset reflection base material, and molecules of the reflection base material are evenly sputtered onto a corresponding region on the bearing surface to form a reflection layer. It should be understood that the bearing body in this embodiment may be a substrate, and the bearing surface may be a top surface of the substrate; when an eleventh packaging layer is arranged on the substrate, the bearing body may be the eleventh packaging layer, and the bearing surface may be a surface of the eleventh packaging layer far away from the substrate; and certainly, the bearing body may alternatively be a connection adhesive layer arranged on a second bearing film, and the bearing surface may be a surface of the connection adhesive layer far away from the second bearing film. It can be learned that the bearing body in this embodiment and the corresponding bearing surface may be flexibly set according to a specific application scenario, the manufacturing is flexible, applicable scenarios are wide, and commonality is good.

Step b11: evenly mix micron-sized glass beads and nanometer-sized black powder in a transparent adhesive to obtain a mixed adhesive. In this step, before the micron-sized glass beads and the nanometer-sized black powder are evenly mixed in the transparent adhesive, the micron-sized glass beads are first subjected to a charging operation. For example, by rotating the micron-sized glass beads off from a specific object to cause friction, the micron-sized glass beads may have negative charges. Correspondingly, the nanometer-sized black powder also carries negative charges, and the nanometer-sized black powder is, for example, carbon black powder. Then, the micron-sized glass beads and the nanometer-sized black powder with negative charges are evenly mixed in the transparent adhesive, and the micron-sized glass beads and the nanometer-sized black powder with negative charges repel each other in the transparent adhesive, thereby preventing the nanometer-sized black powder from being attached onto the micron-sized glass beads.

Step e11: arrange a mixed adhesive layer on the reflection layer, and cure the mixed adhesive layer to obtain the black adhesive layer.

It should be understood that in this embodiment, a manner of arranging the mixed adhesive layer on the reflection layer may be, but not limited to, coating, mold-pressing, or printing. Certainly, in some examples, the mixed adhesive layer may be arranged on the second bearing film to manufacture a black film, and then the black film is mounted onto the reflection layer. In addition, it should be understood that the adhesive in the mixed adhesive layer has specific viscosity and tension, and therefore does not flow into seams between reflection particles in the reflection layer or only a part of the transparent adhesive flows into the seams, but does not prevent the seams from forming the first light-transmitting channels.

For ease of understanding, a manufacturing method for a display module shown in the foregoing examples is exemplified below in this embodiment, and includes, but not limited to:

Step a12: arrange a plurality of light-emitting units on a top surface of a substrate, where electrodes of each light-emitting unit are electrically connected to corresponding solder pads. As described in the foregoing examples, electrical connection may be performed through, but not limited to, a tin paste or a conducting silver adhesive.

Step b12: arrange a translucent layer on the top surface of the substrate. The arranged translucent layer covers at least a region that is on the top surface of the substrate and is not covered by an orthographic projection of each light-emitting unit.

For ease of understanding, several specific manufacturing processes for a display module are exemplified below in this embodiment.

As shown in FIG. 10-21, a manufacturing process in this example includes, but not limited to:

Step a13: arrange a plurality of light-emitting units 29 on a top surface of a substrate 19.

Step b13: Form an eleventh packaging layer 311 on the top surface of the substrate 19. The eleventh packaging layer 311 in this example is a transparent adhesive layer.

Step c13: form a reflection layer 3101 on a surface of the eleventh packaging layer 311 far away from the substrate 19 through vacuum ion plating or evaporation. The thickness of the reflection layer 3101 is 200 nanometers. To be specific, in this example, the eleventh packaging layer 311 is a bearing body, and has a surface far away from the substrate 19 as a bearing surface.

Step d13: print, mold-press, or coat a mixed adhesive layer on the reflection layer 3101 and cure the mixed adhesive layer to obtain a black adhesive layer 3102. The thickness of the black adhesive layer 3102 in this example is 100 microns.

As shown in FIG. 10-22, a manufacturing process in this example includes, but not limited to:

Step a14: arrange a plurality of light-emitting units 29 on a top surface of a substrate 19.

Step b14: form a reflection layer 3101 on the top surface of the substrate 19 through vacuum ion plating or evaporation. The reflection layer 3101 has a thickness of 200 nanometers, and covers side surfaces and a top surface of each light-emitting unit 29. To be specific, in this example, the substrate 19 is a bearing body, and the top surface of the substrate 19 is a bearing surface.

Step c14: print, mold-press, or coat a mixed adhesive layer on the reflection layer 3101 and cure the mixed adhesive layer to obtain a black adhesive layer 3102.

Step d14: form a twelfth packaging layer 312 on the black adhesive layer 3102 through printing, mold-pressing, or coating. The twelfth packaging layer 312 in this example is mixed with light conversion particles and/or light diffusion particles.

As shown in FIG. 10-23, the manufacturing process in this example further includes removing at least one part of the translucent layer on a light-emitting surface of each of the light-emitting units 29. The removing manner may be, but not limited to, laser removing, grinding, or plasma etching. Then, the following is performed: forming a twelfth packaging layer 312 on the black adhesive layer 3102 through printing, mold-pressing, or coating, and covering each light-emitting unit 29 with the twelfth packaging layer 312, which includes, but not limited to:

Step a15: arrange a connection adhesive layer on a second bearing film. The connection adhesive layer in this embodiment may be various adhesive layers having viscosity and converted from a cured state into a semi-melted state when being heated. For example, the connection adhesive layer may be, but not limited to, a thermo-sensitive adhesive layer, a modified epoxy adhesive layer, or a modified silica gel layer, and may be specifically flexibly selected according to an application scenario.

Step b15: form a reflection layer on the connection adhesive layer through a vacuum ion plating or evaporation process. To be specific, in this example, the connection adhesive layer is a bearing body, and a surface of the connection adhesive layer far away from the second bearing film is a bearing surface.

Step c15: evenly mix micron-sized glass beads and nanometer-sized black powder in a transparent adhesive to obtain a mixed adhesive.

Step d15: arrange a mixed adhesive layer on the reflection layer, and cure the mixed adhesive layer to obtain the black adhesive layer.

Step e15: remove the second bearing film, cover the top surface of the substrate with a surface of the connection adhesive layer, and perform hot-pressing.

For ease of understanding, several specific manufacturing processes for a display module are exemplified below in this embodiment.

As shown in FIG. 10-24, a manufacturing process in this example includes, but not limited to:

Step a16: arrange a plurality of light-emitting units 29 on a top surface of a substrate 19.

Step b16: form an eleventh packaging layer 311 on the top surface of the substrate 19. The eleventh packaging layer in this example is a transparent adhesive layer.

Step c16: arrange a connection adhesive layer 307 on a second bearing film 306. The connection adhesive layer in this example may be, but not limited to, a thermo-sensitive adhesive layer, a modified epoxy adhesive layer, or a modified silica gel layer.

Step d16: form a reflection layer 3101 on the connection adhesive layer 307 through a vacuum ion plating or evaporation process. The thickness of the reflection layer 3101 is 200 nanometers.

Step e16: print, mold-press, or coat a mixed adhesive layer on the reflection layer 3101 and cure the mixed adhesive layer to obtain a black adhesive layer 3102. The thickness of the black adhesive layer 3102 in this example is 100 microns.

Step f16: remove the second bearing film 306.

Step g16: cover the eleventh packaging adhesive layer 311 with a surface of the connection adhesive layer 307.

Step h16: laminate the connection adhesive layer 307 with the eleventh packaging adhesive layer 311 through, but not limited to, hot-pressing.

As shown in FIG. 10-25, a manufacturing process in this example includes, but not limited to:

Step a17: arrange a plurality of light-emitting units 29 on a top surface of a substrate 19.

Step b17 and step c17 are the same as step b16 and step c16 in the foregoing examples. The connection adhesive layer 307 in this example may be specifically a modified epoxy adhesive layer, or a modified silica gel layer.

Step d17: Remove the second bearing film 306, and then cover the eleventh packaging adhesive layer 311 with a surface of the connection adhesive layer 307 to perform press-fitting. Certainly, a black adhesive layer may be further arranged on the black adhesive layer 3102 according to a requirement.

As shown in FIG. 10-26, step a18 to step d18 in the manufacturing process in this example are similar to step a17 to step d17 in the foregoing examples, and have a difference that the connection adhesive layer 307 is thicker. In this way, after the second bearing film 306 is removed in step e18, a surface of the connection adhesive layer 307 covers a light-emitting surface of each light-emitting unit 29, and then is heated and press-fit in step f18 to be laminated with the top surface of the substrate 19, and the press-fit connection adhesive layer 307 is also used as the first packaging adhesive layer. In some application scenarios, the connection adhesive layer 307 in this example has an initial thickness that is set to be greater than or equal to 100 μm before press-fitting, and a thickness greater than or equal to 50 μm after press-fitting.

In some other examples of this embodiment, positions of the reflection layer 3101 and the black adhesive layer 3102 on the second bearing film 306 may be interchanged. For example, the black adhesive layer 3102 may be directly formed on the second bearing film 306 first, and then the reflection layer 3101 is formed on the black adhesive layer 3102. During lamination, a surface of the reflection layer 3101 is directly laminated with the top surface of the substrate 19 or the packaging layer on the top surface of the substrate 19, thereby obtaining a structure in the foregoing examples. Certainly, in some application scenarios, a bonding layer (the bonding layer is a light-transmitting layer, for example, a transparent adhesive layer) may be arranged between the reflection layer 3101 and the top surface of the substrate 19 or the packaging layer on the top surface of the substrate 19, to improve the bonding strength between the reflection layer 3101 and the top surface of the substrate 19 or the packaging layer on the top surface of the substrate 19. Such a variation manner also falls within the protection scope of the present invention.

It can be learned that the manufacturing method for a display module provided in this embodiment is simple and efficient, and the efficiency is high. This embodiment further provides a display screen. The display screen includes at least one display module in the foregoing embodiments. For ease of understanding, this embodiment is described below using an example in which a display screen uses the display module shown in FIG. 10-27. A driving element 49 of the display screen is arranged on a back surface of a substrate 19 and electrically connected to each light-emitting unit 29 on a top surface of the substrate, to drive each light-emitting unit 29. In addition, in some application scenarios of this example, other electronic elements different from the light-emitting units 29 may be further flexibly arranged on the top surface and/or the back surface of the substrate 19. The arranged electronic elements may include, but not limited to, a resistor, a capacitor, and the like, and may be specifically selected and arranged according to an application requirement

### Embodiment 10

This embodiment provides a display module and a manufacturing method for a display module that can resolve a problem of reducing contrast of a display screen because a surface of a solder pad is covered by a silver tin paste and can also prevent a black adhesive from remaining on a light-emitting surface of an LED chip. In addition, this embodiment may be individually implemented independently of other embodiments.

The manufacturing method for a display module provided in this embodiment includes, but not limited to:

Step a19: manufacture a substrate and a packaging layer.

The manufacturing a substrate in this embodiment includes, but not limited to: providing a substrate, and fixing a plurality of light-emitting units on a top surface of the substrate, where a gap is provided between adjacent light-emitting units. In this embodiment, one light-emitting unit includes a plurality of LED chips, and an electrode of each LED chip is soldered to corresponding solder pads on the substrate; and a silver outer surface formed after LED chips of each light-emitting unit are soldered to solder pads is mainly distributed in the gap f1. It should be understood that in this embodiment, other electronic elements may be first arranged on the top surface and/or the back surface of the substrate, and then the packaging layer is arranged on the substrate; or after the light-emitting units and the packaging layer are arranged on the top surface of the substrate, electronic elements are arranged on the back surface of the substrate.

In this embodiment, the manufacturing a packaging layer includes: providing a black adhesive layer and a first packaging layer superposed together. In this example, when the packaging layer is manufactured, the black adhesive layer may be first formed, and then the first packaging layer is formed on the black adhesive layer; or the first packaging layer may be first formed, and then the black adhesive layer is formed on the first packaging layer. Regardless of a manner which is used, when press-fitting is performed using a hot-pressing process, the black adhesive layer is oriented to the top surface of the substrate (that is, a surface of the black adhesive layer far away from the first packaging layer is oriented to the top surface of the substrate), and the black adhesive layer and the first packaging layer are press-fit together onto the top surface of the substrate. In this embodiment, processes used for forming the black adhesive layer and the first packaging layer are not limited, and the process used for forming the black adhesive layer process may be the same as or different from the process used for forming the first packaging layer. The specific used processes may be, but not limited to, coating, silk-screen printing, printing, or mold-pressing. In this embodiment, the substrate and the packaging layer may be manufactured synchronously, or the substrate is first manufactured and then the packaging layer is manufactured. Alternatively, the substrate and/or the packaging layer are/is directly purchased from an upstream.

The black adhesive layer and the first packaging layer formed in this embodiment may be in and be maintained in a semi-cured state, and therefore are subsequently directly press-fit to the top surface of the substrate easily. In addition, this embodiment is not limited to a hot-pressing process using an adhesive. For example, when being in and maintained in a specific semi-cured state, the black adhesive layer and the first packaging layer that are formed may be directly press-fit and do not need to be heated. This manner is an equivalent alternative manner of the hot-pressing process in this embodiment.

Step b19: press-fit the black adhesive layer and the first packaging layer together on the top surface of the substrate through a hot-pressing process.

In this embodiment, after the black adhesive layer and the first packaging layer are press-fit together on the top surface of the substrate through the hot-pressing process, the black adhesive layer covers the top surface of the substrate and a light-emitting surface of each of the LED chips, and forms a concave portion in the gap between the adjacent light-emitting units, and a part of the first packaging layer fills in the concave portion to cover at least the concave portion (that is, completely cover at least the concave portion). In this embodiment, the light-emitting surfaces of the LED chips are surfaces of the LED chips far away from the top surface of the substrate.

For example, the black adhesive layer is oriented to the top surface of the substrate, and is laminated with the light-emitting surfaces of the LED chips on the top surface of the substrate and then hot-pressed. During press-fitting, the black adhesive layer and the first packaging layer are in a semi-cured state, and the transparent adhesive layer and the first packaging layer are pressed and gradually approach the top surface of the substrate, until the black adhesive layer is laminated with the top surface of the substrate. The LED chips located on the top surface of the substrate are covered by the black adhesive layer, the light-emitting surfaces of the LED chips are also covered by the black adhesive layer, and the black adhesive layer forms the concave portion in the gap between the adjacent light-emitting units. After the first packaging layer on the black adhesive layer is press-fit, at least each concave portion is filled, thereby covering the silver outer surface on the solder pad. Therefore, the contrast of the display module can be improved, to improve the display effect. In addition, because the black adhesive layer covers the light-emitting surfaces of the LED chips, and the first packaging layer does not contact the light-emitting surfaces of the LED chips during press-fitting, that is, is impossible to directly remain on the light-emitting surfaces of the LED chips, light-emitting characteristics of the LED chips can be ensured. In addition, during the foregoing press-fitting, the black adhesive layer is located between the first packaging layer and the substrate to serve as a buffer layer. Even if one or more LED chips are inclined on the top surface of the substrate during the foregoing fixation, the black adhesive layer can still form one flat surface as much as possible in regions right above the LED chips, thereby improving consistency of the press-fit first packaging layer between the regions on the black adhesive layer, to further improve consistency between light-emitting effects. In addition, the black adhesive layer and the first packaging layer are press-fit together onto the top surface of the substrate, and the black adhesive layer and the first packaging layer do not need to be separately press-fit at two times, which can improve the manufacturing efficiency. In addition, the used hot-pressing process is simple and mature, which can further ensure and improve the yield, and facilitate control of the manufacturing costs.

For ease of understanding, a specific example of a manufacturing method for a display module is described below. As shown in FIG. 11-1, the manufacturing method for a display module in this example includes, but not limited to:

Step a20: manufacture a packaging layer, including forming a black adhesive layer 313, which is also referred to as a black optical layer in the present invention, and a first packaging layer 314 superposed with the black adhesive layer 313. In FIG. 11-1, viewed from a position relationship, the first packaging layer 314 is located on the black adhesive layer 313. However, it should be understood that during manufacturing, the first packaging layer 314 may be first formed, and then the black adhesive layer 313 is formed on the first packaging layer 314; or the black adhesive layer 313 may be first formed, and then the first packaging layer 314 is formed on the black adhesive layer 313.

Step b20: manufacture a substrate. For example, refer to a substrate shown in FIG. 11-1, where a plurality of light-emitting units are arranged on the substrate 110, a gap f1 is provided between adjacent light-emitting units, and a main part of a silver outer surface Y formed during soldering is in the gap f1.

Step c20: laminate the black adhesive layer 313 and the first packaging layer 314 together onto LED chips 2101 arranged on a top surface of the substrate 110, and then perform press-fitting using a hot-pressing process. A surface of the black adhesive layer 313 far away from the first packaging layer 314 is oriented to the substrate 110.

Step d20: press-fit the black adhesive layer 313 and the first packaging layer 314 onto the top surface of the substrate 110, and then cover the top surface of the substrate 110 and the LED chips 2101 with the black adhesive layer 313. The first packaging layer 314 forms a concave portion in the gap between the adjacent light-emitting units. A schematic diagram of the concave portion is shown in FIG. 11-2 (FIG. 11-2 shows a structure remaining after the black adhesive layer is removed from the display module obtained after the press-fitting of step d20 in FIG. 11-1), FIG. 11-2 shows a concave portion f11 formed between the light-emitting units A side wall of the concave portion f11 includes a curved surface d formed by fluidity of the first packaging layer 314, and formation of the curved surface d can further increase the lamination area between the black adhesive layer 313 and the first packaging layer 314, thereby improving the bonding strength between the two packaging layers.

As shown in FIG. 11-1 and FIG. 11-2, in this example, after the press-fitting, the first packaging layer 314 covers each concave portion f11, and each silver outer surface Y is covered by the first packaging layer 314, which can improve the contrast of the display module, and improve the display effect. In addition, the LED chips 2101 are covered by the first packaging layer 314, the black adhesive layer 313 covers the first packaging layer 314, and the black adhesive layer 313 does not contact the LED chips 2101. Therefore, the black adhesive layer 313 does not remain on the LED chips 2101, which can ensure light-emitting characteristics of the LED chips 2101.

In addition, in step c20, the black adhesive layer 313 and the first packaging layer 314 are press-fit together onto the top surface of the substrate, which can simplify the manufacturing process, and improve the manufacturing efficiency. In addition, the used hot-pressing process is simple and mature, which can further ensure and improve the yield, and facilitate control of the manufacturing costs.

For ease of understanding, this embodiment is described below using an example in which the same manufacturing process as that in FIG. 11-1 is used in a cross-sectional view of a substrate in another direction. Specifically, as shown in FIG. 11-3, step a21 to step d21 in FIG. 11-3 are the same as step a20 to step d20 in FIG. 11-1 respectively. Details are not described herein again. As shown in step b21 in FIG. 11-3, it is assumed that LED chips X1 and X2 are inclined during soldering. FIG. 11-4 shows a structure remaining after the first packaging layer is removed from the display module obtained after the press-fitting in FIG. 11-3. As shown in FIG. 11-3 and FIG. 11-4, regions of the first packaging layer 314 right above the light-emitting surfaces of the LED chips 2101 can also form one flat surface Q, that is, the first packaging layer 314 is used to compensate for unevenness caused by inclination of the LED chips X1 and X2 as much as possible, thereby ensuring consistency of the black adhesive layer 313 between the regions on the first packaging layer 314, and improving consistency between light-emitting effects of modules.

As shown in FIG. 11-1 and FIG. 11-3, in this example, each light-emitting unit contains multiple LED chips. A gap f2 is provided between adjacent LED chips 2101 in each light-emitting unit 210, and the width of the gap f2 between LED chips 2101 is less than the width of the gap f1 between the light-emitting units 210. In addition, it should be understood that in the display field, the width of the gap f2 is generally far less than the width of the gap f1, and a specific difference between the two may be flexibly set according to a specific application scenario and is not limited herein.

In this example, as shown in FIG. 11-3 and FIG. 11-4, after the black adhesive layer 313 and the first packaging layer 314 are press-fit together on the top surface of the substrate through a hot-pressing process, a region of the first packaging layer 314 on the gap f2 between LED chips forms a concave portion f12, the black adhesive layer 313 fills in the concave portion f12 and completely covers a top surface of the first packaging layer 314, and the top surface of the first packaging layer 314 is a surface thereof far away from the substrate 110. As shown in FIG. 11-4, a distance h2 from the lowest point of the concave portion f12 to the top surface of the substrate is greater than a distance h1 from the light-emitting surface of the LED chip 2101 to the top surface of the substrate. To be specific, in this example, the thickness of the first packaging layer 314 filled in the concave portion f12 is greater than the thickness of the LED chip 2101.

In another embodiment, the distance h3 from the lowest point of the concave portion f11 formed between the light-emitting units 210 to the top surface of the substrate 110 is less than the distance h1 from the light-emitting surface of the LED chip 2101 to the top surface of the substrate 110. To be specific, in this example, the thickness of the first packaging layer 314 filled in the concave portion f11 is less than the thickness of the LED chip 2101. For example, in some scenarios, h3 may be set to be less than or equal to ⅔*h1. The setting of this structure can reduce a whole thickness of the display module as much as possible and better facilitate lightening and thinning of the display screen; and can improve utilization of the adhesive material and reduce the costs. For example, in some specific display module structures, h3 is set to be equal to ⅓*h1, ½*h1, or ⅔*h1. Preferably, h3 is greater than or equal to ½*h1 and less than or equal to ⅔*h1, thereby reducing the refinement requirement on the thickness of the black adhesive layer 313 and reducing the process precision requirement.

In some application scenarios of this example, based on a condition that the first packaging layer 314 is set to satisfy display contrast performance, the first packaging layer 314 may be further set to have specific light transmission performance. In the present invention scenario, after a display module is manufactured through the manufacturing method shown in FIG. 11-1 or FIG. 11-3, no treatment may be performed on the first packaging layer 314, thereby simplifying the manufacturing process and improving the manufacturing efficiency.

Certainly, in some examples, even if the black adhesive layer 313 has light transmission performance, to further improve the luminous efficiency of the display module, after the display module is made, a part of the black adhesive layer 313 above the light-emitting surfaces of the LED chips 2101 can also be removed. For example, for an application scenario, refer to a display module shown in FIG. 11-5. A part of the black adhesive layer 313 is removed, thereby obtaining a thinner black adhesive layer 313, to improve the luminous efficiency. After the removing, the black adhesive layer 313 still covers a first packaging layer 314 on the light-emitting surfaces of LED chips 2101, and the top surface of the black adhesive layer 313 is a flat plane. In the display module shown in FIG. 11-5, a part of black adhesive layer 313 may be removed, but not limited to, by grinding or another process. FIG. 11-6 shows a schematic diagram of the partial removing of black adhesive layer 313 in the display module After the removing, a top surface of the black adhesive layer 313 still covers a first packaging layer 314 on light-emitting surfaces of LED chips 2101 and the concave portion f11 and the concave portion f12, and the top surface of the black adhesive layer 313 is a flat plane.

For another application scenario, refer to display modules shown in FIG. 11-7 and FIG. 11-8. FIG. 11-7 shows the partial removal of the black adhesive layer 313 disposed on the light-emitting surface of LED chips in the display module of FIG. 11-1, and FIG. 11-8, shows the partial removal of the black adhesive layer 313 disposed on the light-emitting surface of LED chips in the display module of FIG. 11-3, so that the black adhesive layer 313 right above the light-emitting surfaces of the LED chips 2101 is thinner than the thickness of the black adhesive layer 313 in the display modules shown in FIG. 11-1 and FIG. 11-3, to improve the luminous efficiency. In this scenario, the first packaging layer 314 may be removed, but not limited to, by an etching process.

In this embodiment, the black adhesive layer 313, which is also referred to as a black optical layer in the present invention, has specific light transmission performance. Regardless of whether to use the foregoing step of removing the black adhesive layer 313 shown in FIG. 11-5 to FIG. 11-8, to ensure the luminance and the display effect of the module, the light transmittance of the black adhesive layer 313 reserved on the light-emitting surfaces of the LED chips 2101 may be set to be greater than or equal to 40%.

In another example of this embodiment, the manufacturing method for a display module may further include, but not limited to:

After the black adhesive layer 313 and the first packaging layer 314 are press-fit together on the top surface of the substrate through the hot-pressing process, further completely removing the first packaging layer 314 right above the light-emitting surfaces of the LED chips 2101.

For example, in some application scenarios, the completely removing the black adhesive layer 313 right above the light-emitting surfaces of the LED chips 2101 includes: completely removing the black adhesive disposed on the region of the concave portion f12, where after the removing, the black adhesive layer 313 is flush with the first packaging layer 314 on the light-emitting surfaces of the LED chips. For example, for an application scenario, refer to a display module shown in FIG. 11-9. A portion of the overall black adhesive layer 313 of FIG. 11-1 removed, until a part of the first packaging layer 314 above the light emitting surface of LED chips 2101 is exposed After the removing, the black adhesive layer 313 is flush with the first packaging layer 314 on the light-emitting surfaces of the LED chips 2101. In the present invention scenario, a schematic diagram of the whole first packaging layer 314 in the display module shown in FIG. 11-3 with a part removed is shown in FIG. 11-10. The first packaging layer 314 above the emitting surface of each LED chip 2101 is exposed from the black adhesive layer 313, and the removed black adhesive layer 313 still fills the concave f12 and is flush with the first packaging layer 314 on the light-emitting surfaces of the LED chips 2101. In the examples shown in FIG. 11-9 and FIG. 11-10, after the removing, the black adhesive layer 313 still covers the first packaging layer 314 on edge regions of the light-emitting surfaces of the LED chips 2101, so that the the black adhesive layer 313 may cover a silver outer surface Y existing between the LED chips 2101 in the light-emitting units as much as possible, thereby further improving the display contrast of the module.

In this example, another example of completely removing the black adhesive located in the concave portion f12 is shown in FIG. 11-11. In contrast to the removal method shown in FIG. 11-10, the difference lies in that when removing the black adhesive layer 313, it is removed until the black adhesive layer 313 is removed and until the black adhesive layer 313 located in the concave portion f12 is also completely removed (it may be learned from FIG. 11-11 that the concave portion f12 on the first packaging layer 314 is also completely removed), after the removing, the black adhesive layer 313 is flush with the first packaging layer 314 on the light-emitting surfaces of the LED chips 2101, and the concave portion f12 does not exist on the first packaging layer 314 anymore. Compared with the example shown in FIG. 11-10, the black adhesive layer 313 and the first packaging layer 314 have a smaller whole thickness, to better facilitate lightening and thinning of the module.

The black adhesive of the black adhesive layer 313 located in the concave portion f12 may alternatively be completely removed in a local removing manner. For example, as shown in FIG. 11-12, the black adhesive of the black adhesive layer 313 in the display module shown in FIG. 11-1 located above the light-emitting surfaces of the LED chips 2101 is locally completely removed; and in FIG. 11-13, the black adhesive of the black adhesive layer 313 in the display module shown in FIG. 11-3 located right above the light-emitting surfaces of the LED chips 2101 is locally completely removed.

In the foregoing examples of this embodiment, the locally removing the black adhesive layer 313 can improve the removing efficiency of the black adhesive layer 313. In addition, in the examples shown in FIG. 11-9 to FIG. 11-13, the black adhesive layer 313 may have a light transmission characteristic or have no light transmission characteristic, and the black adhesive layer 313 has more flexible material selection and wider applicability.

In still some other examples of this embodiment, to improve the yield and the manufacturing efficiency, a substrate jig may be provided, and the substrate jig is provided with an accommodating cavity adapted for the substrate. When the black adhesive layer and the first packaging layer are press-fit to the top surface of the substrate, the substrate may be fixed on the substrate jig. After the fixation, the substrate is fixedly arranged in the accommodating cavity of the substrate jig. In addition, the back surface of the substrate faces the bottom of the accommodating cavity, and the top surface of the substrate and the LED chips face a top opening of the accommodating cavity, to laminate the black adhesive layer. In this example, before the black adhesive layer is press-fit to the top surface of the substrate, other electronic elements are first arranged on the back surface of the substrate. The bottom of the accommodating cavity is further provided with an accommodating groove corresponding to each electronic element. After the substrate is fixed on the substrate jig, each electronic element is located in a corresponding accommodating groove. It can be learned that the substrate jig used in this embodiment has a simple structure, is easy to manufacture, and has low costs.

It can be learned that in the manufacturing method for a display module provided in this embodiment, the process is simple, the efficiency is high, costs are low, the display contrast of the manufactured display module is good, and the first packaging layer included in the display module has good consistency, and does not remain on the light-emitting surfaces of the LED chips. This embodiment further provides a display screen. The display screen is manufactured through at least one manufacturing method for a display module in the foregoing examples. It can be learned that the display screen provided in this embodiment has good black contrast, the manufacturing process is simple, impact on flatness of the LED chips after the LED chips are fixed onto the substrate is reduced, the yield is high, and costs are low.

### Embodiment 11

Because a point light source of a backlight module is converted into a surface light source through optical film sheets such as light homogenization film sheets or diffusion film sheets in the related technology, and 2 or 3 light homogenization film sheets or diffusion film sheets are generally required, it is inevitable that a whole thickness and costs of a display module are increased, and consequently a requirement of consumers on a product cost-performance ratio cannot be satisfied. This embodiment provides a display module and a manufacturing method therefor that can resolve this technical problem. In addition, this embodiment may be individually implemented independently of other embodiments.

An example of the manufacturing method for a display module provided in this embodiment of the present invention includes the following steps:

Step a22: arrange a plurality of light-emitting units on a top surface of the substrate, where each of the light-emitting units includes at least one LED chip. In this step, LED chips are fixed on the top surface of the substrate, and the LED chips are evenly distributed on the top surface of the substrate according to a preset array layout.

Step b22: manufacture a first packaging layer used for sealing the plurality of LED chips. The first packaging layer can seal and protect the LED chips.

Step c22: arrange a plurality of light diffusion units at intervals on an light-emitting surface of the first packaging layer. Before this step, the manufacturing method further includes mixing light diffusion particles into a glue solvent according to a predetermined proportion to manufacture glue. This step may be performed before or after step b22, and then the light diffusion units are arranged on the light-emitting surface of the first packaging layer using the glue. In this embodiment, the light diffusion particles include silicon dioxide and/or titanium dioxide, a resin adhesive is used as the glue solvent, and the silicon dioxide and/or titanium dioxide are/is mixed into the glue solvent according to a predetermined proportion relationship.

The array layout of the light diffusion units on the light-emitting surface of the first packaging layer should be the same as the array layout of the LED chips on the top surface of the substrate, so that the light diffusion units are just located right above the LED chips. The light diffusion units reflect and refract light emitted by the LED chips to evenly emit the light emitted by the LED chips from the light-emitting surface of the first packaging layer, so that when the light emitted by the LED chips on the substrate is emitted from the light-emitting surface of the first packaging layer, the light-emitting surface of the first packaging layer is a surface light source that evenly emits light. In this step of this embodiment, the light diffusion units may be manufactured and molded on the light-emitting surface of the first packaging layer using a 3D printing technology or a silk-screen printing technology.

Step d22: press-fit the first packaging layer provided with the light diffusion units onto the top surface of the substrate.

After the light diffusion units are arranged on the first packaging layer, the first packaging layer provided with the light diffusion units are press-fit onto the top surface of the substrate. In this embodiment, the first packaging layer provided with the light diffusion units may be press-fit onto the substrate using a hot-pressing process, so that the first packaging layer clothes LED chips. The light diffusion units are pressed into a protection adhesive layer and located above the LED chips, and upper surfaces of the light diffusion units and the light-emitting surface of the first packaging layer are located in a same plane. It should be understood that in this embodiment, the melting point of the light diffusion units is greater than the melting point of the first packaging layer, and the first packaging layer is press-fit onto the substrate using the hot-pressing process. During the hot-pressing, the light diffusion units are not deformed because of being heated. When the first packaging layer reaches the melting point because of being heated, the first packaging layer clothes the LED chips, and the light diffusion units are pressed into the first packaging layer. Therefore, if the whole thickness of the first packaging layer is maintained unchanged, because light emitted by the LED chips is refracted and reflected for a plurality of times by the light diffusion units in the first packaging layer that are arranged above the LED chips and then is emitted from the light-emitting surface of the first packaging layer, the light-emitting surface of the first packaging layer evenly emits light, and no light homogenization film sheet needs to be arranged on the first packaging layer, to avoid use of a light homogenization film sheet and reduce the whole thickness of the backlight module. The light diffusion units perform optical treatment on light from a single LED chip, so that light homogenization performance is good, to avoid a particle agglomeration phenomenon, compared with use of a light homogenization film sheet. In addition, the light-emitting chips do not directly contact the light diffusion units, so that the light emitted by the LED chips is reflected for a plurality of times between the light diffusion units and the top surface of the substrate and then is emitted from the first packaging layer, to reduce the light loss.

After step d22 of this embodiment, the manufacturing method further includes: arranging an optical film layer on a side of the light-emitting surface of the first packaging layer. The optical film layer includes a quantum film and a prismatic lens, but does not include a light homogenization film. In this embodiment, the light emitted by the LED chips is reflected and refracted by the light diffusion units arranged in the first packaging layer and then is emitted from the light-emitting surface of the first packaging layer, so that the light-emitting surface of the first packaging layer evenly emits light, instead of arranging a light homogenization film on the first packaging layer to homogenize the light from the LED chips, to save use of a light homogenization film sheet and reduce the whole thickness of the backlight.

This embodiment further provides another exemplary manufacturing method for a display module, including steps:

Step a23: arrange a plurality of light-emitting units on a top surface of the substrate, where each of the light-emitting units includes at least one LED chip. In this step, LED chips are fixed on the top surface of the substrate, and the LED chips are evenly distributed on the top surface of the substrate according to a preset array layout.

Step b23: manufacture a first packaging layer used for sealing the plurality of LED chips.

Step c23: mix light diffusion particles into a glue solvent according to a predetermined proportion to manufacture glue.

In this embodiment, the light diffusion particles include silicon dioxide and/or titanium dioxide, a resin adhesive is used as the glue solvent, and the silicon dioxide and/or titanium dioxide is mixed into the glue solvent according to a predetermined proportion relationship. In this embodiment, step b23 and step c23 may be performed interchangeably or may be performed simultaneously.

Step d23: print the manufactured glue on an light-emitting surface of the first packaging layer using a 3D printing technology, to form light diffusion units. In this example, the glue is printed on the light-emitting surface of the first packaging layer using the 3D printing technology, to form the light diffusion units evenly distributed. It should be understood that in this embodiment, the glue may alternatively be silk-screen printed on the light-emitting surface of the first packaging layer using a silk-screen printing technology, to form the light diffusion units. The array layout of the light diffusion units on the light-emitting surface of the first packaging layer should be the same as the array layout of the LED chips on the top surface of the substrate, so that the optical structure is just located right above the LED chips. The light diffusion units reflect and refract light emitted by the LED chips to evenly emit the light emitted by the LED chips from the light-emitting surface of the first packaging layer, so that when the light emitted by the LED chips on the substrate is emitted from the light-emitting surface of the first packaging layer, the light-emitting surface of the first packaging layer is a surface light source that evenly emits light.

Step e23: press-fit the first packaging layer provided with the light diffusion units onto the top surface of the substrate.

Step f23: arrange an optical film layer on a side of the light-emitting surface of the first packaging layer. In this embodiment, the optical film layer includes a quantum film and a prismatic lens but does not include a light homogenization film. In this embodiment, the light emitted by the LED chips is reflected and refracted by the light diffusion units arranged in the first packaging layer and then is emitted from the light-emitting surface of the first packaging layer, so that the light-emitting surface of the first packaging layer evenly emits light, instead of arranging a light homogenization film on the first packaging layer to homogenize the light from the LED chips, to save use of a light homogenization film sheet and reduce the whole thickness of the backlight.

In the backlight module manufactured through the foregoing exemplary method, through the light diffusion units in the first packaging layer and above the LED chips, the light emitted by the LED chips is evenly emitted from the light-emitting surface of the first packaging layer, to save the light homogenization film sheet, reduce the whole thickness of the backlight module, and reduce the costs of the backlight module.

This embodiment further provides a display module, to resolve the problem in the related technology that a point light source of a backlight module is converted into a surface light source through optical film sheets such as light homogenization film sheets or diffusion film sheets, which increases a whole thickness and costs of a display module, and consequently cannot satisfy a requirement of consumers on a product cost-performance ratio. The display module includes: a substrate, and a plurality of light-emitting units arranged on a top surface of the substrate. For the substrate and the light-emitting units in this embodiment, reference may be made to, but not limited to, the foregoing embodiments. Details are not described herein again. In this embodiment, a driving IC for LED chips may be further arranged on a back surface of the substrate, to drive the LED chips to work. The display module further includes a first packaging layer arranged on the top surface of the substrate and covering the LED chips. A plurality of first diffusion regions distributed at intervals are formed in regions of the first packaging layer far away from top surfaces of the LED chips, each of the first diffusion regions includes at least one light diffusion unit, each of the light diffusion units includes a light incident surface opposite to the top surface of an LED chip and a light emergent surface flush with an light-emitting surface of the first packaging layer, and the light diffusion units are used to reflect and refract light emitted by the LED chips to evenly emit the light emitted by the LED chips from the light-emitting surface of the first packaging layer.

For ease of understanding, the display module provided in this embodiment is exemplified below with reference to accompanying drawings used as examples.

An exemplary display module is shown in FIG. 12-1, and includes a substrate 111, a plurality of LED chips 2110 evenly distributed on a top surface of the substrate 111, and a first packaging layer 315 arranged on the top surface of the substrate and covering the LED chips. A plurality of first diffusion regions 3151 distributed at intervals are formed in regions of the first packaging layer 315 that correspond to top surfaces of the LED chips, each of the first diffusion regions 3151 includes at least one light diffusion unit region 3153, and light diffusion units are formed by a glue solvent and light diffusion particles mixed into the glue solvent according to a predetermined proportion. In this embodiment, the first diffusion regions 3151 are located right above the LED chips 2110 and have a projection area on the top surface of the substrate greater than a projection area of the LED chips on the top surface of the substrate.

In this embodiment, each of the light diffusion unit regions 3153 on each of the first diffusion regions 3151 includes a light incident surface opposite to the top surface of each of the LED chip and a light emergent surface flush with an light-emitting surface of the first packaging layer 315. As shown in FIG. 12-2, light F emitted by LED chips is incident onto a light incident surface of a light diffusion units, then is reflected and refracted, and then is emitted from a light emergent surface of the light diffusion unit, so that the light emitted by the LED chips is evenly emitted from an light-emitting surface of a first packaging layer 315. The light diffusion units separately perform optical treatment on light from a single LED chip, so that light homogenization performance is good, to avoid a particle agglomeration phenomenon, compared with use of a light homogenization film sheet. In addition, the LED chips do not directly contact the light diffusion units, so that the light emitted from top surfaces of the LED chips is reflected for a plurality of times between the light diffusion units and the top surface of the substrate and then is emitted from the first packaging layer, to reduce the light loss. The array layout of the light diffusion units on the light-emitting surface of the first packaging layer should be the same as the array layout of the LED chips on the top surface of the substrate, so that the light diffusion units are just located right above the LED chips. The light diffusion units reflect and refract light emitted by the LED chips to evenly emit the light emitted by the LED chips from the light-emitting surface of the first packaging layer, so that when the light emitted by the LED chips on the substrate is emitted from the light-emitting surface of the first packaging layer, the light-emitting surface of the first packaging layer is a surface light source that evenly emits light.

It should be understood that the backlight module in this embodiment further includes an optical film layer arranged on a side of the light-emitting surface of the first packaging layer. The optical film layer includes a quantum film and a prismatic lens, but does not include a light homogenization film. In this embodiment, the light emitted by the LED chips is reflected and refracted by the light diffusion units arranged in the first packaging layer and then is emitted from the light-emitting surface of the first packaging layer, so that the light-emitting surface of the first packaging layer evenly emits light, instead of arranging a light homogenization film on the first packaging layer to homogenize the light from the LED chips, to save use of a light homogenization film sheet and reduce the whole thickness of the backlight.

In this embodiment, glue is made of a glue solvent and light diffusion particles mixed into the glue solvent according to a predetermined proportion. The light diffusion particles include at least one of silicon dioxide and/or titanium dioxide. The shape of the light diffusion particles includes any one of a circle, a square, and a triangle, or may be another irregular shape, and may be flexibly set according to actual application. After the glue is made, the glue is printed on the light-emitting surface of the first packaging layer through a 3D printing technology or the glue is silk-screen printed on the first diffusion regions on the light-emitting surface of the first packaging layer through a silk-screen printing technology, to form the light diffusion units. Then, the first packaging layer provided with the light diffusion units is press-fit onto the top surface of the substrate through a hot-pressing process, so that the LED chips arranged on the top surface of the substrate are cladded in the first packaging layer. In addition, the light diffusion units on the light-emitting surface of the first packaging layer are pressed into the first packaging layer and located right above the LED chips, and upper surfaces of the light diffusion units and the light-emitting surface of the first packaging layer are located in a same plane. It should be understood that in this embodiment, the light diffusion unit has a projection area on the top surface of the substrate greater than a projection area of the LED chip on the top surface of the substrate, so that the light diffusion unit can reflect or refract most of the light emitted by the LED chip.

In this embodiment, the light homogenization effect of the light diffusion unit is related to the shape and the thickness of the light diffusion unit and an ingredient proportion of the light diffusion particles in the light diffusion unit, and different light homogenization effects can be achieved by setting different shapes and thicknesses of the light diffusion unit and different ingredient proportions of the light diffusion particles. In this embodiment, silicon dioxide is used as an example of the light diffusion particles, a proportion of the silicon dioxide in the glue is determined according to a pitch between the LED chips (as shown in FIG. 12-1) and the thickness of the light diffusion unit, and according to a crosstalk ratio indicator of the display module, light from one lamp region should be diffused into other lamp regions as little as possible. Therefore, the proportion of the silicon dioxide positively correlates with the LED pitch and negatively correlates with the thickness of the light diffusion unit, and the LED pitch and the thickness of the light diffusion unit are set according to an actual requirement. In this embodiment, the proportion of the silicon dioxide=30%+[(LED Pitch−3.0)/0.2−(the thickness of the light diffusion unit−20)/10]*10%. Table 1 shows several groups of data of proportions of silicon dioxide, LED pitches, and thicknesses of a light diffusion unit obtained according to the relationship expression.

TABLE 1

| Proportion of silicon | Thickness of a light | LED pitch |
|---|---|---|
| dioxide (%) | diffusion unit (μm) | (μm) |
| 30 | 20 | 3.0 |
| | 30 | 3.2 |
| | 40 | 3.4 |
| | 50 | 3.6 |
| 40 | 20 | 3.2 |
| | 30 | 3.4 |
| | 40 | 3.6 |
| | 50 | 3.8 |
| 50 | 20 | 3.4 |
| | 30 | 3.6 |
| | 40 | 3.8 |
| | 50 | 4.0 |

In an example, as shown in FIG. 12-3, only one light diffusion unit is arranged in each of the first diffusion regions 3151, to fill in the entirety of each of the first diffusion regions 3151, the shape of the light diffusion unit is a circle, and the shape of the light diffusion unit mentioned in this embodiment is the shape of a projection of the light diffusion unit on the top surface of the substrate. It should be understood that the shape of the light diffusion unit is not limited to the foregoing several examples or may be any other shape, and may be flexibly set according to an actual need. In this embodiment, the light diffusion unit should have a projection area on the top surface of the substrate greater than a projection area of the LED chip on the top surface of the substrate.

In this embodiment, each of the first diffusion regions 3151 may alternatively include a plurality of light diffusion units, and the plurality of light diffusion units form each of the first diffusion regions according to a preset arrangement rule. As shown in FIG. 12-4, the first diffusion region 3151 includes a plurality of light diffusion unit regions 3153, and the plurality of light diffusion unit regions 3153 are evenly arranged in the first diffusion region at equal pitches. In this embodiment, the plurality of light diffusion units are evenly distributed at equal pitches. Certainly, the plurality of light diffusion units may alternatively be distributed according to another arrangement rule, and the shape of the light diffusion unit may include any one of a circle, a rectangle, and a triangle, and be flexibly set according to an actual need.

In this embodiment, a plurality of second diffusion regions may be further arranged at intervals around the first diffusion region, each of the second diffusion regions includes at least one light diffusion unit, and the second diffusion regions are distributed around the first diffusion region according to a preset rule. In this embodiment, the second diffusion regions are evenly distributed at equal pitches around the first diffusion region. It should be understood that the second diffusion regions may alternatively be distributed around the first diffusion region according to another arrangement rule, and may be flexibly set according to an actual application requirement. It should be understood that in this embodiment, the projection area of each of the second diffusion regions on the substrate is less than the projection area of the first diffusion region on the substrate.

In an example, as shown in FIG. 12-5, eight second diffusion regions 3152 are further arranged around the first diffusion region 3151, one light diffusion unit is arranged in the first diffusion region 3151, one light diffusion unit is arranged in each of the second diffusion regions 3152, and the second diffusion regions 3152 are arranged at equal pitches around the first diffusion region 3151.

In another example, as shown in FIG. 12-6, eight second diffusion regions 3152 are arranged around the first diffusion region 3151, a plurality of light diffusion unit regions 3153 are arranged in the first diffusion region 3151, a plurality of light diffusion units are arranged in each of the second diffusion regions 3152, and the plurality of light diffusion units in the first diffusion region and the second diffusion regions are evenly arranged at equal pitches.

In the display module provided in this embodiment, light diffusion units are arranged in regions of the first packaging layer far away from top surfaces of the LED chips, to reflect or refract light emitted by the LED chips to evenly emit the light emitted by the LED chips from the light-emitting surface of the first packaging layer, thereby saving use of the light homogenization film and reducing a whole thickness and costs of the backlight module. This embodiment further provides a display screen, including at least one display module shown in the foregoing examples.

### Embodiment 12

In this embodiment, one light-emitting unit is one pixel unit of the display module, and generally includes a red light LED chip, a green light LED chip, and a blue light LED chip (positions of the red light LED chip and the blue light LED chip are interchangeable) that are sequentially arranged in a row or a column. The red light LED chip, the green light LED chip, and the blue light LED chip may be LED chips whose quantum wells emit red light, green light, and blue light respectively. However, in some other examples, the red light LED chip, the green light LED chip, or the blue light LED chip may alternatively be obtained by converting light in a color emitted by an LED chip through a light conversion layer such as a quantum dot film layer or a fluorescent powder layer. In this arrangement, the green light LED chip is adjacent to both the red light LED chip and the blue light LED chip, but the red light LED chip and the blue light LED chip are spaced apart from each other by the green light LED chip. Therefore, a light mixing effect of the green light and the red light and a light mixing effect of the green light and the blue light are both good, while a light mixing effect of the red light and the blue light is poor. As a result, light emitted by light-emitting units as a whole has chromatic aberration, which affects a whole display effect of the display module. This embodiment provides a display module that can resolve this technical problem. In addition, this embodiment may be individually implemented independently of other embodiments.

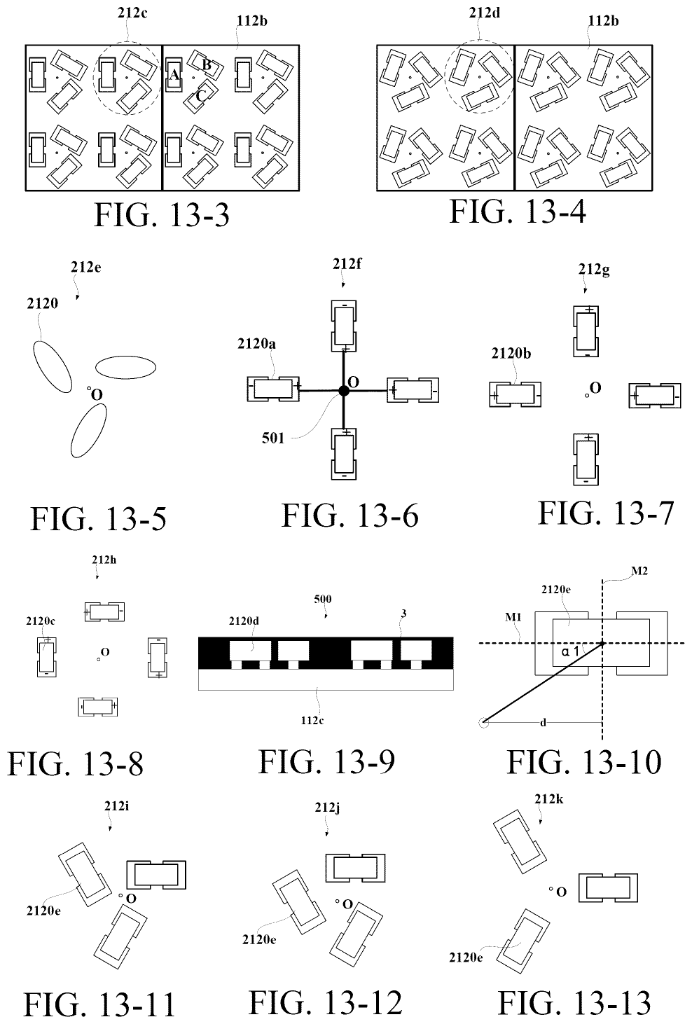

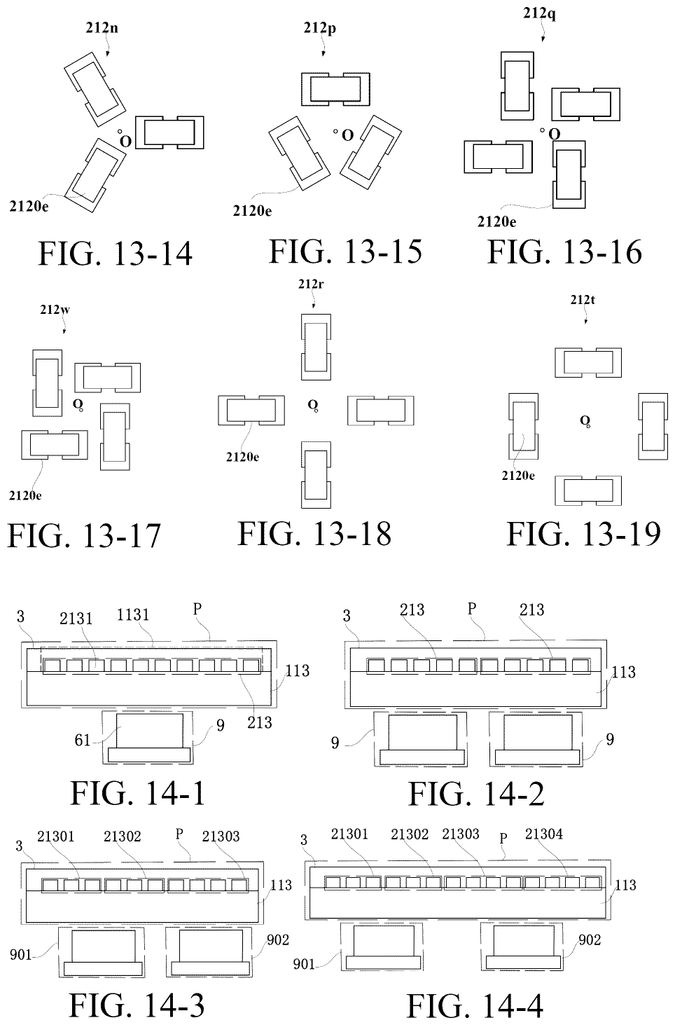

An exemplary display module provided in this embodiment is shown in FIG. 13-1. The display module 400 includes a substrate 112a and a plurality of light-emitting units 212a, and the substrate 112a is provided with a driving circuit.

Each of the light-emitting units 212a includes N LED chips, N is greater than or equal to 3, and colors of the LED chips are not completely the same, that is, may be completely different or partially the same. In other words, each of the light-emitting units 212a includes a plurality of LED chips whose colors are not completely the same. In some examples of this embodiment, each of the light-emitting units 212a includes a red light LED chip 2121a, a green light LED chip 2122a, and a blue light LED chip 2123a, and these LED chips may be chips whose quantum wells emit light in corresponding colors or be chips with light in corresponding colors obtained through conversion of a light conversion layer. In some other examples of this embodiment, colors of LED chips in each of the light-emitting units 212a may not be limited to such three types as red, green, and blue, and may further include, for example, at least one of several colors of a white light LED chip, a yellow light LED chip, and the like. In some examples, the light-emitting unit 212a may include four LED chips in red, green, blue, and white. In some examples, one light-emitting unit 212a is formed by three LED chips such as a red light LED chip 2121a, a green light LED chip 2122a, and a blue light LED chip 2123a. In some other examples, although one light-emitting unit 212a includes LED chips only in three colors such as red, green, and blue, but two or more LED chips are in at least one of the colors.

It may be understood that when one light-emitting unit includes three LED chips, an angle between two adjacent center connection lines is 120°, that is, an angle between a connection line between the center of one LED chip and a rotational symmetry center and a connection line between the center of an adjacent LED chip and the rotational symmetry center is 120°. When one light-emitting unit includes four LED chips, an angle between two adjacent center connection lines is 90°. If the quantity of LED chips in the light-emitting unit is expanded into N, where N is greater than or equal to 3, an angle between a connection line between the center of one LED chip and a rotational symmetry center and a connection line between the center of an adjacent LED chip and the rotational symmetry center is 360°/N.

In this embodiment, for the size and the type of the LED chips, reference may be made to, but not limited to, the foregoing embodiments. In some examples of this embodiment, each LED chip on the substrate 112a is a chip with a flip structure, and the display module 400 is a COB display module, or may be a COG (Chip On Glass) display module.

In this embodiment, the LED chips in each of the light-emitting units 212a are arranged rotationally symmetrically, the so-called rotationally symmetric arrangement means that a pattern formed by arranging the LED chips in each of the light-emitting units 212a is a rotationally symmetric pattern, and the rotationally symmetric pattern is defined as follows: if one planar pattern after being rotated by angle of a (in radian) around one fixed point on a plane coincides with the initial pattern, this pattern is referred to as a rotationally symmetric pattern, this fixed point is referred to as a rotational symmetry center, and the rotating angle is referred to as a rotational angle. Typical rotationally symmetric patterns include a pattern of a fan blade, a pattern of a Hong Kong orchid tree in the regional emblem of the Hong Kong Special Administrative Region, and the like. In the corresponding pattern of each of the light-emitting units 212a in this embodiment, after being rotated by a specific angle around the rotational symmetry center, any LED chip may coincide with another LED chip.

It may be seen from FIG. 13-1 that, in a light-emitting unit 212a, one LED chip is adjacent to two other LED chips in a rotational direction, and the LED chips in the light-emitting unit 212a on one side close to a rotational symmetry center O are all adjacent to each other, thereby resolving the problem in the existing technology in which LED chips are arranged in rows or columns, where some LED chips are adjacent to each other at a short distance, and some LED chips are spaced apart from each other at a long distance, thereby causing an undesired light mixing effect because distances between the LED chips are not balanced. Particularly, in a case that each of the light-emitting units 212a is formed by three LED chips, as shown in FIG. 13-1, the LED chips of the red light LED chip 2121a, the green light LED chip 2122a, and the blue light LED chip 2123a are adjacent to each other in pairs in the rotational direction, and are also adjacent to each other on a side close to the rotational symmetry center, which can significantly improve the light mixing effect of the LED chips in the light-emitting unit 212a and improve the display performance of the display module.

In this embodiment, a vertical projection of an LED chip in a direction parallel to the substrate 112a (denoted as “vertical projection” below) has two symmetry axes perpendicular to each other, and the vertical projection of the LED chip is generally the same as a cross-sectional outline of the LED chip in the direction parallel to the substrate, but this embodiment does not exclude a case that the cross-sectional outline of the LED chip in the direction parallel to the substrate is different from the vertical projection of the LED chip in the direction parallel to the substrate. The vertical projection of the LED chip is, but not limited to, rectangular, rhombic, elliptical, regularly polygonal, or the like.

For ease of description, a connection line between the center of the LED chip and the rotational symmetry center is denoted as a “center connection line”. When the vertical projection of the LED chip has a specific length-width ratio (that is, the length-width ratio is greater than 1), a symmetry axis corresponding to a direction in which the vertical projection of the LED chip has a large size is referred to as a “long symmetry axis”, and a symmetry axis corresponding to a direction in which the vertical projection of the LED chip has a small size is referred to as a “short symmetry axis”. In some examples of this embodiment, the center connection line may be parallel to one symmetry axis of the vertical projection of the LED chip. For example, FIG. 13-2 is a schematic diagram of arrangement of LED chips in a light-emitting unit 212b. The light-emitting unit 212b includes four LED chips 2120, and a vertical projection of each of the four LED chips 2120 is in the shape of a rectangle, and has a center connection line that is parallel to a long symmetry axis of the vertical projection, that is, parallel to a long side of the rectangle, and perpendicular to a short symmetry axis, that is, perpendicular to a short side of the rectangle. It may be understood that two electrodes in the LED chip are generally arranged along a symmetry axis of the vertical projection (for example, generally arranged along the long symmetry axis, and certainly this embodiment does not exclude a case of being arranged along the short symmetry axis), so that when the center connection line is parallel to the symmetry axis of the vertical projection, the center connection line coincides with or is perpendicular to a connection line between electrode centers of the two electrodes of the LED chip (briefly referred to as an “electrode center connection line” below). In this way, a die bonding process for LED chips on the substrate is simpler, and the quantity of LED chips in a region with the same area on the substrate is small, which can facilitate heat dissipation of the LED chips and maintain reliability of the LED chips.

In some other examples, the two symmetry axes of the vertical projection of the LED chip are neither parallel to the center connection line, so that a deployment area of the light-emitting unit 212b on the substrate is smaller, to facilitate deployment of more light-emitting units 212b in a limited effective display region on the substrate. In addition, a smaller pitch between the light-emitting units 212b may be achieved, to further reduce a light mixing distance between the LED chips 2120, enhance a light mixing effect of a single light-emitting unit, and improve sharpness of an image displayed by the display module. Still refer to FIG. 13-1. In FIG. 13-1, each LED chip is “I”-shaped. For another example, as shown in FIG. 13-5, a light-emitting units 212e includes three LED chips 2120, a vertical projection of each of the three LED chips is in the shape of an ellipse, and has a center connection line that is parallel to neither a long axis nor a short axis of the ellipse. In some examples of this embodiment, the angle between the center connection line and the electrode center connection line ranges from 25° to 65°. For example, in some examples, it is ensured that the angle between the center connection line and the electrode center connection line ranges from 30° to 60°, and may be, for example not limited to, 30°, 45°, 50°, 55°, or 60°. By limiting the angle range, a contradiction between heat dissipation and light mixing of the LED chips in the light-emitting units may be balanced, to maintain the light mixing effect of the LED chips while ensuring the heat dissipation requirement of the LED chips.

In some examples of this embodiment, a symmetry axis of at least one of the LED chips in one light-emitting unit is parallel to a side edge of the substrate. For example, refer to FIG. 13-3. In FIG. 13-3, a light-emitting unit 212c includes three LED chips A, B, and C. A long symmetry axis of A is parallel to a side edge of a substrate 112b. It may be understood that because a vertical projection of A has a specific length-width ratio, and the long symmetry axis is parallel to the side edge of the substrate 112b, it means that a side of the LED chip A having a large size is parallel to the side edge of the substrate. As a result, when substrates are spliced, an light-emitting amount on a side surface of the LED chip A in the light-emitting unit 212c near a splicing seam is larger. Consequently, chromatic aberration occurs in the light-emitting unit 212c, and the display effect of the display module is affected. Therefore, in some examples of this embodiment, as shown in FIG. 13-4, a vertical projection of an LED chip in a direction parallel to a substrate has two symmetry axes perpendicular to each other, but none of symmetry axes of LED chips in a light-emitting unit 212d is parallel to a side edge of the substrate 112b, to improve a light mixing effect of light-emitting units 212d near a splicing seam, and enhance display performance of the display module.

It may be understood that when the LED chips in the light-emitting units are arranged rotationally symmetrically, the LED chips should not interfere with or contact each other, that is, a specific gap is reserved between adjacent LED chips. In some examples of this embodiment, the LED chip is micron-sized. For example, in some examples, the size of the vertical projection of the LED chip may be as small as 10 μm×10 μm. In some other examples, the size of the vertical projection of the LED chip may reach 400 μm×300 μm. In some examples of this embodiment, a distance from a rotational symmetry center O to each of two symmetry axes of an LED chip is less than 2 mm. In this way, a problem that LED chips in a surface light-emitting unit are arranged excessively dispersedly can be resolved based on ensuring that LED chips do not contact or interfere with each other, which can reduce the deployment area of the light-emitting units, and can also improve the light-emitting effect of the light-emitting units.

In some cases, when the LED chips of the light-emitting unit 212a are arranged rotationally symmetrically, two electrodes of each LED chip are at different distances from the rotational symmetry center O. For example, refer to FIG. 13-6. In a light-emitting unit 212f, each of four LED chips 2120a has one electrode relatively close to a rotational symmetry center O and the other electrode relatively far away from the rotational symmetry center O. In this embodiment, one electrode in the LED chip 2120a close to the rotational symmetry center O is denoted as a “sub-central electrode”, that is, an electrode close to the rotational symmetry center. In some examples of this embodiment, when the LED chips in the light-emitting unit are arranged rotationally symmetrically, polarities of sub-central electrodes of the LED chips may be set to be the same. For example, in FIG. 13-6, the sub-central electrode of each LED chip 2120a is an anode. Optionally, in some examples, the polarities of the sub-central electrodes of the LED chips in the light-emitting units are set to be the same, and these sub-central electrodes are connected together, to implement co-polar driving. For example, in FIG. 13-6, a conducting via hole 501 may be arranged at the rotational symmetry center O, and the sub-central electrodes of the LED chips with the same polarity are connected using the conducting via hole 501.

Certainly, it should be understood that this embodiment is not limited to a case that the conducting via hole 501 needs to be located at the rotational symmetry center O. For example, the conducting via hole may alternatively be located near the rotational symmetry center O. However, relatively, if the conducting via hole 501 is arranged at the rotational symmetry center O, the conducting via hole 501 is at equal distances from all the sub-central electrodes of the LED chips in the light-emitting unit 212f, to facilitate wiring design. In addition, in some other examples of this embodiment, two or more conducting via holes may alternatively be arranged corresponding to one light-emitting unit 212f, and these conducting via holes may be electrically connected together in another manner or be independent of each other. In some other examples, the sub-central electrodes of the LED chips in the light-emitting unit 212f may alternatively be electrically connected in a manner other than using a conducting via, and even in some examples, these sub-central electrodes are not electrically connected together, but are driven independently of each other. Further, in some examples, the polarities of the sub-central electrodes of the LED chips are different. As shown in FIG. 13-7, a light-emitting unit 212g shown in FIG. 13-7 also includes four LED chips 2120b similarly. However, sub-central electrodes of some LED chips 2120b are anodes, and sub-central electrodes of some LED chips 2120b are cathodes. However, in a light-emitting unit 212h shown in FIG. 13-8, two electrodes of an LED chip 2120c are at equal distances from a rotational symmetry center O, and the concept of a sub-central electrode does not exist. In this case, orientations of LED chips 2120c may be set arbitrarily, and polarities of adjacent electrodes of two adjacent LED chips 2120c may alternatively be set to be the same. Refer to FIG. 13-8. For example, in FIG. 13-8, an anode of the top LED chip 2120c is close to an anode of the left LED chip 2120c, a cathode of the top LED chip 2120c is close to a cathode of the right LED chip 2120c, an anode of the right LED chip 2120c is close to an anode of the bottom LED chip 2120c, and a cathode of the bottom LED chip 2120c is close to a cathode of the left LED chip 2120c.

In this embodiment, the plurality of light-emitting units 212a in the display module 400 may be arranged on the substrate 112a in an array, that is, in rows or columns. Still refer to FIG. 13-1. In some examples, orientations of LED chips in different light-emitting units are not associated, and therefore orientations of the light-emitting units are random. However, in some other examples, orientations of LED chips in the same color in the light-emitting unit are the same, as shown in FIG. 13-1. In this way, the LED chips in the same color are arranged easily on a transferred substrate according to the same orientation, and then are transferred together and bonded to the substrate 112a from the transferred substrate in a mass transfer manner, thereby improving the production efficiency of the display module and reducing the production costs.

In some examples of this embodiment, a display module 500 includes a packaging layer 3. The packaging layer 3 may be, but not limited to, the packaging layer structure shown in the foregoing other embodiments. As shown in FIG. 13-9, the packaging layer 3 covers LED chips 2120d. In FIG. 13-9, a case that orientations of LED chips 2120d in a light-emitting unit are different is simply explained. However, a person skilled in the art may understand that orientations of the LED chip 2120d in FIG. 13-9 are not a limitation on orientations of the LED chips 2120d in the display module 500. The packaging layer 3 can fix the LED chips 2120d on a substrate 112c more firmly, to prevent the LED chips 2120d from falling off from the substrate 112c, and can also block intrusion of external moisture into the interior of the LED chips 2120d. Particularly, when the LED chip 2120d includes a quantum dot material, the packaging layer 3 can protect the quantum dot material, improve reliability of the LED chip 2120d, and extend the service life of the display module 500. In some examples, the packaging layer 3 may be a transparent adhesive or a black adhesive. When the packaging layer 3 is a black adhesive, packaging of the display module 500 may be blackened, to prevent a user from viewing details of the LED chip 2120d and the substrate 112c in the display module 500 from the outside, and improve the display performance of the display module 500.

This embodiment further provides an electronic device. The electronic device includes a processor and at least one display module communicatively connected to the processor. The display module may be a display module provided in any one of the foregoing examples. In the display module, LED chips in a light-emitting units are arranged rotationally symmetrically. It may be understood that the communicative connection between the display module and the processor may be implemented through wired connection, for example, data bus connection, or may be implemented through wireless connection. In addition, in addition to the processor and the display module, the electronic device may further include other devices, for example, at least one of an audio input/output unit, an image acquisition unit, a memory, a Bluetooth module, a Wi-Fi module, and the like.

In the display module and the electronic device provided in this embodiment, because LED chips in a light-emitting unit in the display module are arranged rotationally symmetrically, arrangement of the LED chips in the light-emitting unit is changed, to change the original one-dimensional arrangement between the LED chips into two-dimensional arrangement, thereby reducing a difference between distances between the LED chips, improving balance of light mixing effects between the LED chips in different colors, and enhancing the display effect of the display module.

To enable a person skilled in the art to understand structures and advantages of the display module and the electronic device provided in the foregoing embodiments more clearly, the arrangement solution of the LED chips in the light-emitting unit in the foregoing example continues to be described with reference to examples in this embodiment: it may be understood that the arrangement solution of the LED chips in the light-emitting unit is related to each of the quantity of LED chips in the light-emitting unit, the shape of the LED chip itself, a distance of the LED chip relative to the rotational symmetry center, and an inclination angle of the LED chip relative to a reference direction on the substrate (for example, a direction parallel to a long side or short side of the substrate). In this embodiment, it is assumed that the light-emitting unit has three LED chips, and the vertical projection of the LED chip is “I”-shaped. In this case, specific arrangement of the LED chips in the light-emitting unit depends on the distance between the LED chip and the rotational symmetry center and the inclination angle of the LED chip relative to the reference direction.

First, refer to FIG. 13-10: a size of a vertical projection of an LED chip 2120e in a direction of one symmetry axis is greater than a size of the vertical projection in a direction of the other symmetry axis, and a size of the vertical projection thereof in a direction of a first symmetry axis M1 is greater than that in a direction of a second symmetry axis M2. For ease of description, in this embodiment, similarly, a symmetry axis corresponding to a direction in which the vertical projection of the LED chip has a large size is referred to as a “long symmetry axis”, and a symmetry axis corresponding to a direction in which the vertical projection of the LED chip has a small size is referred to as a “short symmetry axis”. Therefore, in FIG. 13-10, the first symmetry axis M1 is the long symmetry axis, and the second symmetry axis M2 is the short symmetry axis. Certainly, in some other examples, if the vertical projection of the LED chip is in the shape of a rectangle, the long symmetry axis is parallel to a long side of the LED chip, and the short symmetry axis is parallel to a short side of the LED chip; if the vertical projection of the LED chip is in the shape of a rhombus, the long symmetry axis is a long diagonal of the rhombus, and the short symmetry axis is a short diagonal of the rhombus; and if the vertical projection of the LED chip is in the shape of an ellipse, the long symmetry axis is a long axis of the ellipse, and the short symmetry axis is a short axis of the ellipse.

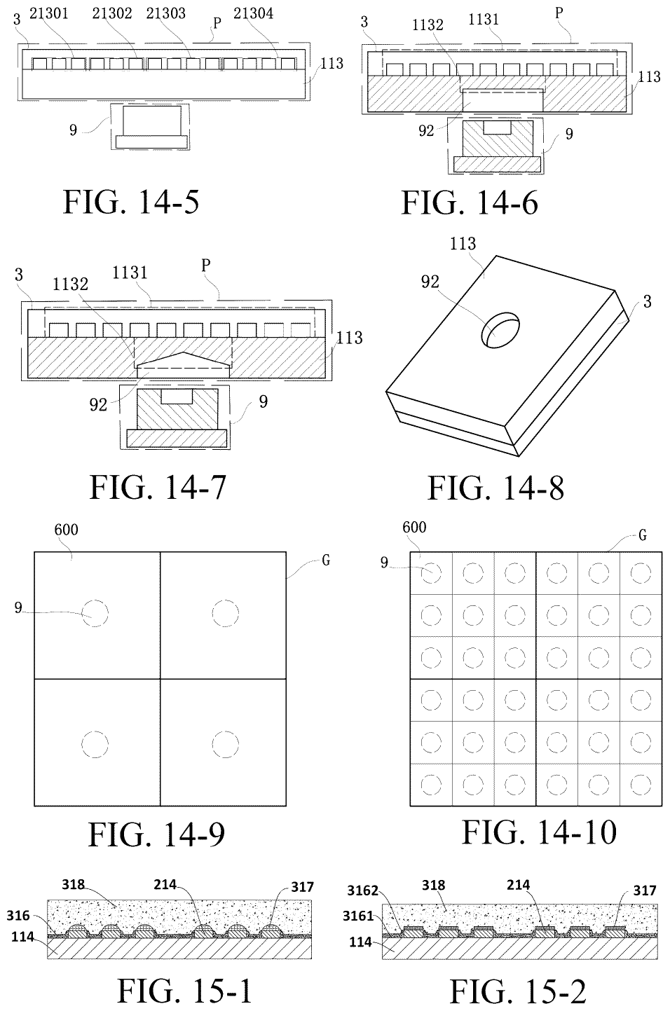

In this embodiment, a distance of the rotational symmetry center O from a short symmetry axis 802 of the LED chip 2120e is denoted as an adjustable distance. The angle between the center line, which is the line connecting the center of the LED chip 2120e to the rotation center O, and a long symmetry axis 801 is denoted as an adjustable angle α1. It may be understood that by adjusting values of the adjustable distance d (micron-sized, but in the accompanying drawing, the size of the LED chip 2120e and the size between the LED chips 2120e are both scaled up) and the adjustable angle α1, light-emitting units in which three LED chips 2120e are arranged differently may be obtained. FIG. 13-11 shows a light-emitting unit 212i obtained when the adjustable distance d is 85.75 and the adjustable angle α1 is 29.76°; FIG. 13-12 shows a light-emitting unit 212j obtained when the adjustable distance d is 35.74 and the adjustable angle α1 is 60.66°; FIG. 13-13 shows a light-emitting unit 212k obtained when the adjustable distance d is 126.79 and the adjustable angle α1 is 0; FIG. 13-14 shows a light-emitting unit 212n obtained when the adjustable distance d is 99.96 and the adjustable angle α1 is 0; FIG. 13-15 shows a light-emitting unit 212p obtained when the adjustable distance d is 0 and the adjustable angle α1 is 90°. In each light-emitting unit including three LED chips 2120e and shown in this embodiment, the adjustable distance d is less than 2 mm.

A case that a light-emitting unit includes four LED chips 2120e is described below: FIG. 13-16 shows a light-emitting unit 212q corresponding to an adjustable distance d of 85.75 and an adjustable angle α1 of 30°; FIG. 13-17 shows a light-emitting unit 212w obtained when the adjustable distance d is 47.56 and the adjustable angle α1 is 60°; FIG. 13-18 shows a light-emitting unit 212r obtained when the adjustable distance d is 166.77 and the adjustable angle α1 is 0; FIG. 13-19 shows a light-emitting unit 212t obtained when the adjustable distance d is 0 and the adjustable angle α1 is 0.

Undoubtedly, if a distance of the rotational symmetry center O from the first symmetry axis M1 of the LED chip 2120e is alternatively used as an adjustable distance, light-emitting units in different arrangement situations may be similarly obtained. Alternatively, it is feasible to use an angle between the center connection line and the second symmetry axis M2 as an adjustable angle.

In the display module or the electronic device obtained based on the arrangement solution of LED chips in this embodiment, in a range of a single light-emitting unit, LED chips are all adjacent to each other, thereby optimizing a color mixing effect of various colors and improving the display effect of the display module and the electronic device.

### Embodiment 13

In an existing LED display screen, a bound edge is made on the periphery of the screen body, and then one work state indicating lamp is arranged on the bound edge, to indicate a work state of the LED display screen. However, in the LED display screen arranged in this way, the work state indicated by the indicating lamp represents the work state of the entire screen body, so that when the display screen is in a debugging stage or is used, a work state of each light-emitting unit in the display screen cannot be learned quickly, immediately, and accurately. Therefore, when the display screen is abnormal, an abnormal light-emitting unit cannot be precisely positioned, and then cannot be precisely maintained at a fixed position. To resolve this technical problem, this embodiment provides a display module, and this embodiment may be individually implemented independently of other embodiments.

An exemplary display module provided in this embodiment is shown in FIG. 14-1. The display module includes a packaging unit P, and the packaging unit P includes a substrate 113, a packaging layer 3, and a plurality of light-emitting units 213 arranged in a display region 1131 on a top surface of the substrate. For the light-emitting units 213 in this embodiment, reference may be made to, but not limited to, the light-emitting units shown in the foregoing embodiments. The covering, by the packaging layer 3, the light-emitting units 213 may include completely covering both the top surface of the substrate and the light-emitting units 213, or may include covering only the light-emitting units 213 on the top surface of the substrate. A specific implementation is not limited herein. The display module further includes an indicating unit 9, the indicating unit 9 is arranged on a side of a back surface of the substrate and located in a region corresponding to the display region 1131, and the indicating unit 9 may include one indicating lamp 61 or may include a plurality of indicating lamps 61, whose specific quantity is not limited herein. Preferably, in some examples, the quantity of indicating lamps 61 is greater than or equal to 1 and less than or equal to 20 in one display module, or is greater than or equal to 1 and less than or equal to 200 in one display screen. The indicating unit 9 in this embodiment includes only one indicating lamp 61, a region on the substrate 113 corresponding to the indicating unit 9 is a light-transmitting region 1132, and light emitted by the indicating unit 9 is transmitted through the light-transmitting region 1132 and is emitted from the display region 1131, to indicate a state of the light-emitting unit 213.

It should be noted that each light-emitting unit 213 in this embodiment includes a plurality of LED chips 2131. For example, as shown in FIG. 14-2, the display module includes two light-emitting units 213 and two indicating units 9, each light-emitting unit 213 includes 5 (far greater than 5 or less than 5 in an actual product) LED chips 2131, and each indicating unit 9 is located on a side of a back surface of the substrate and located in a region corresponding to a display region 1131. It should be noted that an indicating lamp 61 in the indicating unit 9 is also provided with an LED chip in a corresponding region on the display region 1131, so that pictures displayed by the display screen are more complete and continuous, to improve use satisfaction of a user.

It should be noted that in this embodiment, the indicating unit 9 may emit light for indication immediately when it is detected that a light-emitting unit 213 is abnormal, or may emit light after a light-emitting unit 213 is abnormal and then is off and on standby. When the indicating unit 9 automatically emits light may be set according to an actual case and a requirement, which is not limited herein. The setting when the indicating unit 9 emits light for indication can avoid a case that light emitted by the indicating unit 9 causes interference to use of the user when maintenance is not facilitated because of a special factor during use. For example, when an important conference is held using the display screen, if one light-emitting unit 213 is abnormal, the user maintains the light-emitting unit after the end of the conference for the sake of continuity of the conference.

In some examples, control of the indicating unit 9 such as on/off or luminance regulation may be manually set by the user, or may be automatically set by automatically monitoring a current use environment. For example, when an important conference is held using the display screen, if some light-emitting units 213 are abnormal, after indicating units 9 corresponding to the abnormal light-emitting units 213 emit light, the user may manually turn off the indicating units or reduce luminance of the indicating units for the sake of continuity of the conference, to prevent the indicating units from affecting continuity of the conference and causing interference to the user visually. Certainly, the indicating units 9 may alternatively be manually turned on/off or have luminance manually regulated during debugging. For example, during debugging, when display modules are debugged, when one display module is considered abnormal, an indicating unit 9 of the display module may be turned on, to indicate that the display module is abnormal. In this embodiment, the indicating unit 9 may differently indicate different abnormality types in different light-emitting indicating manners (including, but not limited to, light emission colors, illumination manners, and the like), so that the user can more quickly identify an abnormality type during maintenance and perform maintenance, to improve maintenance efficiency.

In some examples of this embodiment, the display module further includes an acquisition control device, used for acquiring a parameter of a light-emitting unit and controlling an indicating unit to emit light when it is determined according to the acquired parameter that the light-emitting unit satisfies a preset indicating condition. The parameter may be a work parameter representing a work state, may be an environment parameter representing an environment state of an environment, or may be a combination of a work parameter representing a work state and an environment parameter representing an environment state of an environment, which may be selected by a person skilled in the art according to an actual case and a requirement. It should be noted that a specific structure of the acquisition control device is not shown in this embodiment, and includes, but not limited to, being integrated in the display module or being externally connected to the display module.

For example, one individual acquisition control platform may be arranged outside the display module and connected to the display module, and by using the externally connected acquisition control platform, the user may acquire data of the display module and control an indicating unit in the display module remotely. A specific setting manner may be set by a person skilled in the art according to an actual case and a requirement, and is not limited herein.

In some examples, the acquisition control device includes an acquisition module and a control module. When a preset indicating condition is that a light-emitting unit is abnormal, the acquisition module is used for acquiring a parameter of the light-emitting unit; and when it is determined according to the parameter that the light-emitting unit is abnormal, the control module is used for controlling an indicating unit to emit light. It should be noted that the preset indicating condition includes that a light-emitting unit is abnormal or normal, and may be that the control module controls an indicating unit to emit light when the light-emitting unit is abnormal, or may be that the control module controls an indicating unit to emit light when the light-emitting unit is normal. The indicating unit may emit light when the display screen is working, or may emit light when the display screen is off and on standby.

For example, during use or debugging, assuming that a parameter acquired by the acquisition module is only a work voltage of a light-emitting unit and a normal voltage range of the light-emitting unit is greater than or equal to 1.2 V and less than or equal to 1.5 V, the acquisition module (for example, a voltage sensor) acquires a current work voltage of the light-emitting unit that is 1 V, the acquisition module sends information about the acquired work voltage to the control module (for example, a control card), and the control module then determines according to the received information about the work voltage of 1 V that the work voltage of the light-emitting unit is not in the normal value range. In this case, the control module determines that the light-emitting unit has voltage abnormality, and the control module automatically controls the indicating unit to emit light, to indicate that a voltage state of the display unit is voltage abnormality. It should be noted that the control module may alternatively include, but not limited to, being installed on a terminal (for example, a computer) in the form of software, and buttons in a one-to-one correspondence with indicating units are set on the software. If an indicating unit needs to be controlled to emit light, only a button corresponding to the indicating unit on the software of the computer needs to be manually clicked. For another example, during use or debugging, assuming that parameters acquired by the acquisition module are a work voltage of a light-emitting unit and an environment temperature of an environment, a normal work voltage range of the light-emitting unit is greater than or equal to 1.2 V and less than or equal to 1.5 V, and a normal range of environment temperatures of the environment is greater than or equal to 0° and less than or equal to 40°, the acquisition module acquires a current work voltage of the light-emitting unit and an environment temperature of the environment (for example, the work voltage is 1.3 V, and the temperature of the environment is) 60°, the acquisition module sends the acquired work voltage and environment temperature of the environment to the control module, and the control module then determines according to the received work voltage of 1.3 V and the environment temperature of 60° of the environment that the work voltage of the light-emitting unit is in the normal value range and the environment temperature of the environment is not in the normal value range. Because the environment temperature of the environment is abnormal, the control module controls a corresponding indicating unit in a display region of the light-emitting unit to emit light, to indicate that the light-emitting unit has temperature abnormality. It should be noted that the temperature may alternatively be a work temperature, which may be set by a person skilled in the art according to an actual case and a requirement, and is not limited in the present invention. Through the foregoing solution, when the indicating unit emits light, the user may quickly and immediately view the light directly from the top surface of the light-emitting unit, to improve maintenance efficiency, and when the indicating unit does not emit light, the indicating unit is hidden under the light-emitting unit, without affecting its aesthetics and the display effect of the light-emitting unit.

It should be noted that the acquisition module may include, but not limited to, a voltage sensor, a current sensor, a temperature sensor, and the like, and may further include, for example, a humidity sensor, a signal on-off sensor, and the like. Certainly, the acquisition module may alternatively integrate functions of sensors for acquiring required parameters. In addition, the acquisition module may acquire the parameters when the light-emitting unit is working or when the light-emitting unit is off and on standby. Certainly, the arranging the sensors may include, but not limited to, arranging some sensors outside the display module. For example, the voltage sensor is arranged outside the display module. During debugging, when it is determined through an external mobile terminal (a computer, a mobile phone, or the like) according to a voltage parameter acquired by the voltage sensor arranged outside the display module that the acquired voltage parameter is not in the normal voltage range, the indicating unit may be controlled to emit light, to indicate that its work state is voltage abnormality, to debug each light-emitting unit. The acquisition module may be set by a person skilled in the art according to an actual case and a requirement and is not limited herein. In addition, the control module may include, but not limited to, a control card, a controller, and the like, as long as the control module can determine the acquired parameter information and control the indicating lamp to emit light. A specific application device of the control module may be selected by a person skilled in the art according to an actual case and a requirement. It should be noted that the acquisition module may be, but not limited to, integrated in the control module. For example, the acquisition module may alternatively be individually arranged in the display module together with the control module. Preferably, the acquisition module of this embodiment is integrated in the control module, so that the structure of the display module is more exquisite and compact, to adapt to more use environments and requirements.

In some examples, the acquisition control device further includes a storage module. The storage module stores a correspondence table of correspondences between abnormality types and light-emitting manners, where the correspondence table is used for determining an abnormality type of a light-emitting unit when it is determined according to a parameter that the light-emitting unit is abnormal, obtaining, through matching, a corresponding target light-emitting manner according to the abnormality type and the correspondence table, and controlling an indicating unit to emit light according to the target light-emitting manner. It should be noted that the storage module may be integrated in the acquisition control device or may be independently arranged, and may be, for example, a storage device such as an external USB flash drive or a storage-enabled mobile terminal, whose specific existence form may be set by a person skilled in the art according to an actual case and a requirement and is not limited in the present invention as long as the specific existence form can store the correspondence table.

It should be noted that the correspondence table of correspondences between abnormality types and light-emitting manners that is stored in the storage module is shown in Table 2, where the table may be stored in the storage module of the acquisition control device in advance, or may be stored in an external device and uploaded to the storage module by connecting to the external device during use, which may be set by a person skilled in the art according to an actual case and a requirement and is not limited herein.

TABLE 2

| Abnormality type | Light-emitting manner |
|---|---|
| Voltage abnormality | Constantly-on red light |
| Current abnormality | Constantly-on blue light |
| Temperature abnormality | Flashing yellow light 30 times/min |
| Humidity abnormality | Flashing yellow light 60 times/min |
| Signal on-off abnormality | Flashing red light 60 times/min |
| Networking state abnormality | Green light with constantly-on |
| | luminance of 20 |
| LED lamp conduction abnormality | Green light with constantly-on |
| | luminance of 100 |
| . . . | . . . |

It should be noted that abnormality types may correspond to, but not limited to, different light-emitting manners. For example, abnormality types may alternatively correspond to the same light-emitting manner. For example, Table 3 shows another correspondence table between abnormality types and light-emitting manners. Regardless of an abnormality type, light is emitted in a light-emitting manner of constantly-on red light. Certainly, the correspondence table may further include, but not limited to, a case that different abnormality types correspond to light-emitting manners with different colors, different frequencies, or different luminance, as long as the case can correctly correspond to a relationship between an abnormality type and a light-emitting manner, which may be set according to an actual case and a requirement and is not limited herein.

TABLE 3

| Abnormality type | Light-emitting manner |
|---|---|
| Voltage abnormality | Constantly-on red light |
| Current abnormality | Constantly-on red light |
| Temperature abnormality | Constantly-on red light |
| Humidity abnormality | Constantly-on red light |
| Signal on-off abnormality | Constantly-on red light |
| Networking state abnormality | Constantly-on red light |
| LED lamp conduction abnormality | Constantly-on red light |
| . . . | . . . |

It should be noted that in some embodiments, the correspondence table may alternatively include, but not limited to, parameter types, parameter abnormality standards, and the like. For example, Table 4 shows a correspondence table between parameter types, parameter abnormality standards, abnormality types, and light-emitting manners, and Table 4 shows only a case of acquiring one parameter type. For example, when a voltage parameter is acquired, whether the acquired voltage parameter falls within a parameter abnormality standard range is determined. If the acquired voltage parameter falls within the parameter abnormality standard range, it may be determined that the light-emitting unit has voltage abnormality, so that an indicating unit is constantly on and in red light, to remind the user that the light-emitting unit is abnormal. Certainly, a plurality of parameters may alternatively be acquired simultaneously. After it is determined that at least one of the acquired plurality of parameters falls within the parameter abnormality standard range, it may be, but not limited to, necessary to determine an abnormality type, and then control an indicating unit to, but not limited to, be constantly on and in red light. For example, an indicating unit is directly controlled to flash in red light or be constantly on and in blue light, and it is not necessary to determine an abnormality type of the indicating unit. A specific implementation may be set by a person skilled in the art according to an actual case and a requirement and is not limited herein.

TABLE 4

| | Parameter | | |
|---|---|---|---|
| Parameter | abnormality | Abnormality | Light-emitting |
| type | standard | type | manner |
| Voltage | 0 V to 0.5 V | Voltage | Constantly-on red |
| | | abnormality | light |
| Current | 0 A to 0.1 A | Current | Constantly-on red |
| | | abnormality | light |
| Temperature | 80° C. to 100° C. | Temperature | Constantly-on red |
| | | abnormality | light |
| . . . | . . . | . . . | . . . |
| Signal on-off | Signal off | Signal on-off | Flashing red light |
| | | abnormality | |
| Networking | Networking off | Networking state | Constantly-on |
| state | | abnormality | blue light |
| . . . | . . . | . . . | . . . |

In some examples, one display module may include, but not limited to, a plurality of light-emitting units 213. For example, FIG. 14-3 is a schematic structural diagram of still another display module. The display module includes a light-emitting unit 21301, a light-emitting unit 21302, and a light-emitting unit 21303. It should be noted that in the display module, an indicating unit 901 is arranged corresponding to the light-emitting unit 21301 and the light-emitting unit 21302, and an indicating unit 902 is arranged corresponding to the light-emitting unit 21303. Each light-emitting unit may include, but not limited to, a different quantity of light-emitting chips, or each light-emitting unit may include the same quantity of light-emitting chips. It may be understood that each indicating unit 9 is, but not limited to, arranged corresponding to a plurality of light-emitting units 213. For example, FIG. 14-4 is a schematic structural diagram of yet another display module. An indicating unit 901 is arranged corresponding to a light-emitting unit 21301 and a light-emitting unit 21302, and an indicating unit 902 is arranged corresponding to a light-emitting unit 21303 and a light-emitting unit 21304. Certainly, the light-emitting unit 21301, the light-emitting unit 21302, the light-emitting unit 21303, and the light-emitting unit 21304 may alternatively be arranged corresponding to the indicating unit 9. For example, FIG. 14-5 is a schematic structural diagram of yet another display module. In some examples, for example, during debugging, one indicating unit may be connected to a plurality of light-emitting units. Assuming that one indicating unit corresponds to three light-emitting units, when the first light-emitting unit is normal during debugging, the indicating unit does not emit light; when the second light-emitting unit is abnormal during debugging, the indicating unit emits light; and when the third light-emitting unit is normal during debugging, the indicating unit does not emit light. It should be noted that a correspondence between quantities of light-emitting units and indicating units may be set by a person skilled in the art according to an actual case and a requirement.

In some examples, FIG. 14-6 shows a display module, a light-transmitting region 1132 has a blind hole 92 extending from a back surface of a substrate to a top surface of the substrate, an indicating unit 9 is arranged toward the blind hole 92, the blind hole 92 has a depth that is greater than or equal to 0 and less than or equal to any depth of the substrate 113 along the thickness, and light emitted by the indicating unit 9 is emitted from a display region 1131 through the light-transmitting region 1132. The shape of the light-transmitting region may include, but not limited to, a square, a rectangle, and a circle, and may further include, for example, a trapezoidal, a rhombus, a triangle, a straight line, and a polygon. FIG. 14-7 is a cross-sectional view of another display module. It should be noted that the blind hole may be any shape and size as long as the blind hole can thin the thickness of the region of the substrate 113 and improve light transmission performance, which may be set by a person skilled in the art according to an actual case and a requirement and is not limited herein. Preferably, for example, FIG. 14-8 is a schematic structural diagram of a blind hole of a substrate according to this embodiment. In this embodiment, the blind hole 92 is set to be circular, and has a pore size of 5 mm and a depth that is 70% of the thickness of a board material, thereby reducing the thickness of a light-transmitting region 1132 located corresponding to a display region on a side of a back surface of the substrate, and improving the light transmittance of the light-transmitting region 1132, so that a user can more clearly view a light-emitting manner of an indicating lamp from the top surface of a display screen.

In some examples, the substrate 113 is a glass backplane or a PCB board, and the light-transmitting region is a clearance region in which no wiring or pixel is arranged. It should be noted that the light-transmitting region may be made of a translucent material or a fully transparent material, and the region may alternatively be a clearance region in which few wirings or no wiring is arranged, to achieve a better light-transmitting effect. Certainly, no copper sheet or paint layer may alternatively be arranged on a surface of the substrate 113 in the region, the light-transmitting region may alternatively include a light-transmitting layer arranged on the top surface of the backplane corresponding to the indicating unit 9 and the display module, and a specific arrangement manner is not limited herein. The light-transmitting region may be set by a person skilled in the art according to an actual case and a requirement as long as the light emitted by the indicating unit 9 can be emitted from the display module.

In the display module in this embodiment, the display region is arranged on the top surface of the substrate, the light-emitting units are arranged in the display region, the indicating units are arranged on a side of the back surface of the substrate and located in a region corresponding to the display region, and the acquisition control device acquires a parameter of a light-emitting unit. The parameters include at least one of a work parameter representing a work state of the light-emitting unit and an environment parameter representing an environment state of an environment. When it is determined according to the parameter that the light-emitting unit satisfies a preset indicating condition, an indicating unit is controlled to emit light, and the light is emitted from the display region through a light-transmitting region on the substrate corresponding to the indicating unit, to indicate a state of the light-emitting unit. Therefore, the user can quickly and immediately learn a work state of each light-emitting unit from the top surface of the display screen, to resolve the problem of the existing LED display screen that a work state of a light-emitting unit and/or an environment state of an environment cannot be quickly, immediately, and accurately learned and an abnormal light-emitting unit cannot be precisely positioned and precisely maintained in a fixed position, thereby improving maintenance precision and use satisfaction of the user. A work state of each light-emitting unit and/or an environment state of an environment can be quickly and immediately learned from the top surface of the display screen, and therefore does not need to be monitored using software, thereby improving convenience, immediacy, and use satisfaction of the user.

This embodiment further provides a control method for a display module. The control method includes, but not limited to:

Step a22: acquire a parameter of a light-emitting unit. The parameters include at least one of a work parameter representing a work state of the light-emitting unit and an environment parameter representing a state of an environment.

It should be noted that in actual application, a device for acquiring the parameter of the light-emitting unit may include, but not limited to, an acquisition module, or may be, for example, a sensor with a parameter acquisition function. The acquisition device may be selected by a person skilled in the art according to an actual case and a requirement. In addition, the parameter may include, but not limited to, at least one of a voltage, a current, a temperature, a humidity, signal on-off, a networking state, and an LED lamp conduction status. For example, the parameter may include only a voltage, may include only a current, or may include only a temperature, and certainly may alternatively include each of a voltage, a current, and a temperature.

Step b22: determine, according to the parameter, whether the display unit satisfies a preset indicating condition.

It should be noted that the preset indicating condition includes that the light-emitting unit is abnormal or normal, and the controlling the indicating unit to emit light may include, but not limited to, controlling the indicating unit to emit light when the light-emitting unit is abnormal or, for example, when the light-emitting unit is normal, which may be set by a person skilled in the art according to an actual case and a requirement and is not limited herein. Preferably, when at least two parameters are acquired and whether the light-emitting unit satisfies the preset indicating condition is determined, it is determined that the light-emitting unit satisfies the preset indicating condition only if all the acquired parameters satisfy the preset condition. If one parameter does not satisfy the preset condition, the light-emitting unit does not satisfy the preset condition. Such an arrangement manner can better avoid a case that when a light-emitting unit is abnormal because one parameter is abnormal, the light-emitting unit is not detected, thereby improving accuracy and precision of the detection and improving experience satisfaction of the user.

Step c22: control, when it is determined according to the parameter that the light-emitting unit satisfies the preset indicating condition, the indicating unit to emit light.

In some examples, when the preset indicating condition is that the light-emitting unit is abnormal, and it is determined according to the acquired parameter that the light-emitting unit is abnormal, a corresponding target light-emitting manner is obtained through matching according to an abnormality type and a preset correspondence table of correspondences between abnormality types and light-emitting manners, and then the indicating unit is controlled to emit light according to the target light-emitting manner.

In some examples, abnormality types in the correspondence table include, but not limited to, at least one of a voltage abnormality, a current abnormality, a temperature abnormality, a humidity abnormality, a signal on-off abnormality, a networking state abnormality, and an LED lamp conduction abnormality, and light-emitting manners in the correspondence table include, but not limited to, at least one of different colors, different frequencies, and different luminance. It may be understood that abnormality types and light-emitting manners may flexibly correspond to each other. A specific implementation may be set by a person skilled in the art according to an actual case and a requirement and is not limited herein. It should be noted that the correspondence table may be stored in the storage module of the acquisition control device in advance, or may be uploaded through an external device. A specific implementation may be set by a person skilled in the art according to an actual case and a requirement.

In the control method for a display module provided in this embodiment, a parameter of a light-emitting unit is acquired, where the parameters include at least one of a work parameter representing a work state of the light-emitting unit and an environment parameter representing a state of an environment; whether the light-emitting unit satisfies a preset indicating condition is determined according to the parameter; and when it is determined according to the parameter that the light-emitting unit satisfies the preset indicating condition, the indicating unit is controlled to emit light. In the display module in this embodiment, when the parameter of the light-emitting unit satisfies the preset indicating condition, an indicating unit corresponding to the light-emitting unit is controlled to emit light emitted by the light-emitting unit from the display region through the light-transmitting region, to resolve the problem of the existing LED display screen that a work state of one or more light-emitting units and/or a state of an environment cannot be quickly, immediately, and accurately learned and an abnormal light-emitting unit cannot be precisely positioned and precisely maintained in a fixed position, thereby improving maintenance precision, maintenance efficiency, and use satisfaction of the user.

This embodiment provides a display screen. The display screen includes the foregoing display module. Preferably, in this embodiment, the display screen includes 4 display modules arranged in a 2×2 arrangement manner. FIG. 14-9 is a schematic structural diagram of a display screen. In FIG. 14-9, G represents a top surface of the display screen, and all light-emitting units of each display module 600 correspond to one indicating unit. Therefore, when the display screen is working, if a light-emitting unit of one display module 600 is abnormal, a corresponding indicating unit is controlled to emit light, and a user can quickly and immediately view the light from the top surface of the display screen. Certainly, when the display screen is debugged, light emitted by an indicating unit corresponding to each display module 600 can also be viewed quickly and immediately from the top surface G of the display screen. For example, during debugging, if it is found through debugging that one display module 600 is abnormal, an indicating unit corresponding to the display module 600 emits light, and a debugging worker performs targeted maintenance according to the display module of 600 that emits light, to resolve the problem in the existing technology that a work state of one or more display modules cannot be quickly and immediately learned, thereby improving precision of the maintenance and use satisfaction of the user. In addition, the indicating unit is further integrated together with the display module in the display screen, so that the appearance is concise and aesthetic.

FIG. 14-10 is a schematic structural diagram of another display screen, which includes a plurality of display modules 600. In the drawing, G represents a top surface of the display screen, and each display module 600 includes a plurality of light-emitting units and a plurality of indicating units. It can be learned that the quantity of display modules in the display screen, an arrangement manner of the display modules, the quantities of light-emitting units and indicating units included in each display module, and an arrangement manner of display units in each display module may be set by a person skilled in the art according to an actual case and a requirement and are not limited herein.

### Embodiment 14

When an LED chip is soldered onto a substrate, a used tin solder paste becomes silver after being melted and covers a surface of a solder pad, to form a silver surface. For this problem, in the related technology, after the LED chip is soldered, black ink is printed on the silver surface using an ink-jet printing process. However, because a used ink material has extremely low viscosity (good fluidity), an ink climbing phenomenon occurs (that is, the ink climbs toward a side surface of the LED chip) after the ink is printed onto the surface of the substrate and climbs onto an upper surface of the LED chip (that is, a light-emitting surface of the LED chip), thereby covering the upper surface of the LED chip, which affects light emission of the LED chip. For this problem, this embodiment provides a display module with a structure, to effectively avoid or as much as possible reduce a case that ink climbs onto the upper surface of the LED chip. In addition, this embodiment may be individually implemented independently of other embodiments.

As shown in FIG. 15-1 to FIG. 15-5, the display module provided in this embodiment includes a substrate 114, and a plurality of light-emitting units 214 arranged on the substrate 114. A light-emitting unit 214 includes at least one LED chip. It should be understood that for the light-emitting units 214 and the substrate 114 in this embodiment, reference may be made to, but not limited to, the foregoing embodiments. Details are not described herein again. The display module further includes an ink layer 316 arranged between the light-emitting units 214. The ink layer 316 is formed by ink, and includes a first portion 3161 (in this example, the first portion 3161 is a relatively flat part, and in another example, the first portion may alternatively be a concave surface, a convex surface, or a rough surface), and a second portion 3162 connected to the first portion 3161. The second portion 3162 is located around the light-emitting unit 214 and extends from the first portion 3161 toward the top of the light-emitting unit 214 (that is, a side of the light-emitting unit 214 far away from the substrate 114), the second portion 3162 is higher than the first portion 3161, and compared with the first portion 3161, the second portion 3162 is closer to the light-emitting unit 214. In this embodiment, a packaging layer includes light-transmitting cladding units 317, the light-transmitting cladding units 317 are in a one-to-one correspondence with the light-emitting units 214, and are used for preventing the second portion 3162 from crossing right above the light-emitting units 214, and the light-transmitting cladding unit 317 covers a light-emitting surface of the light-emitting unit 214 (that is, an upper surface of the light-emitting unit 214). Specifically, the light-transmitting cladding unit 317 may cover a light-emitting surface of an LED chip included in the light-emitting unit 214 (which is a surface of the LED chip far away from the substrate, and may also be referred to as an upper surface of the LED chip). The ink has extremely low viscosity and good fluidity, and therefore is prone to climbing along a side surface of the LED chip. In this embodiment, there is a height difference between the light-transmitting cladding unit 317 and the ink layer 316 to prevent the ink from climbing. For example, the height of the ink layer 316 is not greater than the height of the light-transmitting cladding unit 317. Because the light-transmitting cladding unit 317 covers the upper surface of the LED chip, and the top of the ink layer 316 is lower than the upper surface of the LED chip, the ink can be prevented from climbing to the upper surface of the LED chip during climbing, thereby avoiding masking or partially masking the upper surface of the LED chip (ink climbing phenomenon) from causing light shielding, the practicability is good, and the effect of preventing the ink from climbing is good. In addition, the light-transmitting cladding unit 317 has a long transparent light path, to facilitate reduction of luminance loss of the LED chip. It is only necessary to cover the upper surface of the light-emitting unit 214 with the light-transmitting cladding unit 317 in advance before the ink layer 316 is arranged, the structure is simple, and the manufacturing costs are low, to facilitate wide application and market promotion.

In some embodiments, the light-transmitting cladding unit 317 includes a front light-transmitting layer 3171 located on an upper surface of the light-emitting unit 214 and a side light-transmitting layer 3172 located on a side surface of the light-emitting unit 214. In some examples, the LED chip may be a face-up chip, the light-transmitting cladding unit 317 may be formed through printing of an ink-jet printing process, a light-transmitting material, but not limited thereto, may be used as a printing material, and ink is sprayed onto the top of the LED chip to form the front light-transmitting layer 3171. The front light-transmitting layer 3171 is arranged adjacent to the ink layer 316 (as shown in FIG. 15-1 and FIG. 15-2), and the front light-transmitting layer 3171 may be connected to the ink layer 316 (as shown in FIG. 15-3 and FIG. 15-4). The printing material has fluidity and therefore can flow to a peripheral side of the LED chip to form the side light-transmitting layer 3172, and the side light-transmitting layer 3172 may also be formed through printing of the ink-jet printing technology. In another example, the LED chip may alternatively be a flip chip. The light-transmitting cladding unit 317 may be dome-shaped; and the height of the light-transmitting cladding unit 317 is less than the width of the light-transmitting cladding unit 317, to facilitate material saving. Certainly, the shape of the light-transmitting cladding unit 317 may not be limited, and the top of the light-transmitting cladding unit 317 may be a plane or be in another shape.

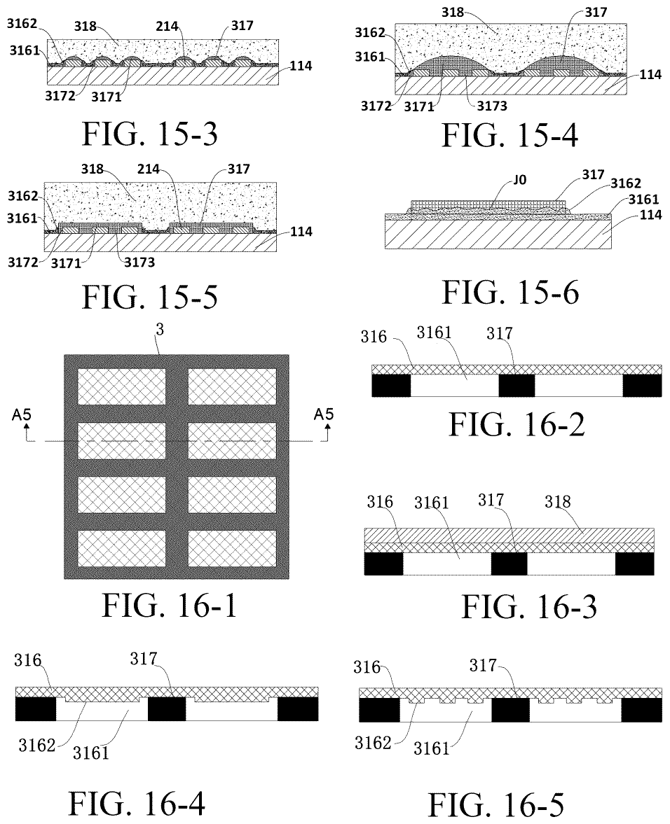

In some embodiments, the second portion 3162 is located under the upper surface of the light-emitting unit 214. For example, as shown in FIG. 15-1 to FIG. 15-5, the top of the ink layer 316 is lower than the top of the LED chip. For example, when the LED chip is a face-up chip, the top of the ink layer 316 is lower than the top of the LED chip, to further prevent ink of the ink layer 316 from flowing to the light-emitting surface of the LED chip; and the top of the second portion 3162 is not higher than the upper surface of the light-emitting unit 214, to prevent the upper surface of the light-emitting unit 214 from being blocked by the second portion 3162 and facilitate light emission from the side surface of the LED chip. During actual process implementation, according to a process implementation status, all of the second portion 3162 may not be required to be under the upper surface of the light-emitting unit 214, and requirements can be satisfied as long as a major part (for example, more than 80%) is located under the upper surface of the light-emitting unit 214. In some embodiments, the formed ink layer 316 is black, and the display module may be used for, but not limited to, a direct view product. For example, the ink layer 316 may be formed by, but not limited to, black ink through printing of an ink-jet printing device, to improve the contrast. A curved line is formed at a junction of the second portion 3162 and the side surface of the light-emitting unit 214 or a junction J0 of the second portion 3162 and the light-transmitting cladding unit 317, as shown in FIG. 15-6. The curved line formed here is an irregular curved line in some examples; and certainly a regular curved line may alternatively be formed in some other examples.

In some application scenarios, the ink layer 316 is arranged in a seam between two adjacent light-emitting units 214 and on the light-emitting units 214 until the edge of the substrate 114, as shown in FIG. 15-1 and FIG. 15-2. The thickness of the ink layer 316 ranges from 3 μm to 120 μm. In this embodiment, the thickness of the ink layer 316 may be controlled by controlling, but not limited to, an adhesive output amount and/or the number of jet printing times of a printing nozzle. For example, in some specific application examples, the thickness of the ink layer 316 may be set to range from 5 μm to 15 μm, thereby reducing use of the ink material based on ensuring black chrominance.

In some embodiments, the packaging layer of the display module may further include a light-transmitting protection layer 318 arranged on the light-transmitting cladding unit 317 and the ink layer 316, and the light-transmitting protection layer 318 may be manufactured through, but not limited to, adhesive dispensing, mold-pressing, and printing. The thickness of the light-transmitting protection layer 318 ranges from 200 μm to 400 μm. In some examples, the thickness of the light-transmitting cladding unit 317 ranges from 30 μm to 100 μm. For example, the thickness of the light-transmitting cladding unit 317 may range from 30 μm to 80 μm, and may be specifically, but not limited to, 30 μm, 35 μm, 40 μm, 50 μm, or 70 μm. In specific application, when the display module is applied to a direct view product, as shown in FIG. 15-4 and FIG. 15-5, the light-emitting unit 214 may include, but not limited to, three LED chips that emit red light, blue light, and green light respectively, the light-transmitting cladding unit 317 may include a light-transmitting protection layer 3173 arranged in a seam between adjacent LED chips in the light-emitting unit 214, and the front light-transmitting layer 3171 is connected to the light-transmitting protection layer 3173. The thickness of the light-transmitting cladding unit 317 may be controlled by controlling an adhesive output amount or the number of jet printing times of an ink-jet printing nozzle. In this embodiment, the thickness of the light-transmitting cladding unit 317 is 35 μm.

In some examples, the material of the light-transmitting cladding unit 317 may be, but not limited to, an epoxy resin material or a silicon resin material; and the material of the ink layer 316 may be, but not limited to, an epoxy resin material or a silicon resin material. In this embodiment, the material of the light-transmitting cladding unit 317 may be the same as the material of the ink layer 316, to facilitate cost reduction.

In some other examples, the hydrophilicity of the light-transmitting cladding unit 317 is different from the hydrophilicity of the ink layer 316. For example, the light-transmitting cladding unit 317 may have a hydrophilic factor added to have hydrophilicity, the ink layer 316 may have a hydrophobic factor added to have hydrophobicity, and a difference between the two in hydrophilicity can be used to further effectively avoid a case that the ink crosses the light-transmitting cladding unit 317 to mask or partially mask the upper surface of the LED chip. In some application scenarios, the hydrophilic factor may be, but not limited to, molecules carrying a polar group (polar molecules), and has large affinity with water, and the hydrophobic factor may be, but not limited to, alkane, grease, fat, and most hydrophobic molecules containing grease (non-polar molecules). The hydrophobic factor and water may repel each other. By setting the light-transmitting cladding unit 317 and the ink layer 316 to be different in hydrophilicity, when ink climbs to the LED chip and encounters the light-transmitting cladding unit 317 located on the LED chip, the ink and the light-transmitting cladding unit do not dissolve each other and repel each other, to effectively prevent the ink from continuing to climb to the upper surface of the light-emitting unit 214 (ink climbing phenomenon), thereby effectively preventing the ink from masking or partially masking the upper surface of the light-emitting unit 214 to affect light emission of the LED chip, the structure is simple, and the costs are low.

This embodiment further provides a manufacturing method for a display module. The manufacturing method may be used for manufacturing a display module shown in the foregoing examples, and the method includes, but not limited to:

Step a23: provide a substrate 114, and arrange a plurality of light-emitting units 214 on the substrate 114.

Step b23: perform ink-jet printing above each of the light-emitting units 214 to form a light-transmitting cladding unit 317, where the formed light-transmitting cladding unit 317 covers an upper surface of the light-emitting unit 214 (that is, a light-emitting surface of the light-emitting unit 214). In some examples, in formed light-transmitting cladding units 317, there is a seam between adjacent light-transmitting cladding units 317, and the seam is in communication with a seam between adjacent light-emitting units 214, to subsequently form an ink layer 316.

Step c23: perform ink-jet printing (through, but not limited to, printing of an ink-jet printing device) along a seam between the light-emitting units 214 on the substrate 114 to form an ink layer 316, where the formed ink layer 316 may be, but not limited to, black, and includes a first portion 3161 and a second portion 3162, the second portion 3162 is connected to the first portion 3161, the second portion 3162 is located around the light-emitting unit 214 and extends from the first portion 3161 toward the top of the light-emitting unit 214, and the light-transmitting cladding unit 317 formed in the previous step can prevent the second portion 3162 from crossing to or flowing to the upper surface of the light-emitting units 214.

Optionally, the manufacturing method for a display module in this embodiment may further include: forming a light-transmitting protection layer 318 above the ink layer 316 and the light-transmitting cladding unit 317. The process of forming light-transmitting protection layer 318 may be, but not limited to, mold-pressing, printing, or adhesive dispensing, which is not limited herein.

### Embodiment 15

When an LED chip is soldered onto a substrate, a used tin solder paste becomes silver after being melted and covers a surface of the solder pad, to form a silver surface. For this problem, in the related technology, a black adhesive layer covering the solder pad is press-fit on the substrate through a press-fitting process, but during the press-fitting, the press-fit black adhesive is extremely prone to remaining on a light-emitting surface of the LED chip, to block light emitted from the light-emitting surface. For this problem, this embodiment provides a display module with a structure and a manufacturing method therefor, to effectively avoid or as much as possible reduce a case that the black adhesive remains on the light-emitting surface of the LED chip. In addition, this embodiment may be individually implemented independently of other embodiments.

In the manufacturing method for a display module provided in this embodiment, before a packaging layer is arranged on a substrate, a manufacturing process for the packaging layer with a structure is further included. An exemplary manufacturing method for a packaging layer is shown in FIG. 16-1 to FIG. 16-5, and includes:

Step a24: provide a packaging layer, where the packaging layer is a light-transmitting adhesive layer.

Step b24: arrange a black adhesive layer on the packaging layer.

Step c24: arrange, on the black adhesive layer, a plurality of windows used for accommodating the LED chips, where each of the arranged windows runs through the black adhesive layer to the packaging layer.

In this embodiment, as shown in FIG. 16-7 and FIG. 16-19, a black adhesive layer 317 is configured to flow toward and fill in an LED chip 215 in a window after the press-fitting, to cover at least a part of a side light-emitting surface 2152 of the LED chip 215, and a packaging layer 316 is configured to cover a light-emitting surface 2151 of the LED chip 215. As shown in FIG. 16-1 to FIG. 16-5, It may be understood that after a window 3161 runs through the black adhesive layer 317 to reach the packaging layer 316, a region that is on a surface of the packaging layer 316 close to the black adhesive layer 317 and corresponds to the window 3161 is exposed. As shown in FIG. 16-6 to FIG. 16-12, after the packaging layer covers the LED chip 215 through the window 3161, the packaging layer covers the top surface of the substrate 115, the black adhesive layer 317 is located between the substrate 115 and the packaging layer 316, the black adhesive layer 317 does not contact the LED chip 215, and the packaging layer 316 is located on the light-emitting surface 2151 of the LED chip 215.

It should be understood that in some examples of this embodiment, the black adhesive layer 317 may be made of a modified epoxy adhesive, and before the press-fitting, the black adhesive layer 317 may be in a solid state or a semi-solid state. Preferably, the black adhesive layer 317 may be in the semi-solid state at a normal temperature. In this embodiment, the press-fitting may be hot-pressing. For example, the black adhesive layer 317 made of the modified epoxy adhesive in the semi-solid state is heated to a range from 50° C. to 60° C., so that the black adhesive layer 317 in the semi-solid state has fluidity under the action of the hot-pressing, the window 3161 is deformed, and the black adhesive on the side wall of the window 3161 flows toward the periphery of the LED chip 215 located in the window 3161, until the side light-emitting surface 2152 of the LED chip 215 is enclosed to complete filling. The heating is stopped after the filling is completed, the black adhesive layer 317 is restored to the normal temperature or another set temperature, and the black adhesive layer 317 stops flowing and is then heated to cure and mold the black adhesive layer 317. For example, the black adhesive layer 317 is heated to a range from 100° C. to 150° C. and cured to complete packaging.

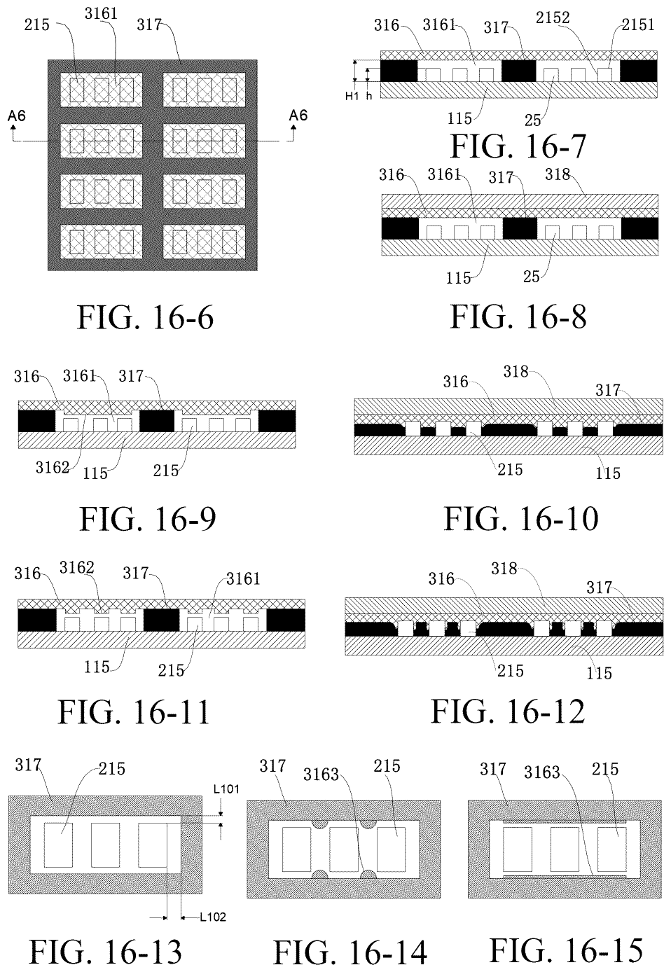

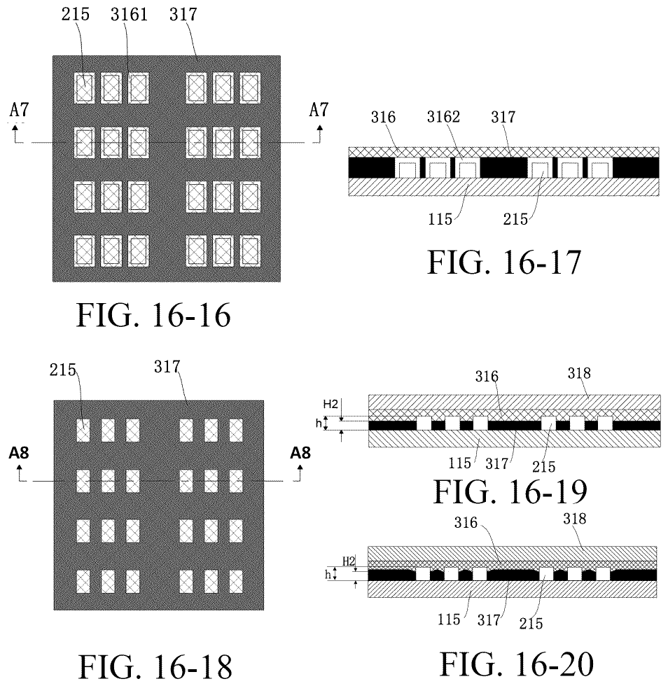

It may be understood that the packaging layer 316 may also be in the solid state, and the packaging layer 316 in the solid state has the hardness reduced under a heating condition, so that during press-fitting, the light-emitting surface 2151 of the LED chip 215 may be pressed into the packaging layer 316. As shown in FIG. 16-19 and FIG. 16-20, after the press-fitting is completed, the thickness of the black adhesive layer 317 is less than the height of the LED chip 215. The packaging layer 316 does not damage the LED chip 215, and the packaging layer 316 is further laminated on the light-emitting surface 2151 of the LED chip 215, to protect the LED chip 215 and prevent the black adhesive layer 317 from being press-fit onto the light-emitting surface 2151 of the LED chip 215. As shown in FIG. 16-8 and FIG. 16-20, when the packaging layer 316 and the black adhesive layer 317 are press-fit on a PCB board, a top surface of an LED chip 5 compresses the packaging layer 316, and the compressed packaging layer 316 may be accumulated toward a side surface of the LED chip 5. In this case, after the press-fitting is completed, on the side surface of the LED chip 5, a part of the packaging layer 316 protrudes toward the bottom of the LED chip 5, which can better prevent the black adhesive layer 317 from extending toward the top surface of the LED chip 215. In some examples, as shown in FIG. 16-8 and FIG. 16-19, if the press-fitting speed is very low and/or the extent to which the LED chip 5 is pressed into the light-transmitting adhesive layer 2 is not large during press-fitting, the light-transmitting adhesive layer on the side surface of the LED chip 5 is compressed to a small extent and does not obviously protrude, and the black adhesive layer on the side surface of the LED chip 5 has good flatness.

In some examples, the window 3161 may be made on the black adhesive layer 317 through exposure and development. In some examples of this embodiment, a layer of film may be first arranged on the black adhesive layer 317. A region on the film corresponding to the window 3161 is an opaque part to form light coverage, and the remaining region of the film is a light-transmitting part. Light illumination is applied to semi-cure or cure a region of the black adhesive layer 317 different from the window 3161, and the window 3161 may be formed by performing wet removing on a part of the black adhesive layer 317 not illuminated by light, that is, the region of the window 3161 with a washing solution. The washing solution in this embodiment may include H₂SO₄ or H₂O₂.

In some examples of this embodiment, as shown in FIG. 16-4 and FIG. 16-5, before the arranging a black adhesive layer 317 on the packaging layer 316, the method may further include:
Arranging a boss 3162 on the packaging layer 316; and

The arranging a black adhesive layer 317 on the packaging layer 316 includes:
Arranging the black adhesive layer 317 on a surface of the packaging layer 316 on which the boss 3162 is arranged, where the boss 3162 is exposed inside of the window.

In this example, a plurality of bosses 3162 may be arranged on the bottom surface of the packaging layer 316. During manufacturing, the bosses 3162 are located in the windows 3161 and correspond to the light-emitting surfaces 2151 of the LED chips 215, and the bottom surface of the packaging layer 316 is a surface close to the black adhesive layer 317. If the height of the black adhesive layer 317 is greater than the height of the LED chips 215 before press-fitting, arrangement of the bosses 3162 can cause the bosses 3162 of the packaging layer 316 to tightly contact the light-emitting surfaces 2151 of the LED chips 215 more quickly during press-fitting, so that the black adhesive layer 317 can be prevented from covering the top of the LED chips 215 during press-fitting, and the black adhesive layer 317 is less prone to remaining on the light-emitting surfaces 2151 of the LED chips 215.

In some implementations, after press-fitting is completed, the bosses 3162 may clothe upper ends of the LED chips 215, that is, upper ends of the light-emitting surface 2151 and the side light-emitting surfaces 2152 of the LED chips 215 tightly contact the packaging layer 316, and the light-emitting surfaces of the LED chips 215 are protected better, and are not polluted by the black adhesive. As shown in FIG. 16-19, after the press-fitting is completed, the height H2 of the black adhesive layer 317 may be less than the height h of the LED chips 215; or after the press-fitting is completed, the height of the black adhesive layer 317 may be equal to the height of the LED chips 215. The light-emitting surfaces 2151 of the LED chips 215 are laminated by the bosses 3162. Therefore, even if the height H2 of the black adhesive layer 317 is equal to the height h of the LED chips 215 after the press-fitting is completed, there is not a case that the black adhesive overflows to the light-emitting surfaces 2151 of the LED chips 215, and normal light emission of the LED chips 215 can still be ensured. Certainly, it can be understood that in this embodiment, the height of the black adhesive layer 317 is not limited thereto after the press-fitting is completed.

In some examples, as shown in FIG. 16-4 and FIG. 16-9, one window 3161 may correspond to one boss 3162, and the boss 3162 may cover light-emitting surfaces 2151 of all LED chips 215 in the corresponding window 3161. During press-fitting, top surfaces of the LED chips 215 compress the boss 3162, and the compressed boss 3162 may be accumulated toward side surfaces of the LED chips 215. After the press-fitting is completed, for a case that the packaging layer 316 covers the LED chips 215, reference may be made to FIG. 16-10. On the side surfaces of the LED chips 215, the packaging layer 316 protrudes toward the bottom of the LED chips 215. In some other examples, as shown in FIG. 16-5 and FIG. 16-11, one window 3161 may correspond to a plurality of bosses 3162, where the bosses 3162 are in a one-to-one correspondence with light-emitting surfaces 2151 of LED chips 215 in the window 3161. During press-fitting, the top surfaces of the LED chips 215 compress the bosses 3162, and the compressed bosses 3162 may be accumulated toward the side surfaces of the LED chips 215. After the press-fitting is completed, a case that the packaging layer covers the LED chips 215 is shown in FIG. 16-12. Because space exists between the bosses, the packaging layer between the LED chips 215 protrudes toward the bottom of the LED chips 215. Because of being compressed by the LED chips 215, the side surface of the packaging layer along the LED chips 215 protrudes toward the bottom of the LED chips 215, which can better prevent the black adhesive layer 317 from extending toward the top surfaces of the LED chips 215.

In some other examples, as shown in FIG. 16-14 and FIG. 16-15, the arranging on the black adhesive layer 317, a plurality of windows 3161 for accommodating the LED chips 215 includes: the window 3161 is a rectangular window, and a protruding portion oriented toward the LED chip 215 is arranged on a side wall on a long side of the rectangular window. When flowing on the black adhesive layer 317, the protruding portion 3163 fills in a gap between the LED chips 215, so that flowing on the black adhesive layer 317 is more even. In some examples, as shown in FIG. 16-15, one protruding portion 3163 may be arranged on a side wall of a long side of one rectangle. In some other examples, as shown in FIG. 16-14, a plurality of protruding portions 3163 may alternatively be arranged on a side wall of a long side of one rectangle, and each protruding portion 3163 corresponds to a gap between the LED chips 215. In this case, after the black adhesive layer 317 is heated, the protruding portions 3163 directly flow to and fill in the gaps between the LED chips 215.

In some examples, as shown in FIG. 16-3, the providing a packaging layer 316 includes: arranging a packaging layer 316 on a bearing member 318. To be specific, in this example, the packaging layer may further include the bearing member 318, and bear the packaging layer 316 and the black adhesive layer 317 through the bearing member 318, to better facilitate manufacturing, preservation, and use of the packaging layer. During manufacturing, the packaging layer 316 may be first manufactured on the bearing member 318 through coating, mold-pressing, or pasting, the packaging layer 316 is cured, and then the black adhesive layer 317 may be arranged on the cured packaging layer 316. A process used for arranging the black adhesive layer 317 on the packaging layer 316 may be flexibly selected. For example, the process may be, but not limited to, coating, silk-screen printing, printing, mold-pressing, or the like. Finally, the window 3161 is made on the black adhesive layer 317. The manufactured packaging layer may be stored in a low temperature environment, for example, an environment in a range from −40° C. to −10° C., and the low temperature environment can reduce activity of chemical ingredients in the adhesive film and extend the storage life of the adhesive film. The adhesive film needs to be unfrozen at a normal temperature before the packaging layer is used for performing packaging, and the black adhesive layer 317 unfrozen at the normal temperature may be in the semi-cured state at the normal temperature. During press-fitting of the packaging, the bearing member 318 may be used as a directly stressed member of the packaging layer, so that during push-down, forces acting on adhesive layers are more even, and deformation of the black adhesive layer 317 is more controllable.

It may be understood that the bearing member 318 in this embodiment may be a transparent substrate or film layer. For example, the transparent substrate may be a glass substrate. In some examples, the bearing member 318 may alternatively be an opaque substrate. However, to prevent the opaque substrate from affecting light emission of the LED chip 215, a layer of release film or release agent may be arranged on the opaque substrate. During packaging, after press-fitting is completed, the opaque substrate may be removed through the arranged release film or release agent.

In this embodiment, to prevent the packaging layer from having an error or being mounted in an opposite direction during alignment, mark points for alignment may be arranged on the packaging layer 316 or the bearing member 318 of the packaging layer. For example, mark points are arranged on opposite corners of the bearing member 318, to facilitate identification during mounting, so that the window of the black adhesive layer 317 is accurately aligned with the LED chip 215.

In the foregoing manufacturing method, the windows are arranged on the black adhesive layer 317. When packaging is performed through the packaging layer, the packaging layer is press-fit on the substrate 115 of the display module, where the black adhesive layer 317 covers the top surface of the substrate 115, and the LED chips 215 on the substrate 115 are located in corresponding windows 3161. In this case, the light-emitting surfaces 2151 of the LED chips 215 and the black adhesive layer 317 do not contact each other. During press-fitting, the black adhesive layer 317 flows toward the peripheries of the LED chips 215, so that the black adhesive layer 317 fills in the peripheries of the LED chips 215, to enclose at least parts of the side light-emitting surfaces 2152 of the LED chips 215. As shown in FIG. 16-18, the black adhesive layer 317 covers a region on the substrate 115 different from the LED chips 215, to cover the silver tin solder paste on the substrate 115, so that purer black is displayed when the display screen is off, to improve the contrast of the display screen. In addition, during manufacturing, the LED chips 215 are directly located in the windows 3161 arranged on the black adhesive layer 317, the black adhesive layer 317 does not contact the light-emitting surfaces 2151 of the LED chips 215 throughout the process, and no black adhesive remains on the light-emitting surfaces 2151 of the LED chips 215, to ensure good light emission of the LED chips 215, so that the display effect of the display module is better. In addition, during manufacturing, the packaging layer 316 covers the light-emitting surfaces 2151 of the LED chips 215, and can protect the light-emitting surfaces 2151 of the LED chips 215.

As shown in FIG. 16-7 to FIG. 16-20, a manufacturing method for a display module provided in this embodiment includes:

Step a25: manufacture a substrate assembly and a packaging layer.

In this embodiment, the packaging layer is manufactured using the foregoing exemplary manufacturing method for a packaging layer. The manufacturing a substrate assembly includes arranging a substrate 115, and arranging a plurality of light-emitting units on a top surface of the substrate 115, where each of the light-emitting units includes at least one LED chip 215.

It may be understood that for the substrate 115 and the light-emitting units in this embodiment, reference may be made to, but not limited to, the foregoing embodiments. Details are not described herein again.

Step b25: cover the top surface of the substrate with the packaging layer, to locate the LED chips in corresponding windows.

After the packaging layer covers the top surface of the substrate 115, a black adhesive layer 317 is located between the substrate 115 and a packaging layer 316. In some examples of this embodiment, as shown in FIG. 16-16 and FIG. 16-17, one window 3161 may correspond to one LED chip 215. Alternatively, in some other examples of this embodiment, as shown in FIG. 16-6 and FIG. 16-7, one window 3161 may alternatively correspond to a plurality of LED chips 215. Specifically, one window 3161 may correspond to one pixel point, and LED chips 215 of one pixel point support emission of red light, green light, and blue light. For example, one pixel point may include three LED chips 215 in red light, green light, and blue light.

Step c25: press-fit the packaging layer and the substrate, to cause the black adhesive layer to flow to and fill in the peripheries of the LED chips.

In this embodiment, before the press-fitting, the thickness of the black adhesive layer 317 is greater than or equal to the height of the LED chips 215, to make it convenient for the black adhesive layer 317 to flow to and fill in the peripheries of the LED chips 215 after the press-fitting. As shown in FIG. 16-7, before the press-fitting, the thickness H1 of the black adhesive layer 317 is greater than the height h of the LED chips 215. In some application scenarios, before the press-fitting, the thickness H1 of the black adhesive layer 317 may alternatively be less than the height h of the LED chips 215. This is not specifically limited in this embodiment.

Step d25: stop press-fitting, where the black adhesive layer encloses at least a part of side light-emitting surfaces of the LED chips, and the packaging layer covers a light-emitting surface of each LED chip.

In this embodiment, the enclosing, by the black adhesive layer 317, at least a part of the side light-emitting surfaces 2152 of the LED chips 215 after the press-fitting can avoid impact from crosstalk between LED chips 215 as much as possible, and improve the contrast. It may be understood that the enclosing at least a part of the side light-emitting surfaces 2152 of the LED chips 215 may be enclosing a part of the side light-emitting surfaces 2152 of the LED chips 215, as shown in FIG. 16-19, where the thickness of the finally cured black adhesive layer 317 is less than the height of the LED chips 215; or may be completely covering the side light-emitting surfaces 2152 of the LED chips 215 to form enclosure. As shown in FIG. 16-20, the packaging layer 316 and the black adhesive layer 317 may alternatively be in curved surface contact with each other in a position close to the side light-emitting surfaces of the LED chips 215. To be specific, when the LED chips 215 are compressed into the packaging layer 316, the packaging layer 316 is compressed to form curved surfaces in nearby regions at upper ends of the LED chips 215. The side surfaces of the curved surfaces along the LED chips 215 protrude toward the bottom of the LED chips 215, which can better prevent the black adhesive layer 317 from extending toward the top surfaces of the LED chips 215, and does not affect light-emitting display of the display module. In addition, the curved surfaces may further form diffuse reflection for external ambient light, to eliminate interference from the external ambient light when the screen of the display apparatus is on, thereby improving the display effect.

In this embodiment, if the thickness of the black adhesive layer 317 is less than the height of the LED chips 215 when press-fitting starts, the black adhesive layer 317 does not contact the top surface of the substrate 115 when the black adhesive layer 317 covers the top surface of the substrate 115. In this case, the packaging layer 316 first contacts the light-emitting surfaces 2151 of the LED chips 215. If the thickness of the black adhesive layer 317 is greater than the height of the LED chips 215 when press-fitting starts, the black adhesive layer 317 first contacts the top surface of the substrate 115 when the black adhesive layer 317 covers the top surface of the substrate 115. After the press-fitting lasts for a specific time, the packaging layer 316 contacts the light-emitting surfaces 2151 of the LED chips 215.

In this embodiment, to achieve an effect that the black adhesive layer 317 well fills in the peripheries of the LED chips 215 and gaps between the LED chips 215 during press-fitting and does not overflow to the light-emitting surfaces 2151 of the LED chips 215 during flowing, in some examples, the thickness of the black adhesive layer 317 after being press-fit and cured, as shown in FIG. 16-19 and FIG. 16-20, that is, the height H2 of the black adhesive layer 317 enclosing the side light-emitting surfaces of the LED chips 215 after the press-fitting is completed, may be ⅔ of the height h of the LED chip 215s, that is, H2=⅔h. In this case, each of the LED chips 215 may have an effective side light-emitting surface with a specific area, and can reduce impact of the black adhesive layer on the luminous efficiency of the LED chips 215. In some application scenarios, after the press-fitting is completed, the height H2 of the black adhesive layer 317 may be greater than ⅔ of the height h of the LED chips 215 or less than ⅔ of the height h of the LED chips 215.

In this embodiment, the shape of the window 3161 may be flexibly set, as long as the shape enables the black adhesive layer 317 to fill between the LED chips 215 during press-fitting. For example, the shape of the window 3161 may be a rectangle or an ellipse. The shape of a rectangle helps the black adhesive layer 317 on a long side flow toward and fill in gaps between adjacent LED chips 215. As shown in FIG. 16-13, before the black adhesive layer 317 is melted, and when the rectangular window correspondingly accommodates a plurality of LED chips 215, a gap between a side wall of the rectangular window and the LED chips 215 along the long side of the rectangle is greater than a gap between the side wall of the rectangular window and the LED chips 215 along a short side of the rectangle. Therefore, the black adhesive layer 317 can flow toward the peripheries of the LED chips 215 and the gaps between the LED chips 215 more evenly. Specifically, if a shortest distance between a side wall on one long side of the rectangular window and side light-emitting surfaces of the LED chips 215 opposite to the side wall on the long side is a first distance L101; a shortest distance between a side wall on the other long side of the rectangular window and side light-emitting surfaces of the LED chips 215 opposite to the side wall on the long side is a second distance, and is preferably equal to the first distance L101; a shortest distance between a side wall on one short side of the rectangular window and side light-emitting surface of the LED chips 215 opposite to the side wall on the short side is a third distance L102, and a shortest distance between a side wall on the other short side of the rectangular window and side light-emitting surfaces of the LED chips 215 opposite to the side wall on the short side is a fourth distance, and is preferably equal to the third distance L102, the gap between the LED chips 215 and the side wall of the rectangular window along the short side of the rectangle is a sum of the first distance and the second distance, that is, two times L101, and the gap between the LED chips 215 and the side wall of the rectangular window along the long side of the rectangle is a sum of the third distance and the fourth distance, that is, two times L102.

It may be understood that to enable the black adhesive layer 317 to better and quickly fill in the gaps between the LED chips 215, hot-pressing may be performed in a vacuum environment, and air between the packaging layer 316 and the substrate 115 may be pumped out in the vacuum environment, to avoid an adverse situation caused because of existence of bubbles.

It should be understood that the foregoing embodiments of the present invention may be each independently implemented, or may be combined and implemented according to some of the embodiments or some technical features in the embodiments. In addition, the application of the present invention is not limited to the foregoing examples. A person of ordinary skill in the art may make improvements or modifications according to the foregoing description, and all of the improvements and modifications should all fall within the protection scope of the attached claims of the present invention.

1.-22. (canceled)

23. A display module, comprising:
a substrate, comprising a chip receiving region and a concave portion extending from the chip receiving region toward a periphery;
a plurality of light-emitting units, each comprising a plurality of light-emitting elements, arranged in the chip receiving region, and electrically connected to the substrate;
a black optical layer, arranged on the substrate and not covering upper surfaces of the plurality of light-emitting units, wherein a surface of the black optical layer comprises uneven microstructures; and
a light-transmitting protection layer, arranged on the black optical layer.

24. The display module according to claim 23, further comprising a transparent adhesive arranged between the black optical layer and a packaging adhesive layer.

25. The display module according to claim 23, further comprising an optical element, arranged on upper surfaces of the light-emitting elements.

26. The display module according to claim 23, wherein each of the light-emitting elements comprises a plurality of LED chips of not entirely identical colors, and the LED chips of each of the light-emitting units are arranged rotationally symmetrically around a rotational symmetry center.

27. The display module according to claim 23, wherein at least one side surface of the substrate is a spliced side surface spliced with a substrate of another display module, a region of the spliced side surface close to a back surface of the substrate is contracted to form an avoidance region, and a region of the spliced side surface close to the top surface of the substrate is used as a spliced region.

28. The display module according to claim 23, wherein a thickness of the black optical layer ranges from 3 μm to 120 μm, and each of black particles of the black optical layer is a carbon partible with a particle diameter less than or equal to 500 nanometers.

29. The display module according to claim 23, wherein a material of the black optical layer is at least one selected from the group consisting of an oxide, a silicide, a nitride, and a composite thereof.

30. An LED light-emitting device, comprising:
a substrate;
a plurality of light-emitting units, each comprising a plurality of light-emitting elements, arranged in the chip receiving region, and electrically connected to the substrate;
a black optical layer, arranged in a gap between the substrate and the plurality of light-emitting units, wherein a height of the black optical layer is less than a height of the light-emitting unit;
an optical element, arranged on light-emitting surfaces of the light-emitting elements and the black optical layer in a completely fitted manner, wherein a surface of the optical element comprises optical microstructures; and
a light-transmitting protection layer, arranged on the optical element.

31. The LED light-emitting device according to claim 30, further comprising a transparent adhesive arranged between the black optical layer and a packaging adhesive layer.

32. The LED light-emitting device according to claim 30, wherein a surface of the black optical layer comprises uneven microstructures.

33. The LED light-emitting device according to claim 30, wherein the optical element covers upper surfaces and side surfaces of the light-emitting elements.

34. The LED light-emitting device according to claim 30, wherein a thickness of the black optical layer ranges from 3 μm to 120 μm.

35. The LED light-emitting device according to claim 30, wherein a height of the light-transmitting protection layer ranges from 200 μm to 400 μm.

36. The LED light-emitting device according to claim 30, wherein each of the light-emitting elements comprises a plurality of LED chips of not entirely identical colors, and the LED chips of each of the light-emitting units are arranged rotationally symmetrically around a rotational symmetry center.

37. An LED display module, comprising:
a substrate;
a plurality of light-emitting units, each comprising a plurality of light-emitting elements, arranged in the chip receiving region, and electrically connected to the substrate;
a black optical layer, arranged in a gap between the substrate and the plurality of light-emitting units;
a light-transmitting protection layer, arranged on the black optical layer and arranged a gap between adjacent ones of the light-emitting units; and
a translucent layer, arranged on the light-transmitting protection layer, wherein the translucent layer comprises black light-blocking units distributed in the translucent layer.

38. The LED display module according to claim 37, wherein the translucent layer comprises micron-sized glass beads, and a volume occupied by the micron-sized glass beads ranges from 50% to 70% of the volume of the translucent layer.

39. The LED display module according to claim 37, wherein a surface of the black optical layer comprises uneven microstructures.

40. The LED display module according to claim 37, further comprising a reflection layer, wherein the reflection layer comprises reflection particles, and the reflection layer is arranged between the translucent layer and the light-transmitting protection layer.

41. The LED display module according to claim 37, wherein a thickness of the black optical layer ranges from 3 μm to 120 μm.

42. The LED display module according to claim 37, wherein each of the light-emitting elements comprises a plurality of LED chips of not entirely identical colors, and the LED chips of each of the light-emitting units are arranged rotationally symmetrically around a rotational symmetry center.
